(19) United States
(12) Patent Application Publication
(10) Pub. No.: US 2013/0299793 A1
(43) Pub. Date: Nov. 14, 2013

(54) 9,10-DIHYDROACRIDINE DERIVATIVE AND ORGANIC LIGHT EMITTING DEVICE COMPRISING THE SAME

(71) Applicant: NICHEM FINE TECHNOLOGY COMPANY LIMTED, Hsinchu County (TW)

(72) Inventors: Chi-Chung CHEN, Hsinchu County (TW); Shwu-Ju SHIEH, Hsinchu County (TW)

(73) Assignee: NICHEM FINE TECHNOLOGY COMPANY LIMTED, Hsinchu County (TW)

(21) Appl. No.: 13/889,963

(22) Filed: May 8, 2013

Related U.S. Application Data
(60) Provisional application No. 61/645,838, filed on May 11, 2012.

(51) Int. Cl. H01L 51/00

(52) U.S. Cl. CPC H01L 51/0072; H01L 51/0071; H01L 51/0058; H01L 51/0061
USPC 257/40; 546/104

(57) ABSTRACT

Provided is a 9,10-dihydroacridine derivative represented by the following Formula (I):

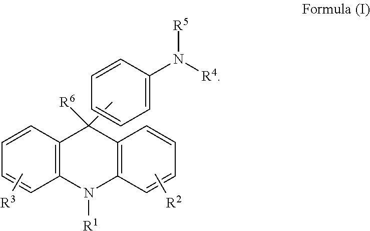

The 9,10-dihydroacridine derivative can be used as a hole transport material or an emission material of an organic light emitting device. An organic light emitting device comprising the 9,10-dihydroacridine derivative is also provided and has an improved optical performance.

### CROSS-REFERENCE TO RELATED APPLICATION

Pursuant to 35 U.S.C. §119(e), this application claims the benefit of the priority to U.S. Provisional Patent Application No. 61/645,838, filed May 11, 2012. The content of the prior application is incorporated herein by its entirety.

### BACKGROUND OF THE INVENTION

1. Field of the Invention

The present invention relates to a novel 9,10-dihydroacridine derivative and an organic light emitting device comprising the same.

2. Description of the Prior Arts

With the advance of technology, various light emitting devices are developed. One of the newly-developed light emitting devices is an organic light emitting device (OLED), which includes a first electrode, a second electrode, at least two organic layers formed between the first and second electrodes, and an emission layer formed between the at least two organic layers. As an electric field is applied to the first and the second electrodes, the first electrode injects electrons into the emission layer; meanwhile, the second electrode injects holes into the emission layer. Recombination of the electrons and the holes occurs in the emission layer, thereby emitting a light.

Depending on the emission mechanism, OLEDs can work without backlights and achieve high contrast ratios, wide viewing angles, and short responding time. Moreover, OLEDs can emit lights in red, green or blue by using different organic compounds as emission materials. With these advantages, OLEDs are easily made thinner and widely integrated in various electronic equipments, such as cell phones and televisions.

Due to the aforesaid advantages of OLEDs, researches have been conducted into OLEDs. Since the optical performance of OLEDs is determined by the organic compounds comprised thereof, a novel organic compound is needed for improving their current efficiencies.

### SUMMARY OF THE INVENTION

An objective of the present invention is to provide a novel 9,10-dihydroacridine derivative useful as a hole transport material, a hole injection material, or an emission material of an organic light emitting device.

To achieve the objective, the present invention provides a 9,10-dihydroacridine derivative represented by the following Formula (I):

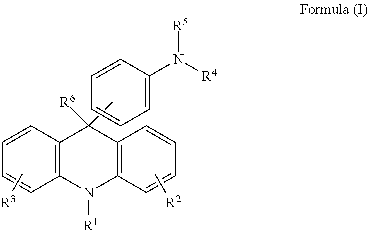

wherein R¹ is a substituted or unsubstituted aryl group having 5 to 20 carbon atoms or a substituted or unsubstituted heteroaryl group having 5 to 20 carbon atoms;

R² and R³ are identical or different and are each independently selected from the group consisting of: a hydrogen group, a substituted or unsubstituted alkyl group having 1 to 20 carbon atoms, a substituted or unsubstituted aryl group having 5 to 20 carbon atoms, and a substituted or unsubstituted heteroaryl group having 5 to 20 carbon atoms;

R⁴ and R⁵ are identical or different and are each independently selected from the group consisting of: a substituted or unsubstituted aryl group having 5 to 40 carbon atoms or a substituted or unsubstituted heteroaryl group having 5 to 40 carbon atoms; and

R⁶ is

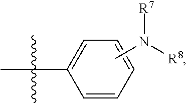

a substituted or unsubstituted aryl group having 5 to 60 carbon atoms, or a substituted or unsubstituted heteroaryl group having 5 to 60 carbon atoms, wherein R⁷ and R⁸ are each independently a substituted or unsubstituted aryl group having 5 to 40 carbon atoms or a substituted or unsubstituted heteroaryl group having 5 to 40 carbon atoms.

The term “heteroaryl group” in the specification is directed to an aromatic group including at least one carbon atom which is replaced by an atom different from carbon atom, such as nitrogen atom, oxygen atom or sulfur atom.

Preferably, R¹ is selected from the group consisting of:

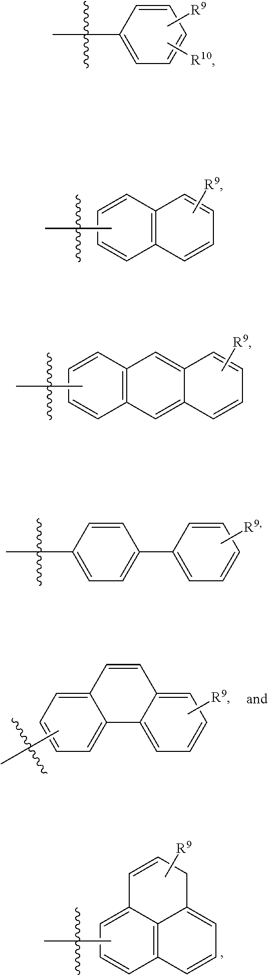

wherein R⁹ and R¹⁰ are identical or different and are each independently a hydrogen group or an alkyl group having 1 to 6 carbon atoms.

Preferably, R² and R³ are identical or different and are each independently selected from the group consisting of: a hydrogen group, a substituted or unsubstituted alkyl group having 1 to 10 carbon atoms, a substituted or unsubstituted aryl group having 5 to 15 carbon atoms, and a substituted or unsubstituted heteroaryl group having 5 to 15 carbon atoms.

In a first embodiment of the 9,10-dihydroacridine derivative in accordance with the present invention, R⁶ is

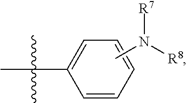

wherein R⁷ and R⁸ are each independently selected from the group consisting of:

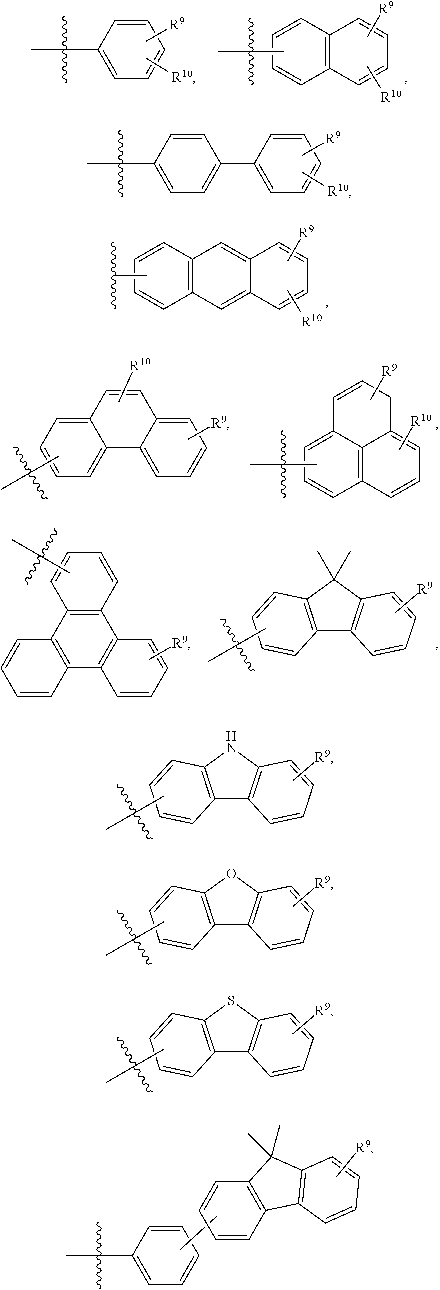

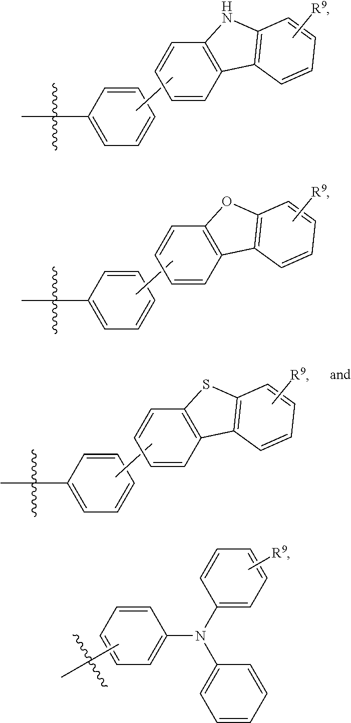

wherein R⁹ and R¹⁰ are each independently a hydrogen group or an alkyl group having 1 to 6 carbon atoms.

Preferably, in the second embodiment of the 9,10-dihydroacridine derivative in accordance with the present invention, R⁴ and R⁵ are identical or different and are each independently selected from the group consisting of:

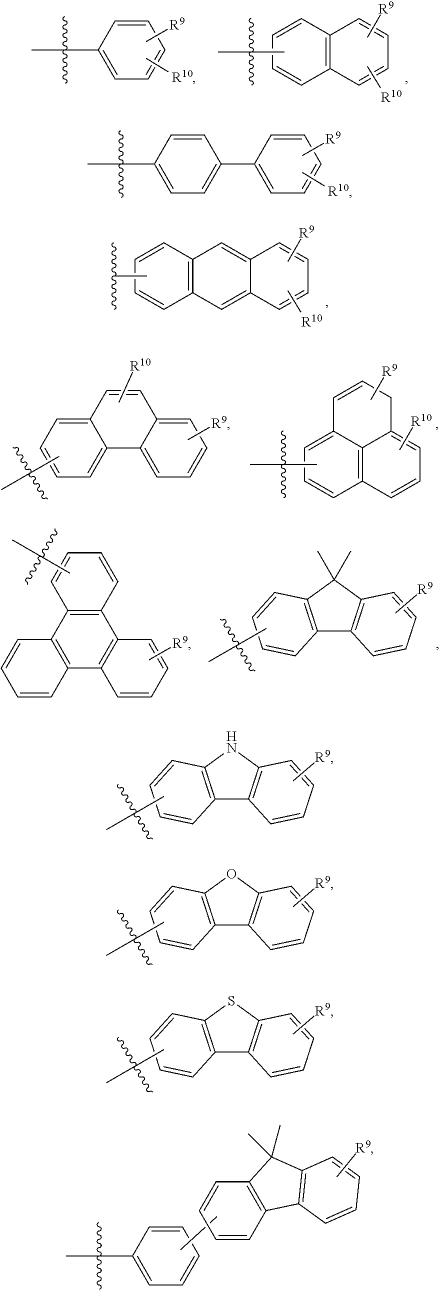

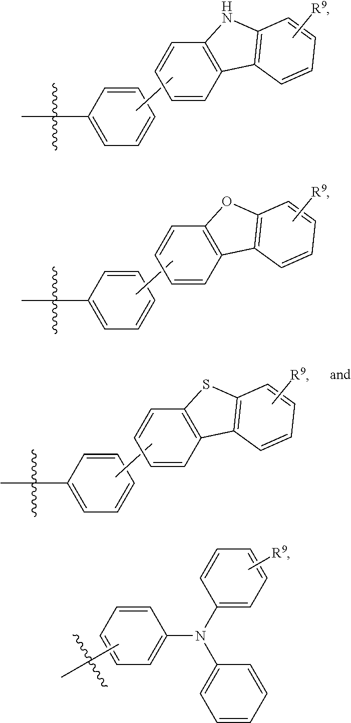

wherein R⁹ and R¹⁰ are identical or different and are each independently a hydrogen group or an alkyl group having 1 to 6 carbon atoms.

More preferably, R² is identical with R³, R⁴ is identical with R⁷, and R⁵ is also identical with R⁸. The 9,10-dihydroacridine derivative has a symmetrical chemical structure.

Several illustrative examples of the 9,10-dihydroacridine derivative in accordance with the first embodiment of the present invention are, but not limited to:

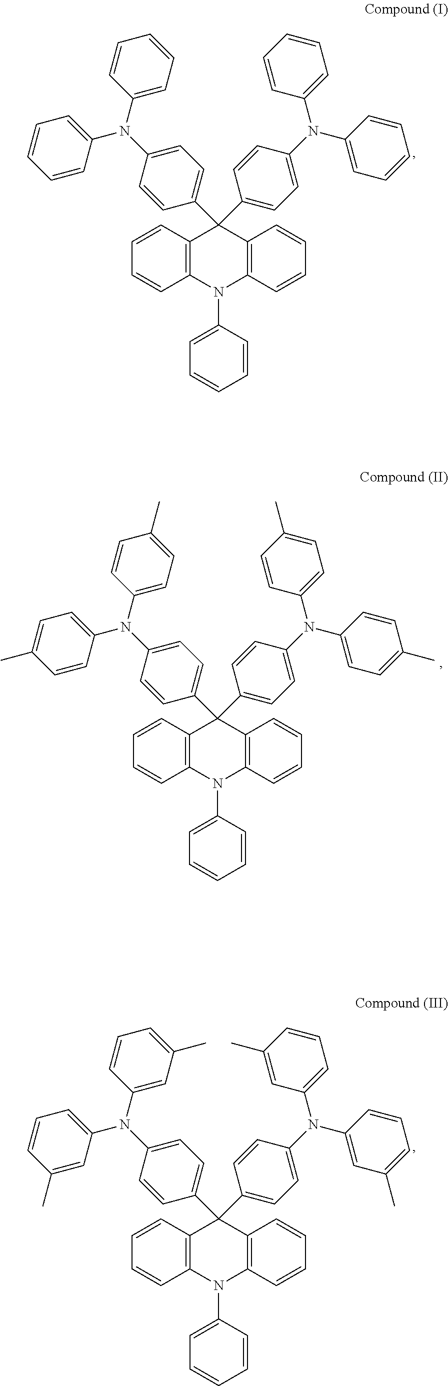

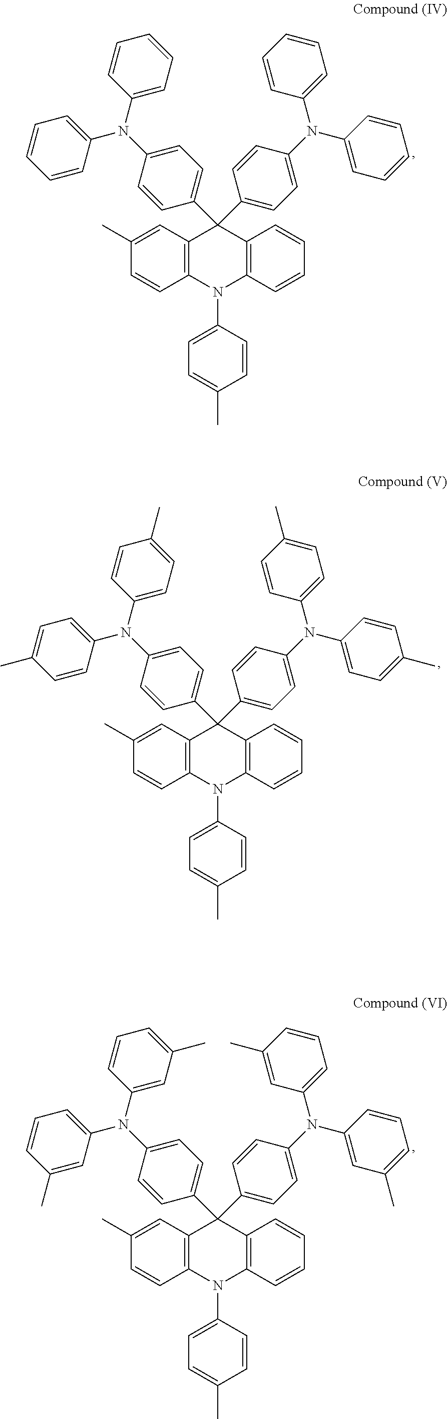

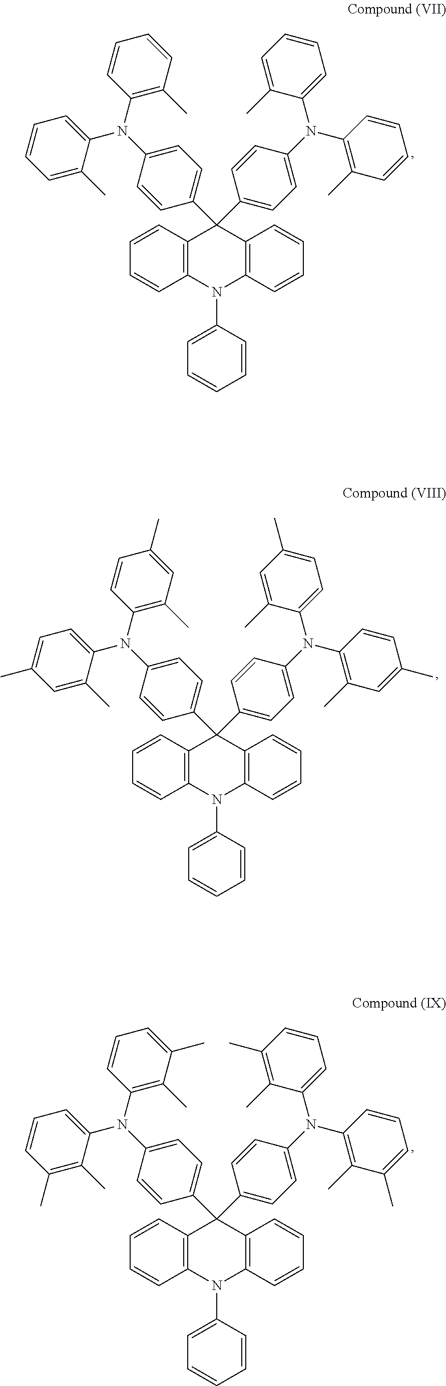

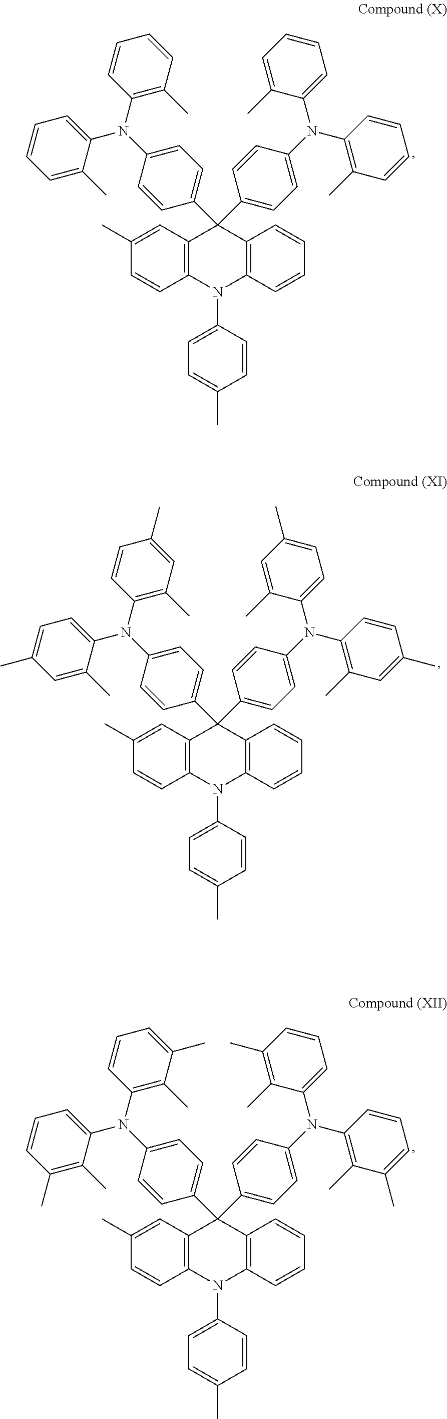

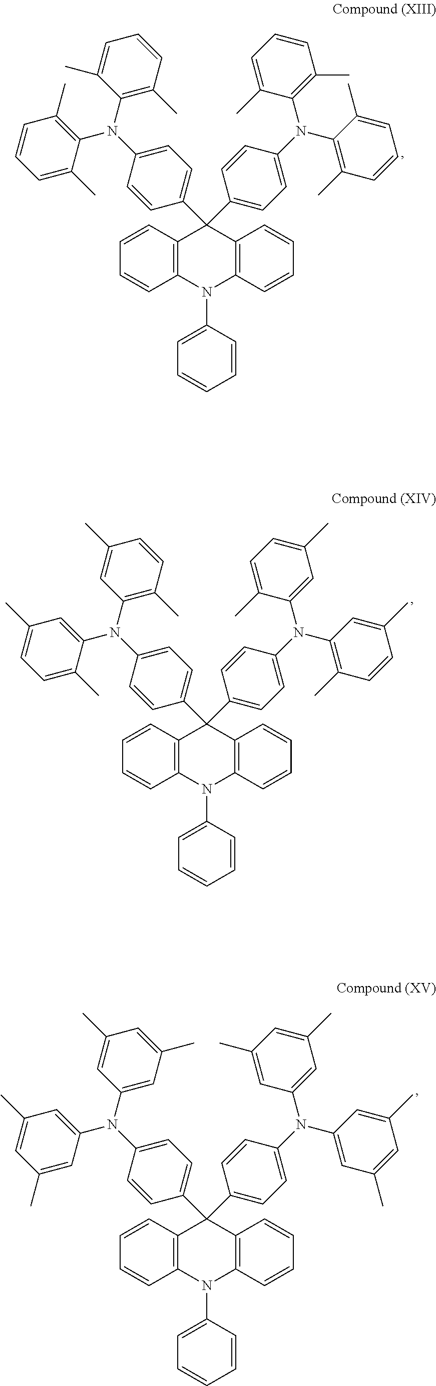

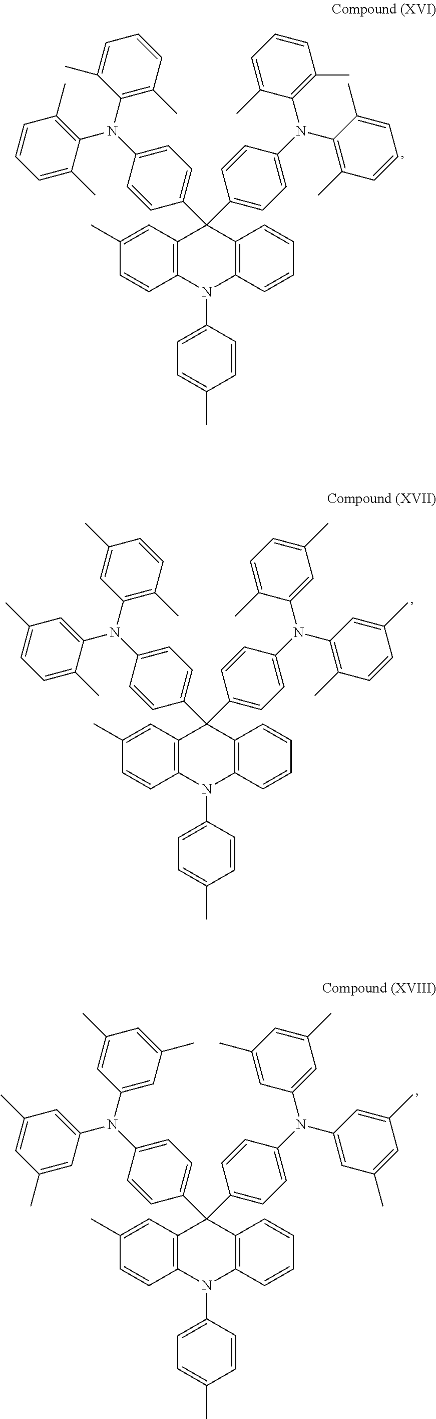

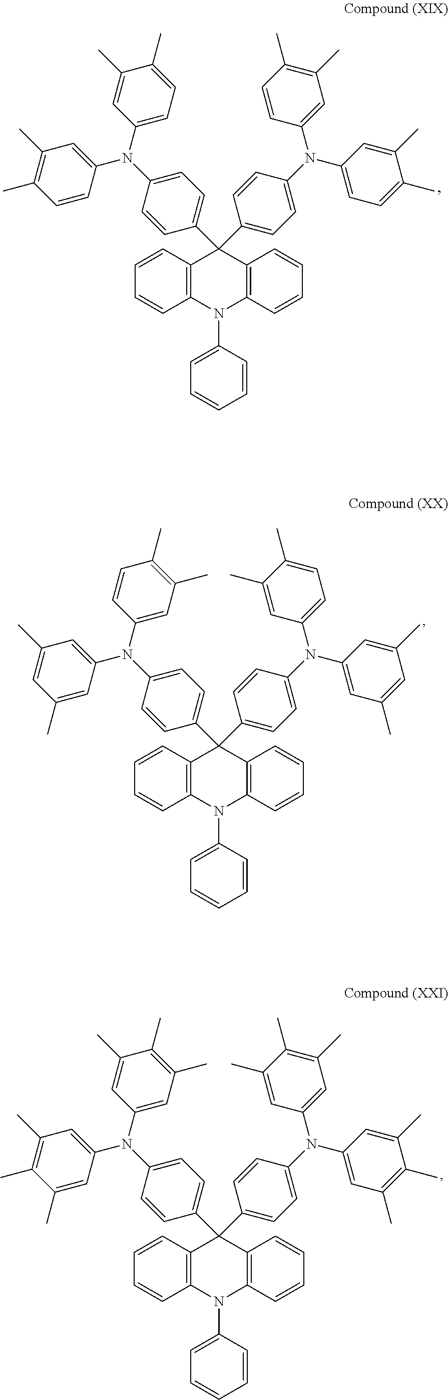

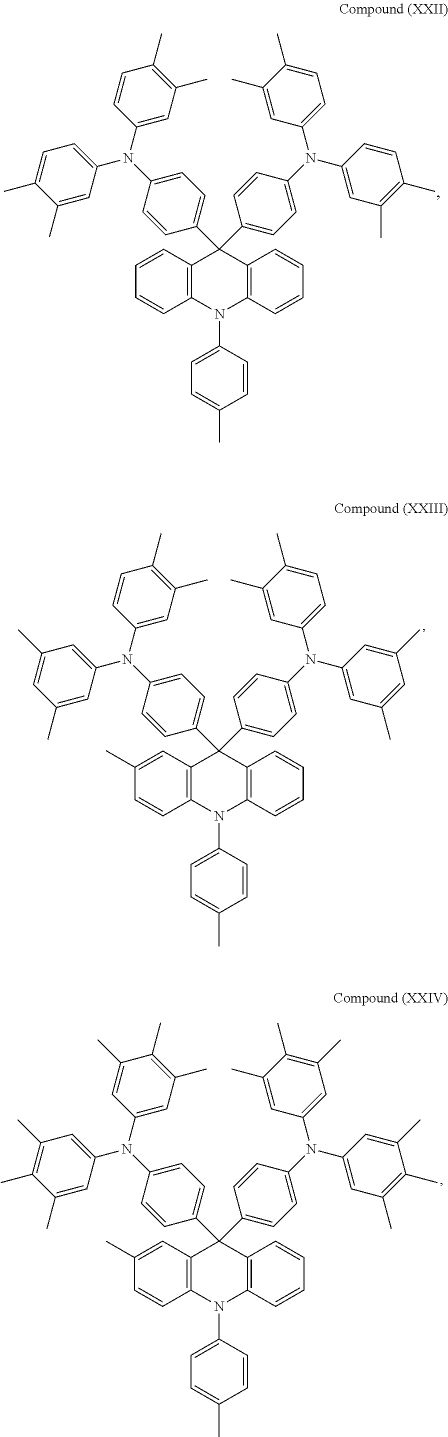

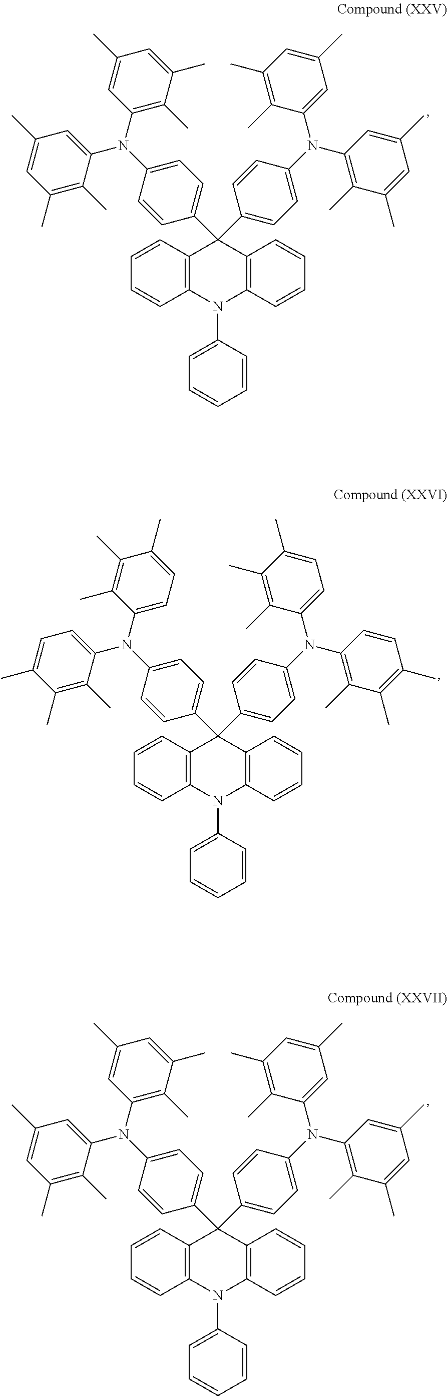

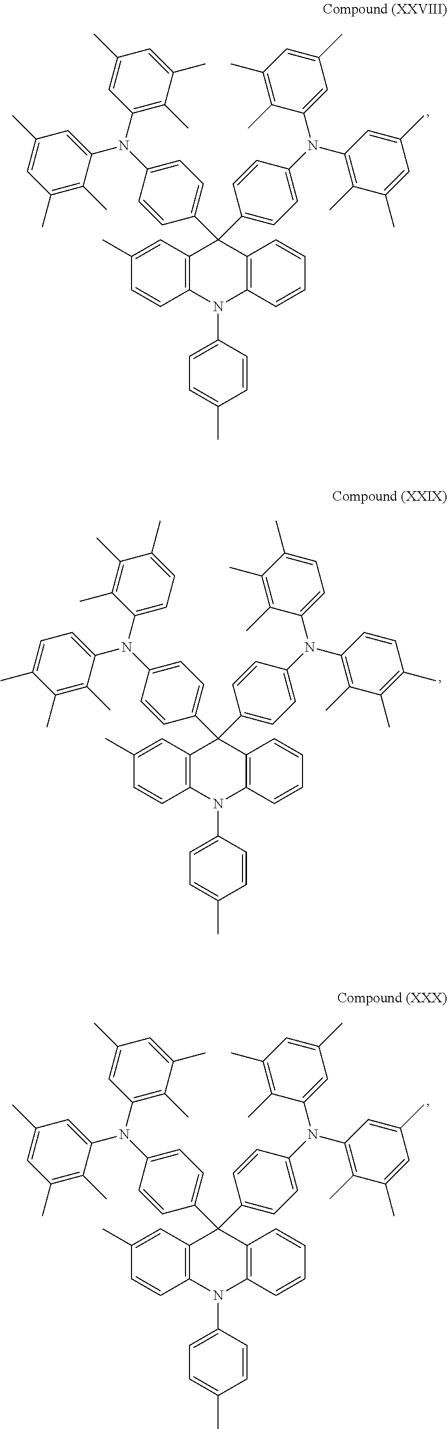

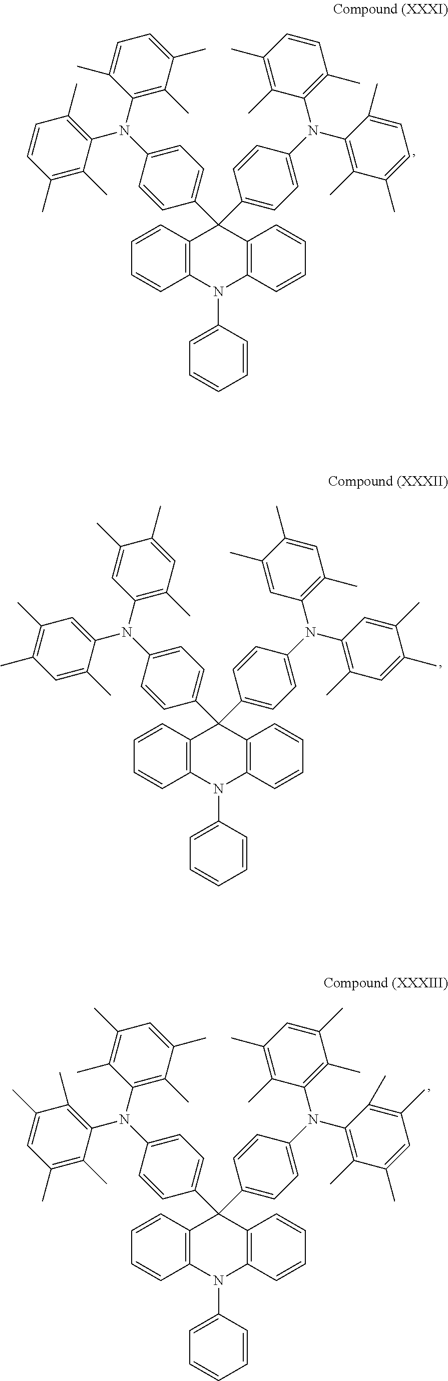

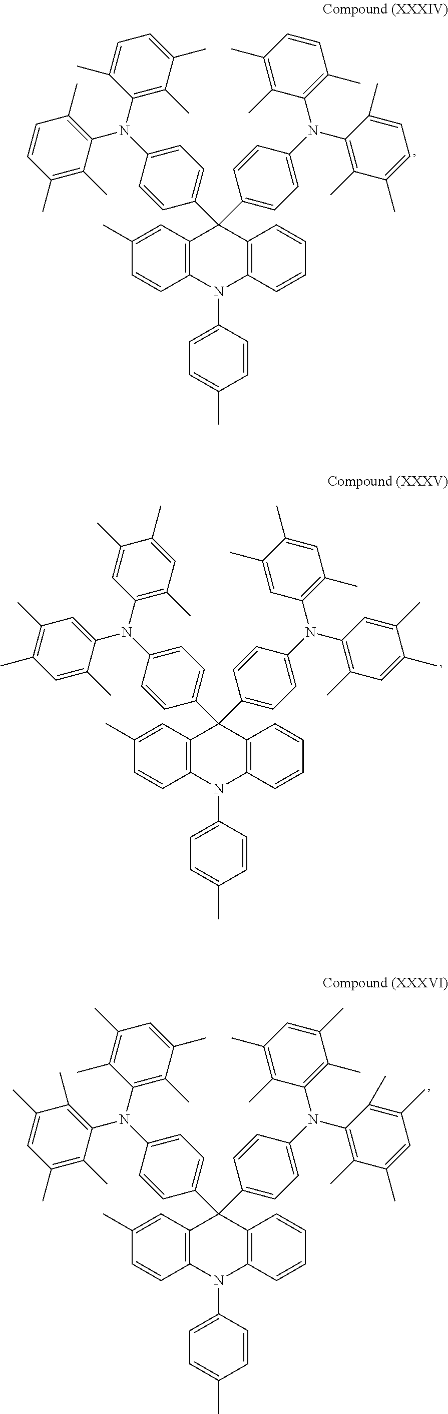

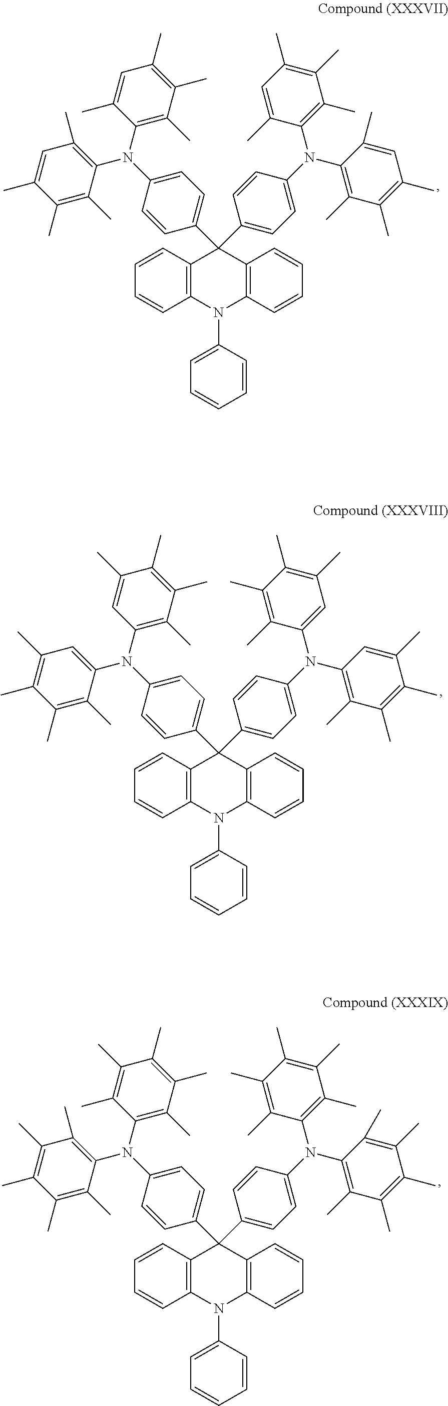

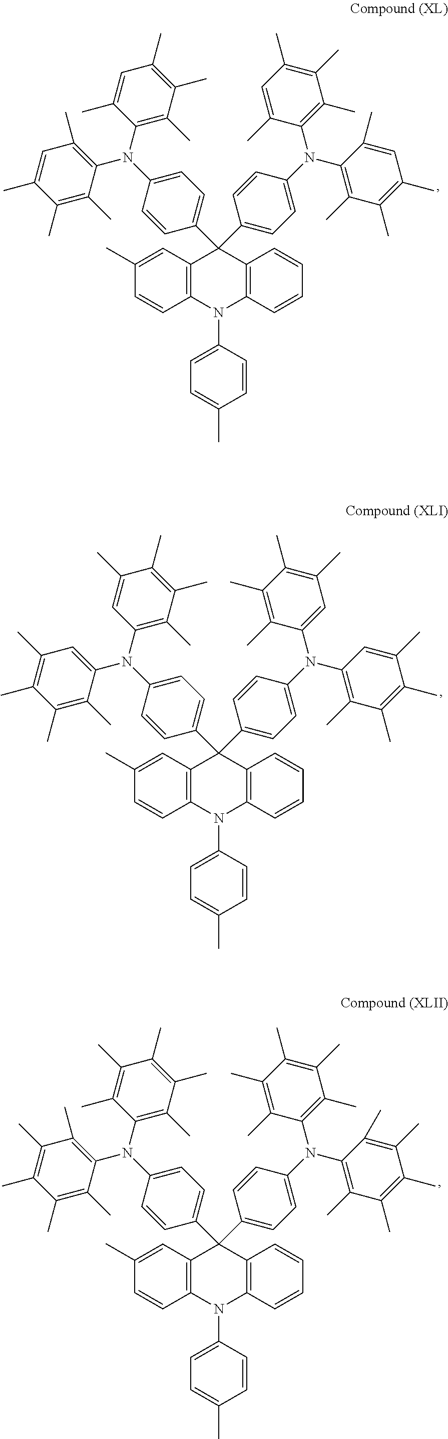

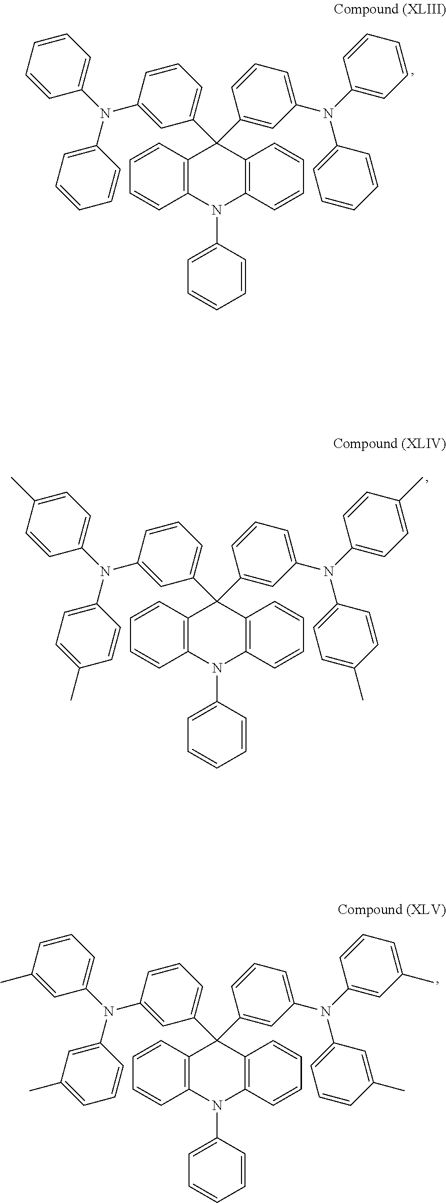

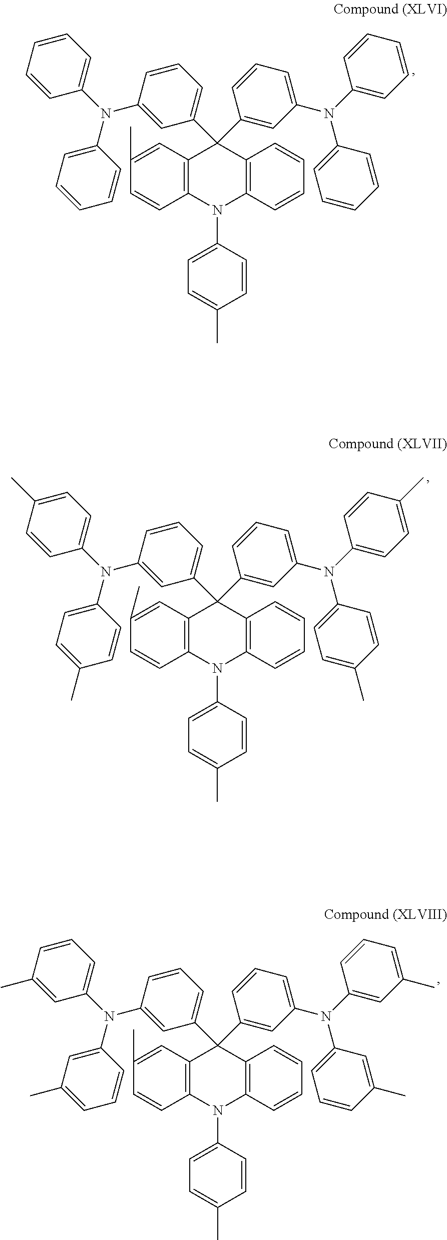

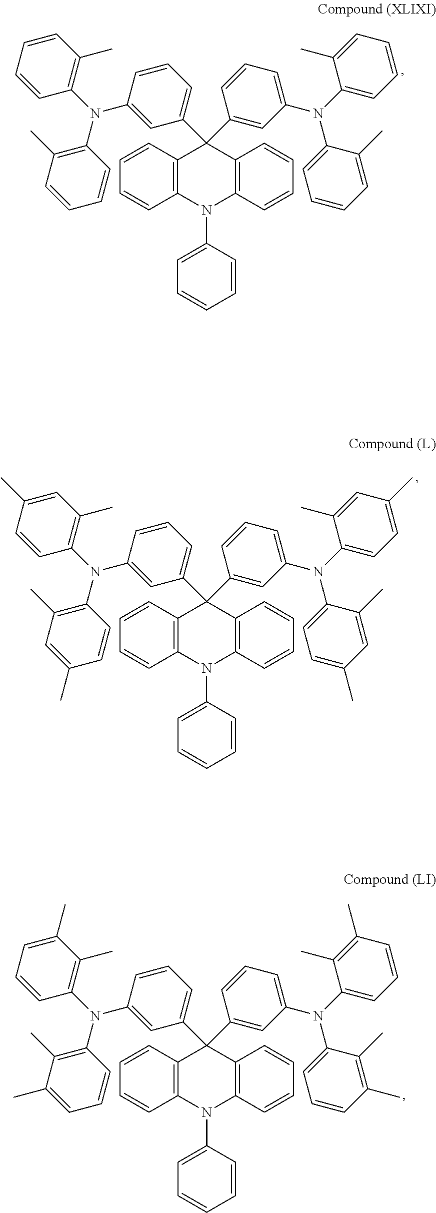

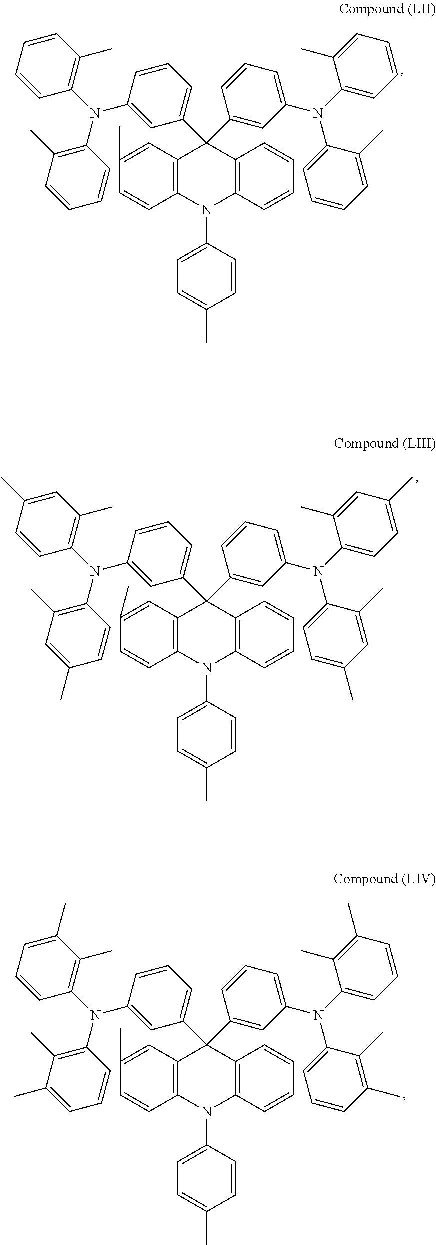

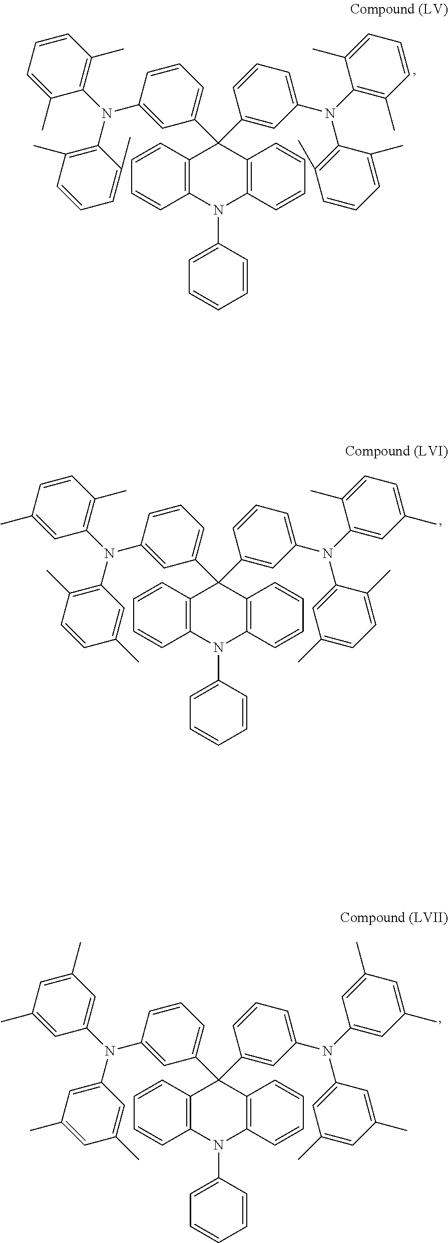

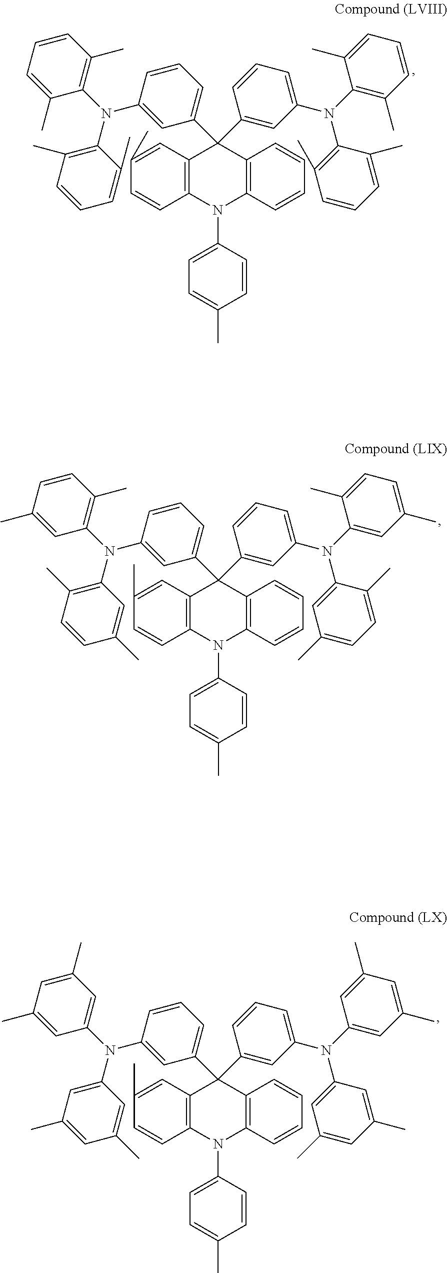

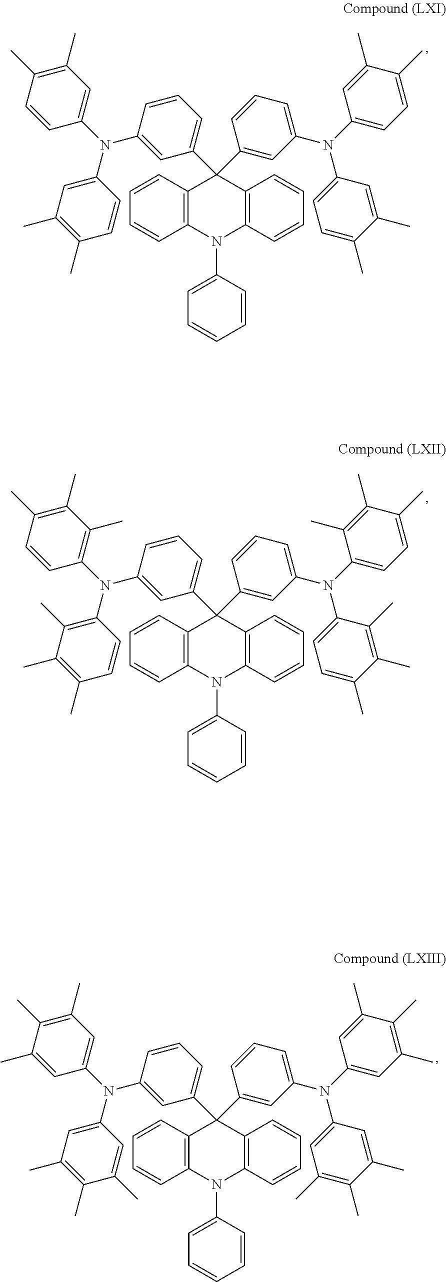

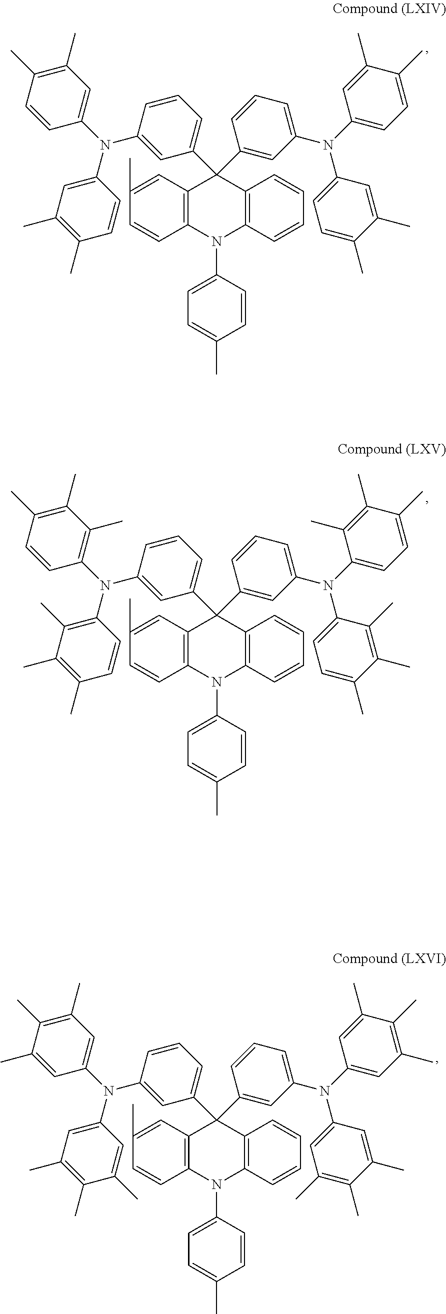

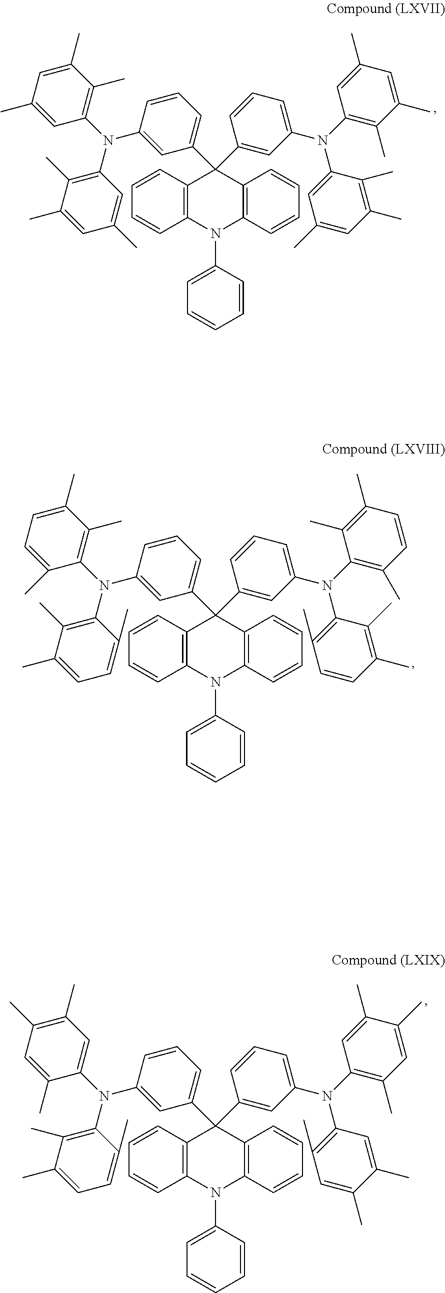

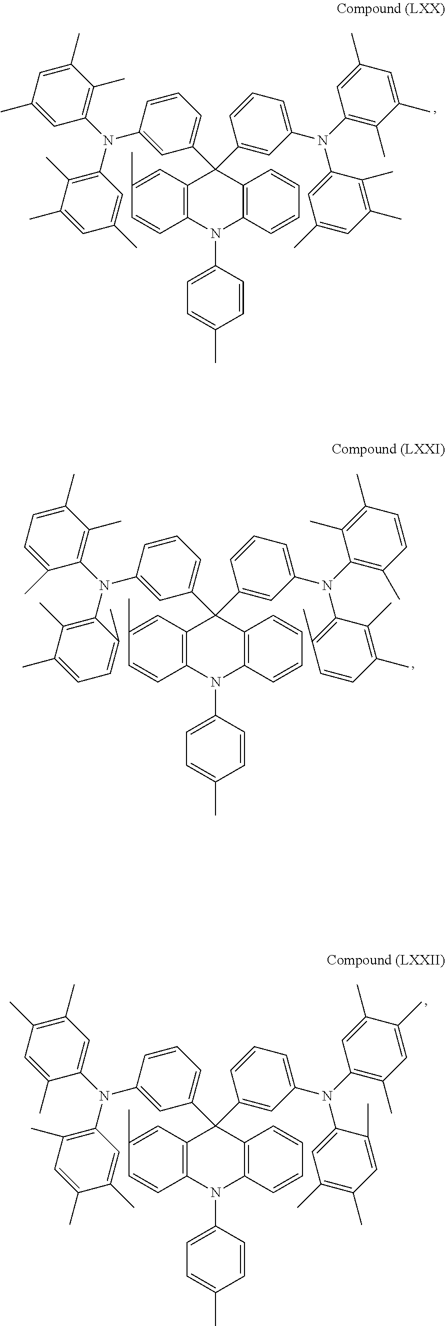

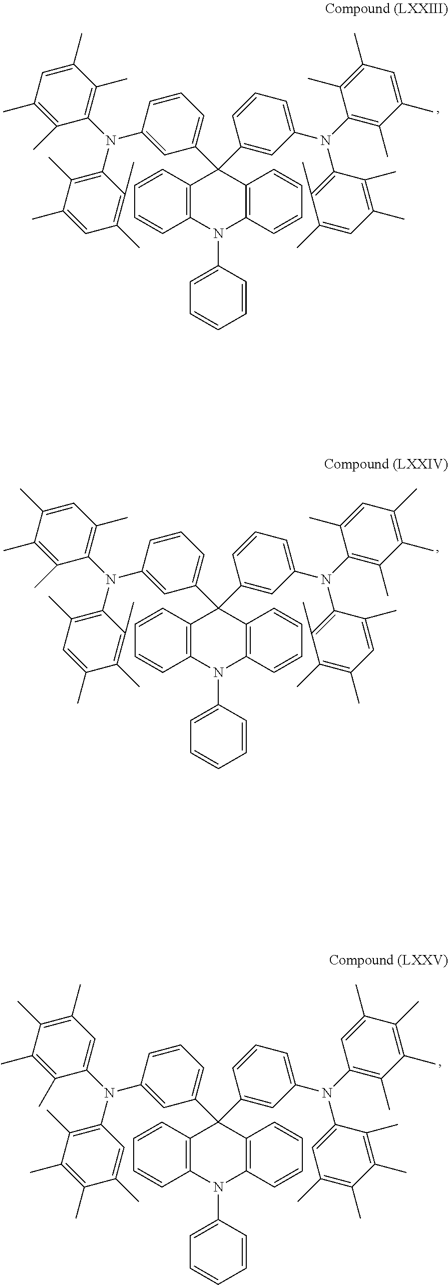

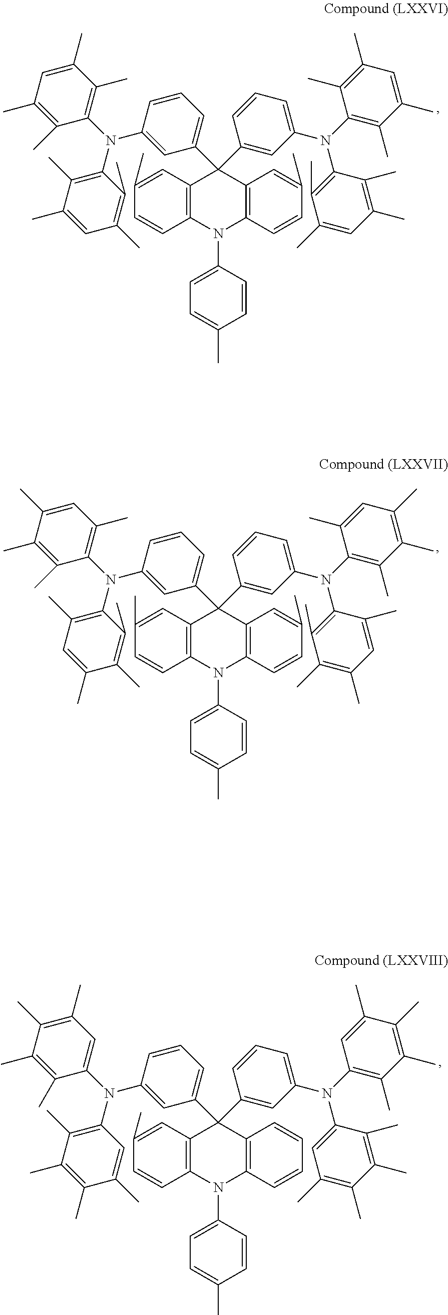

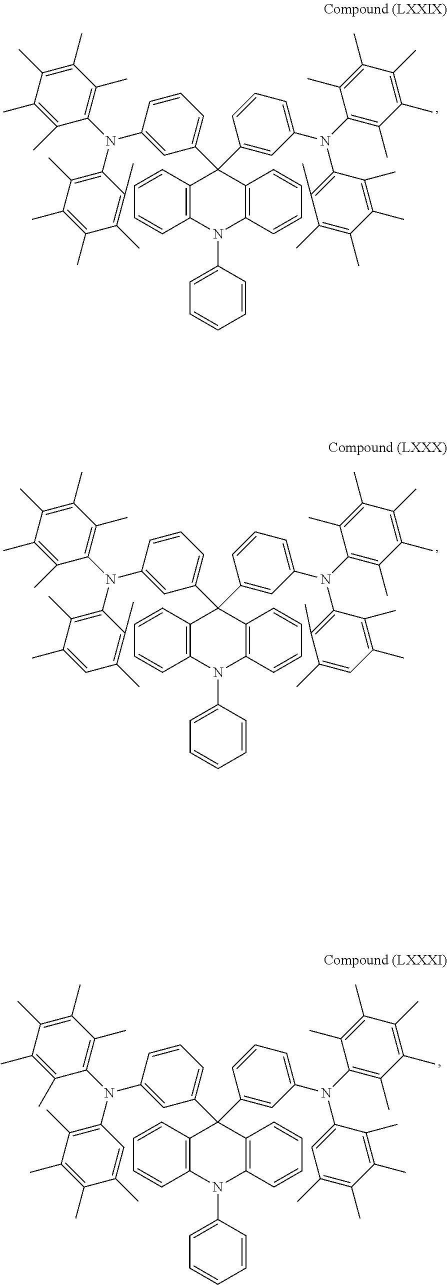

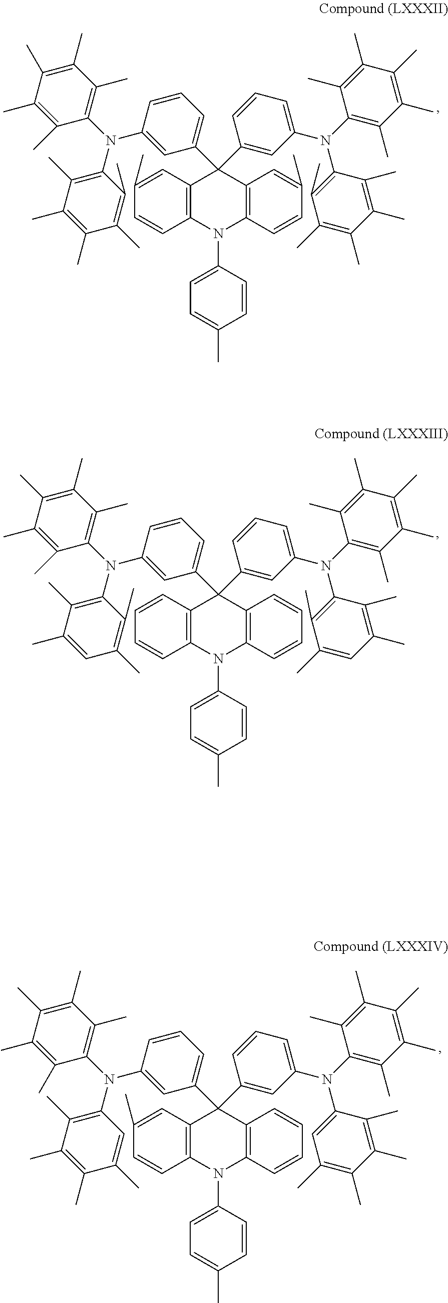

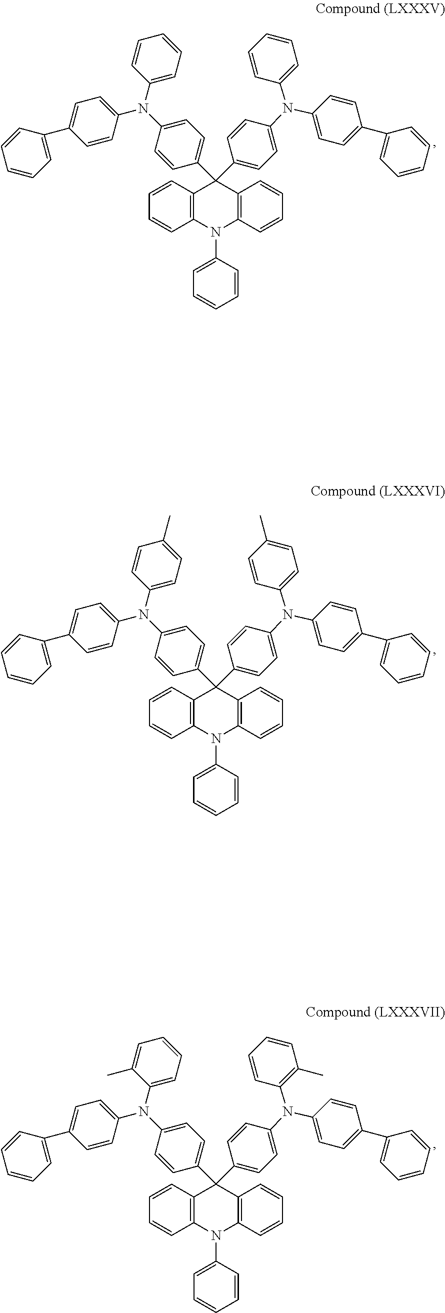

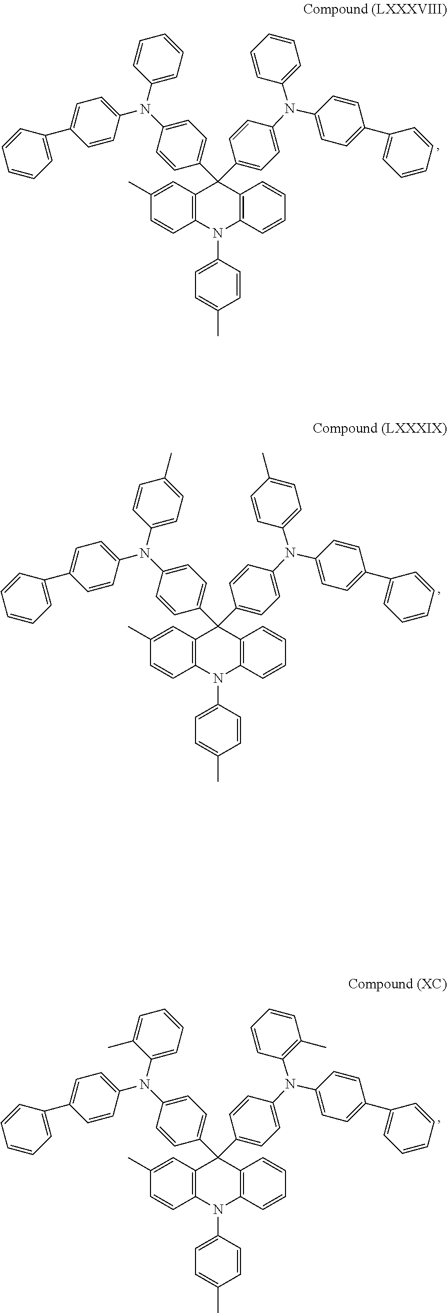

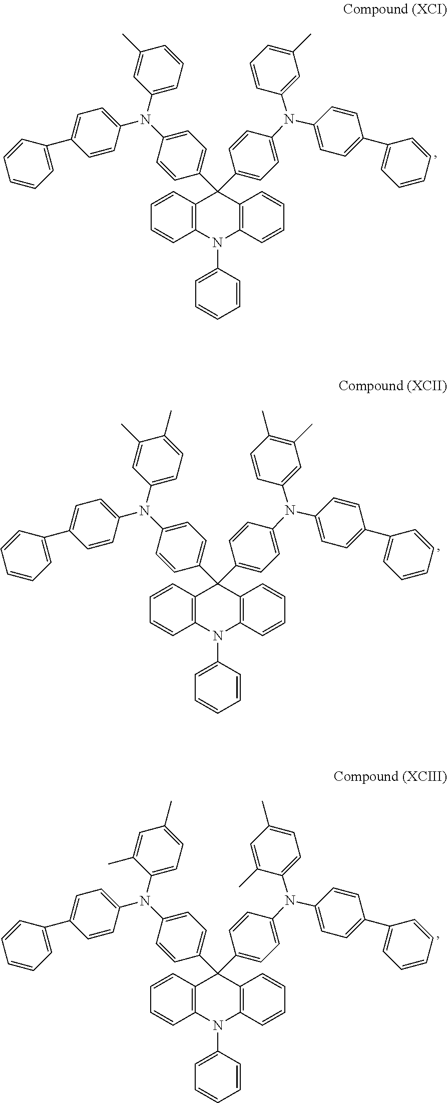

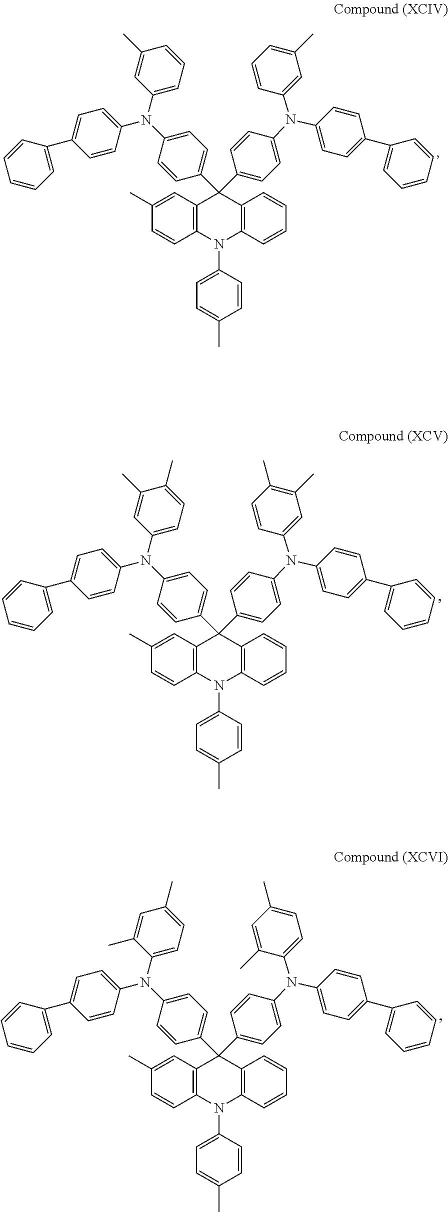

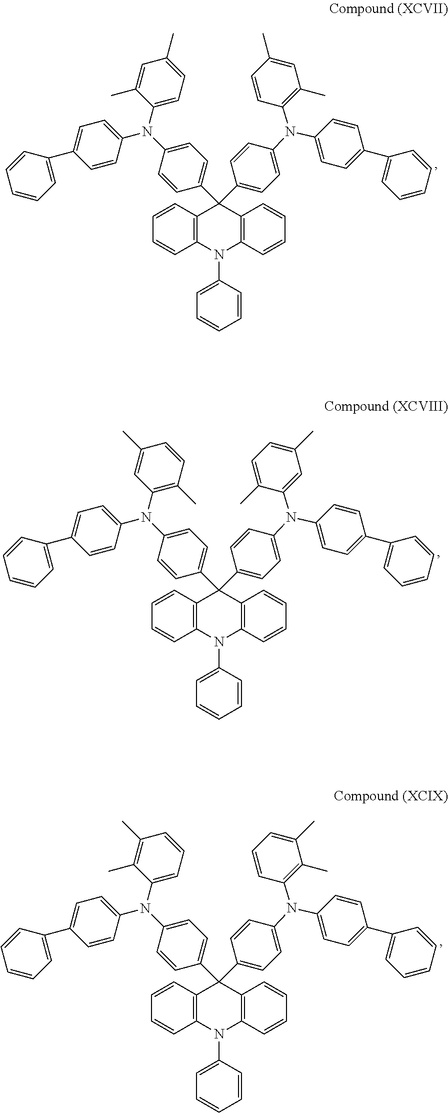

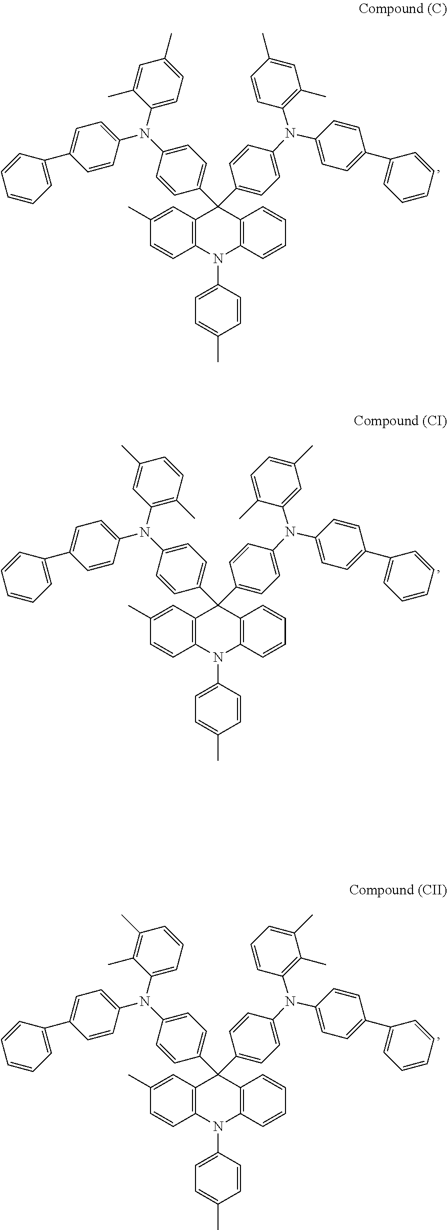

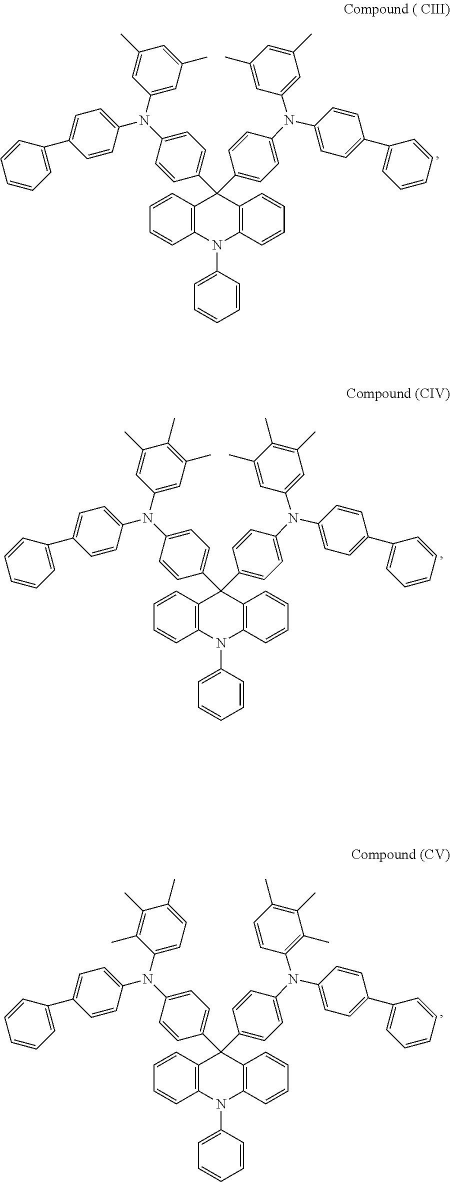

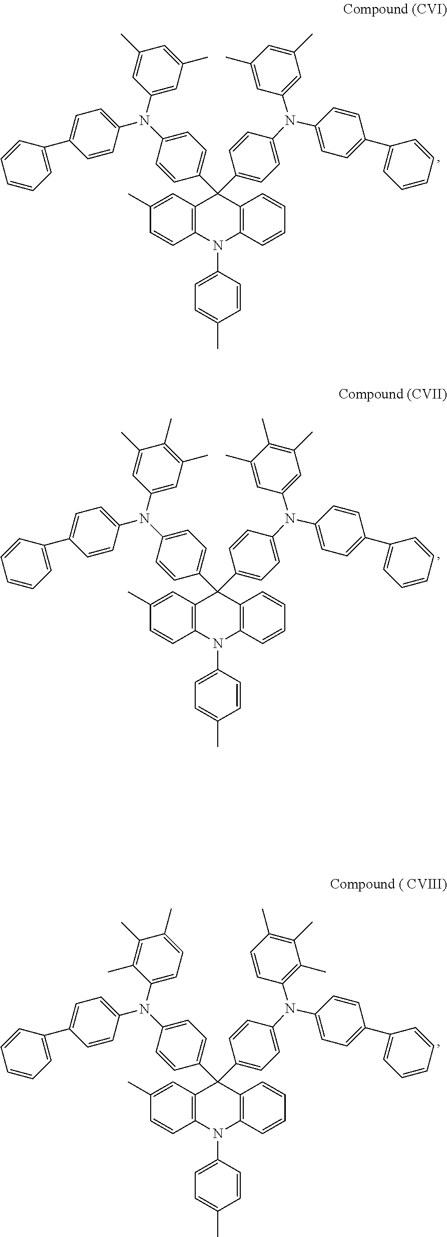

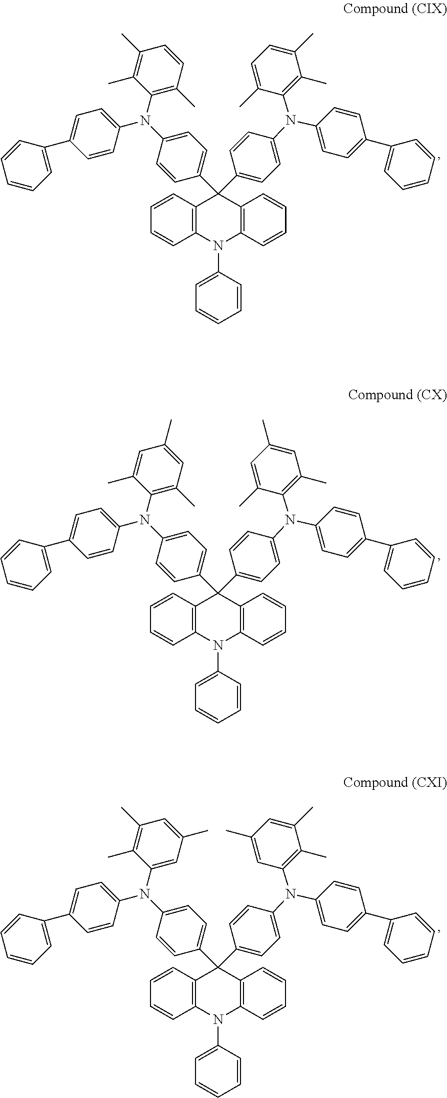

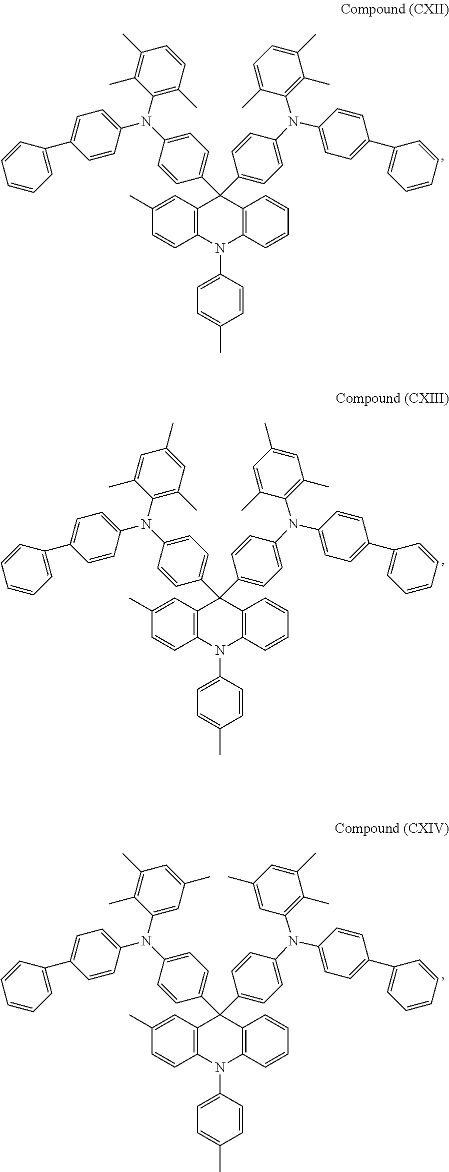

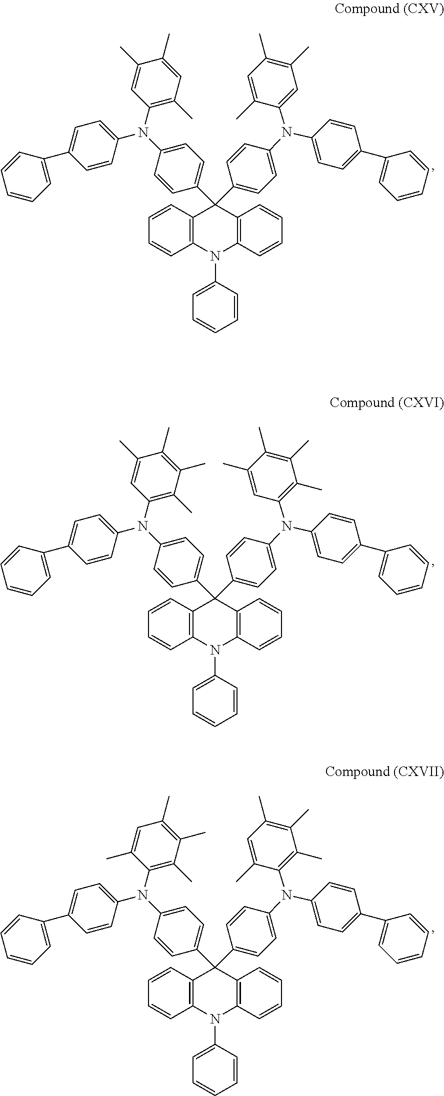

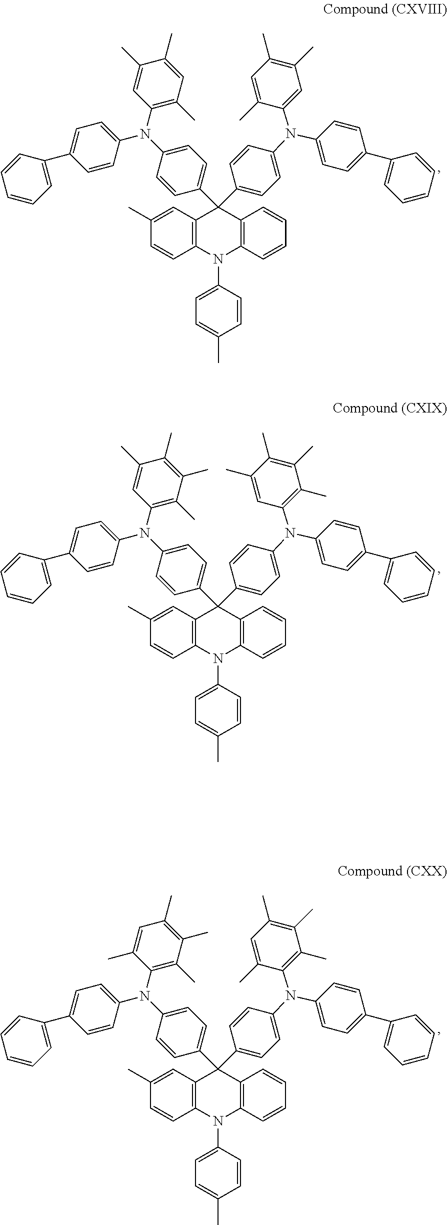

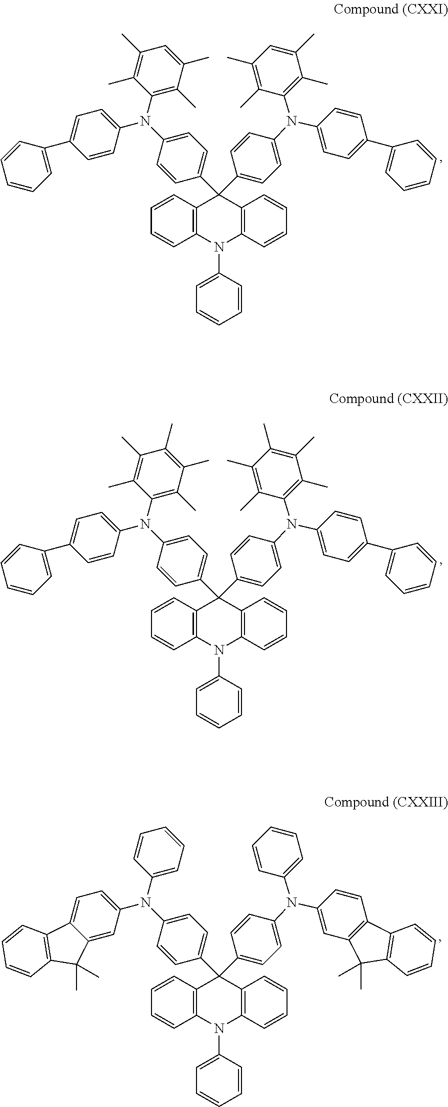

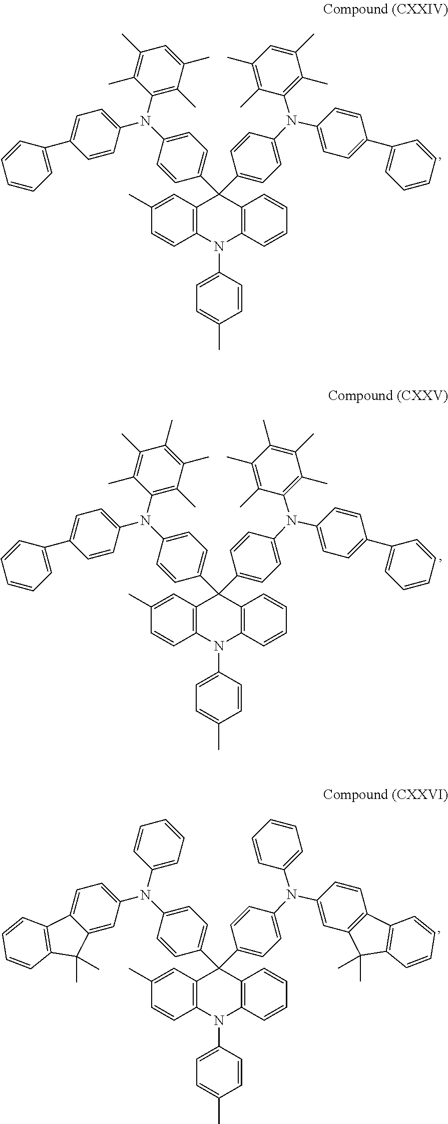

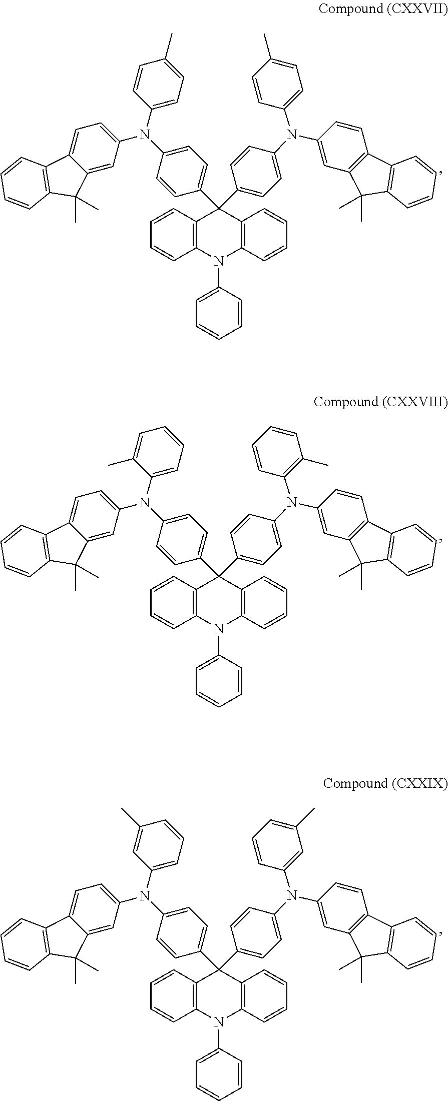

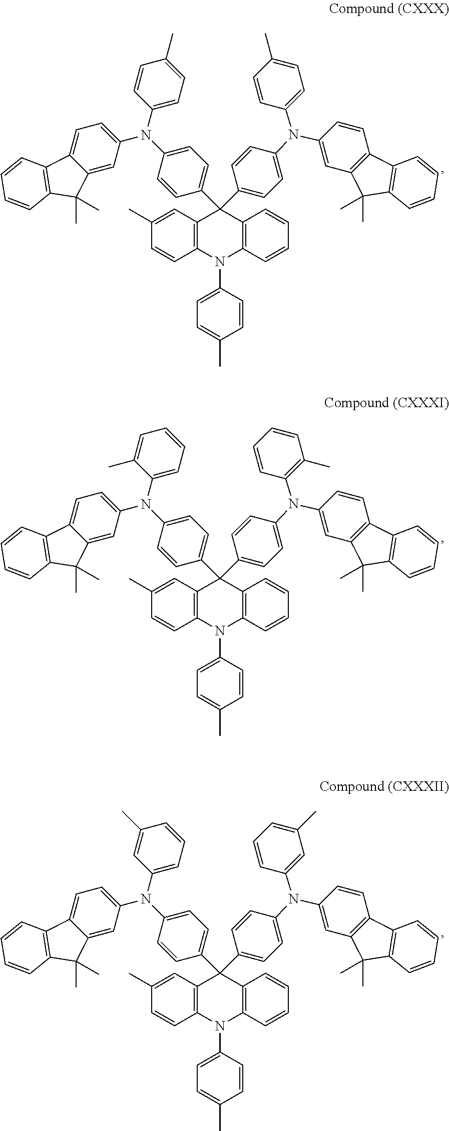

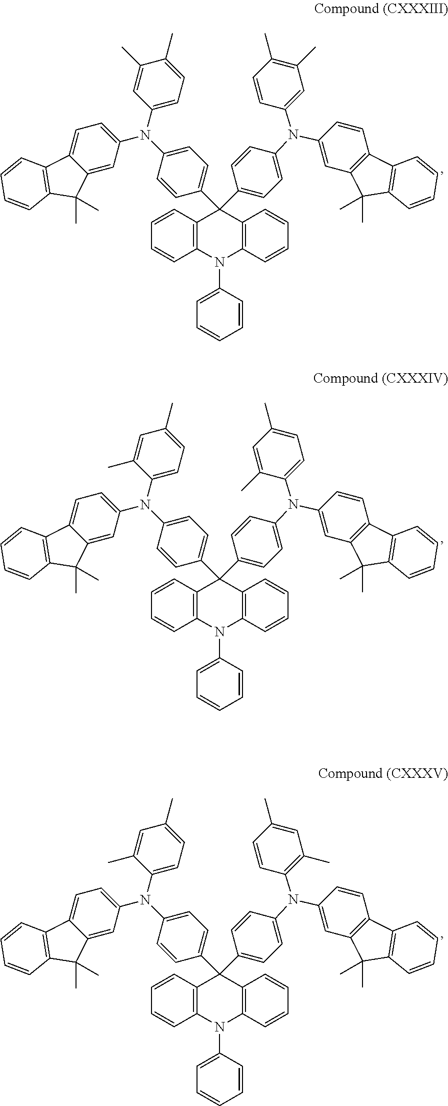

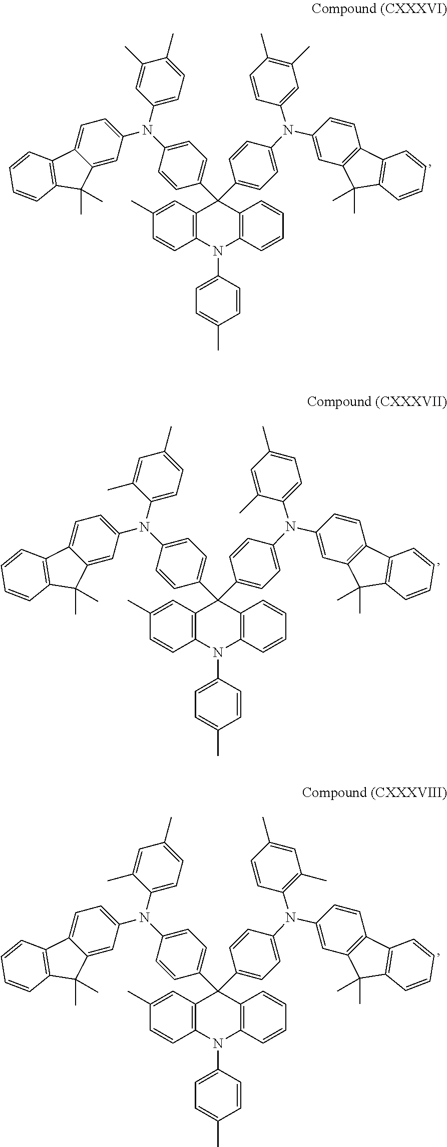

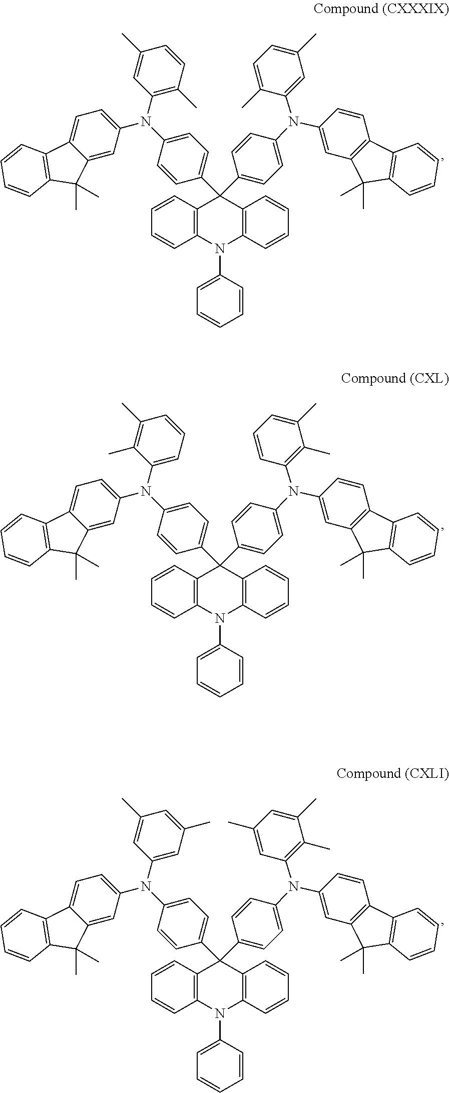

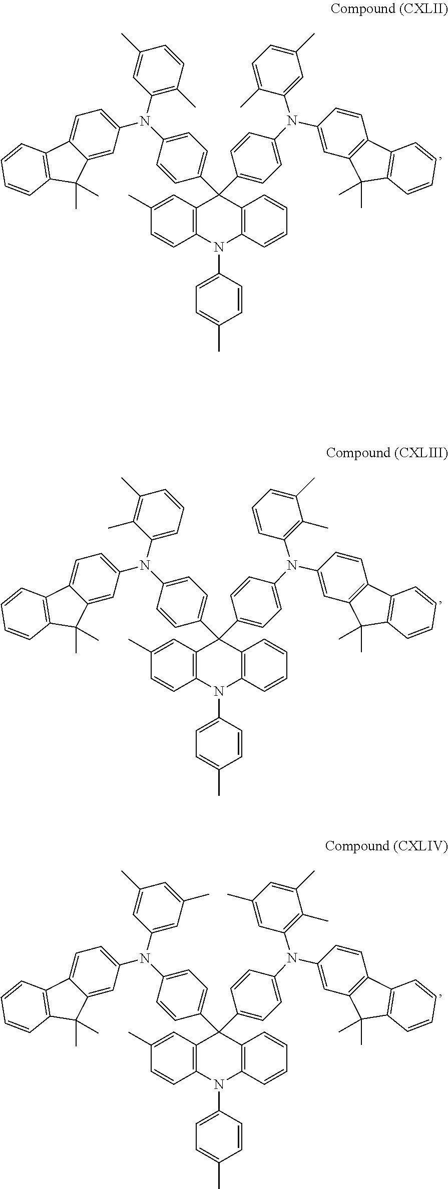

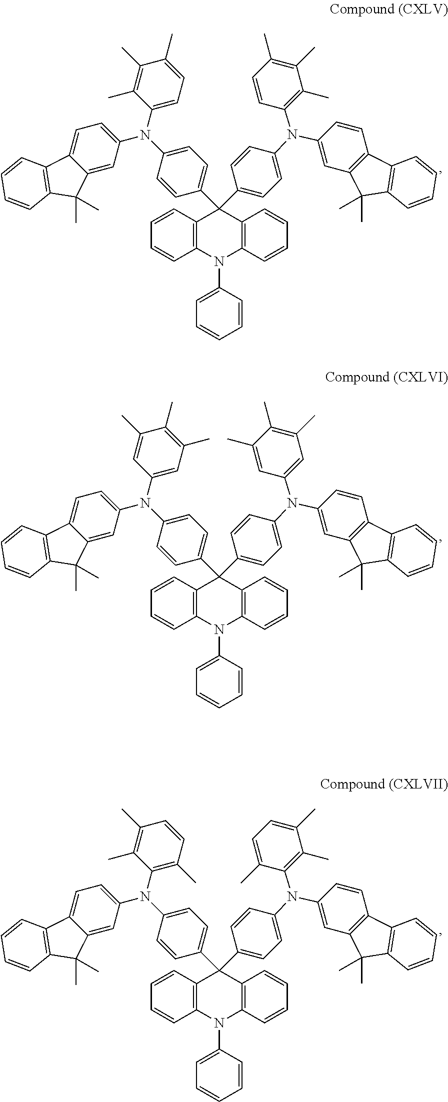

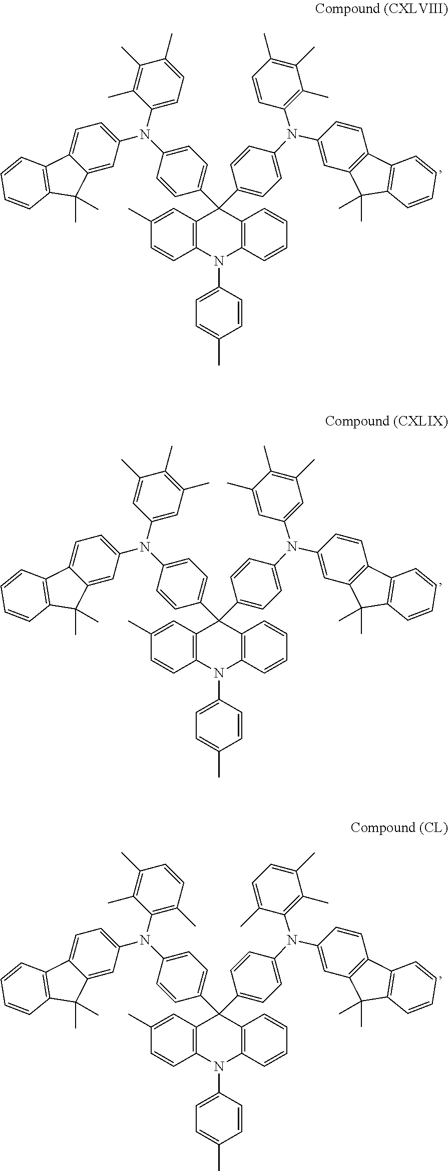

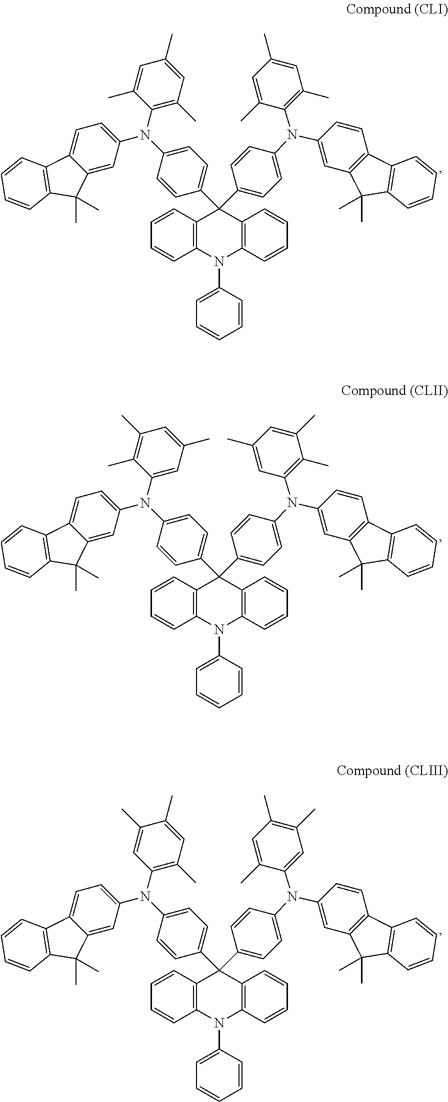

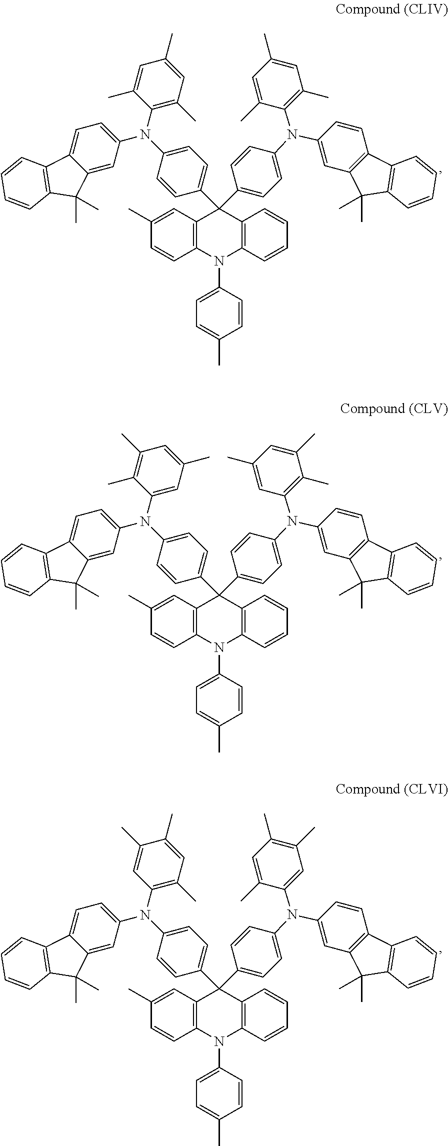

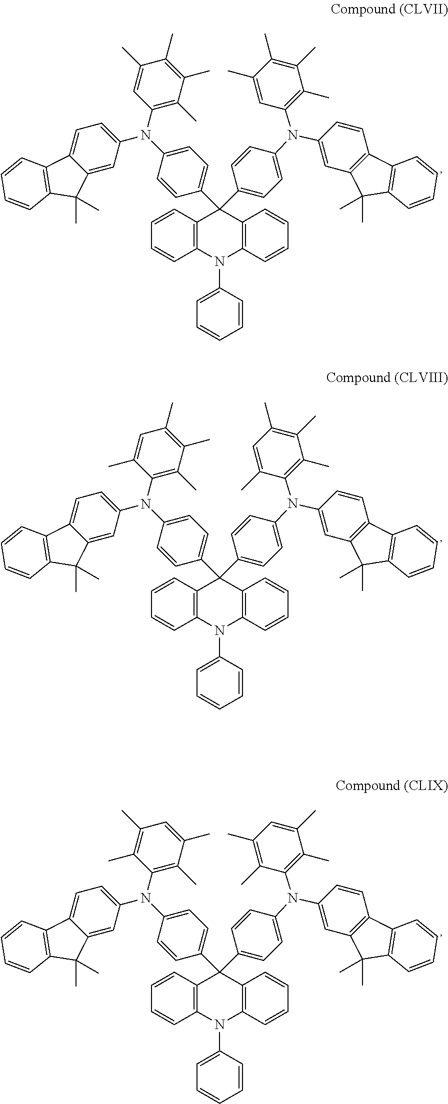

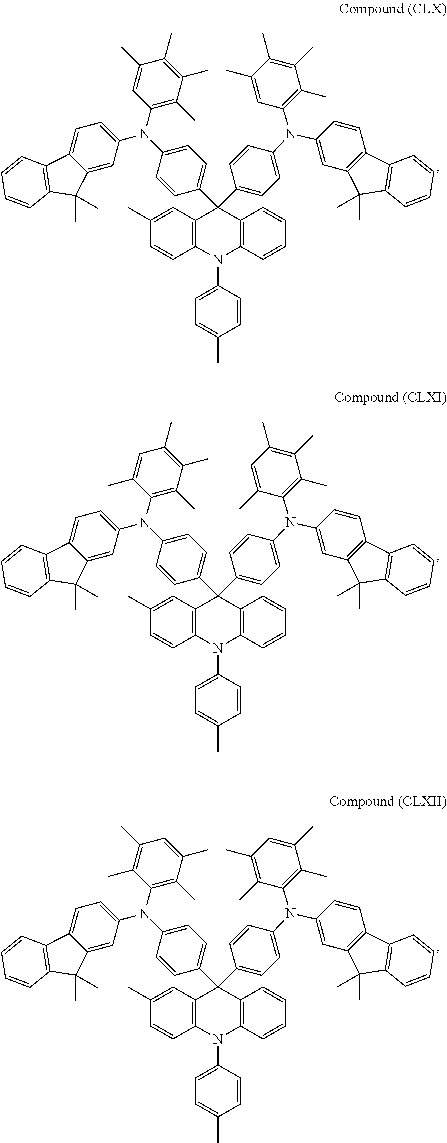

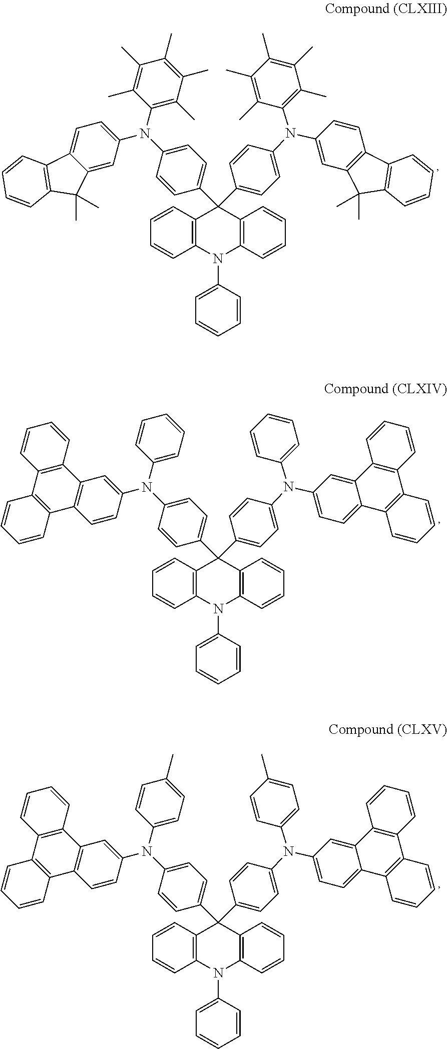

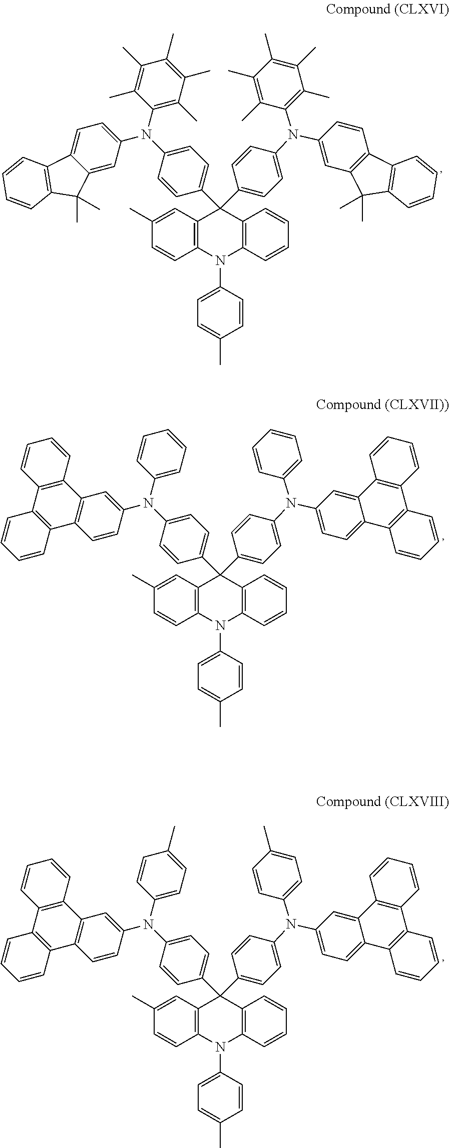

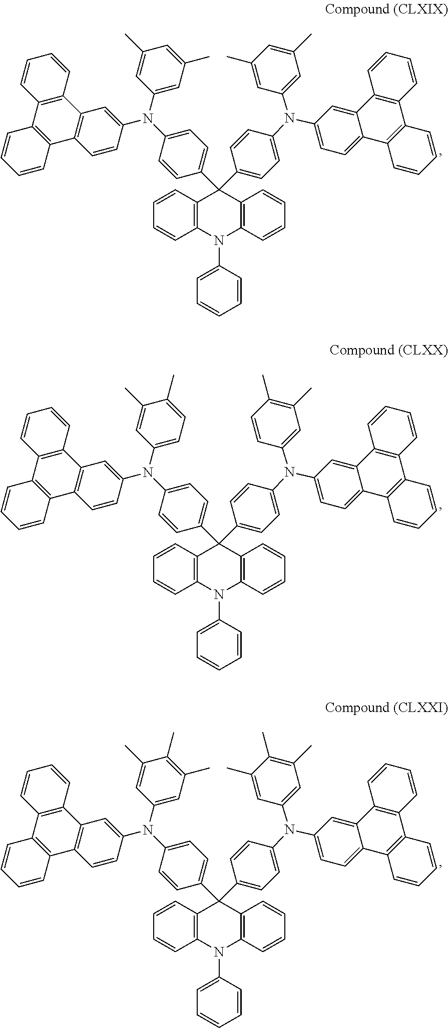

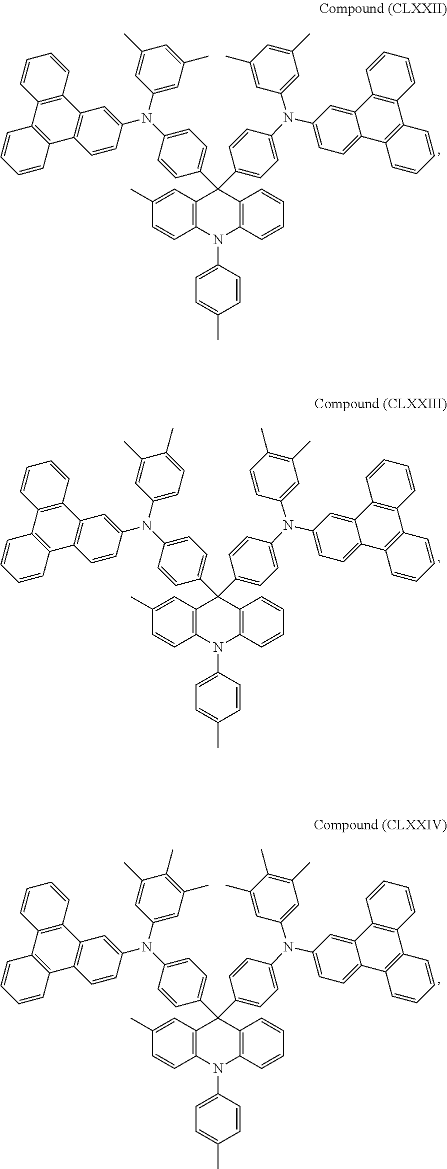

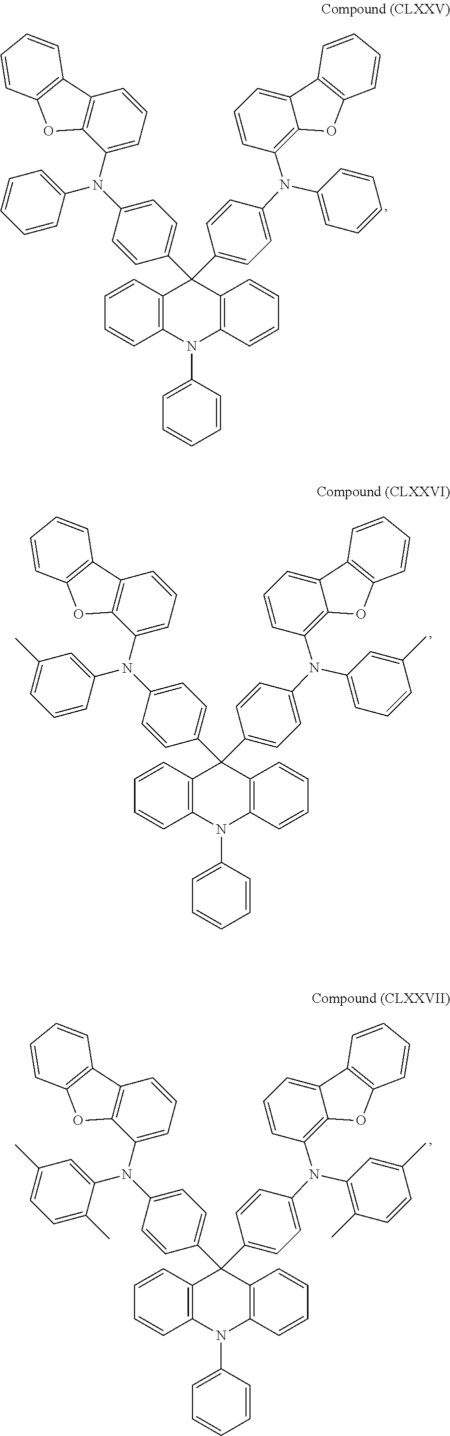

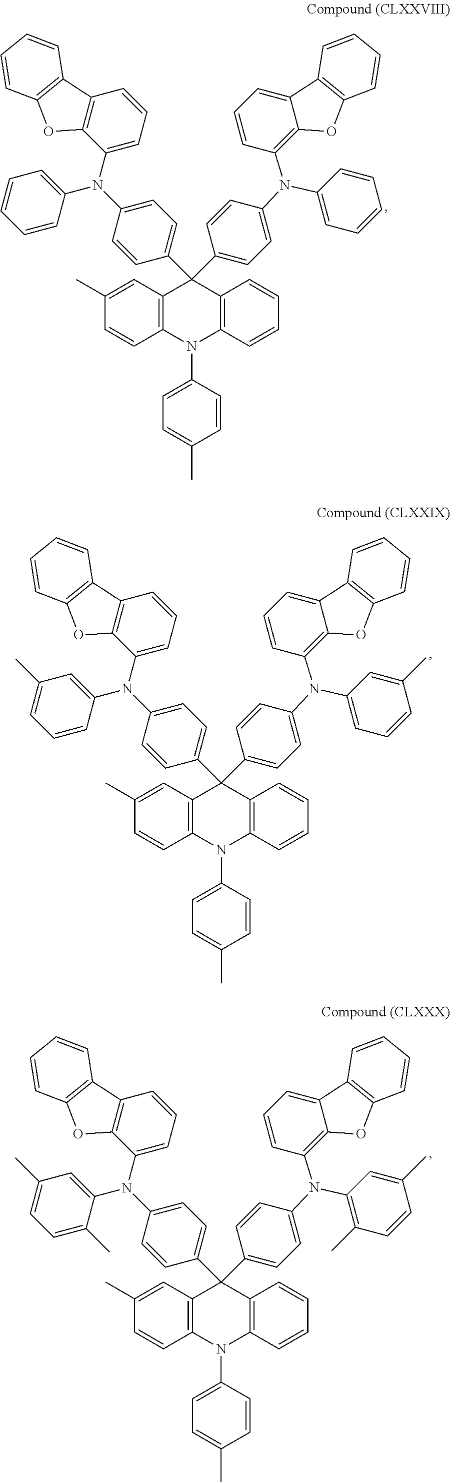

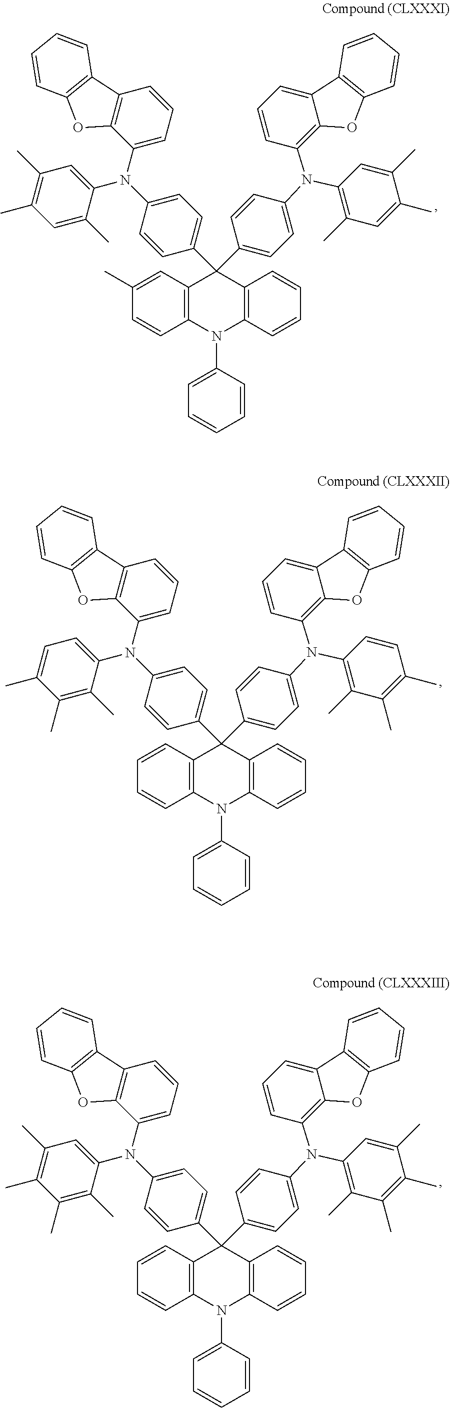

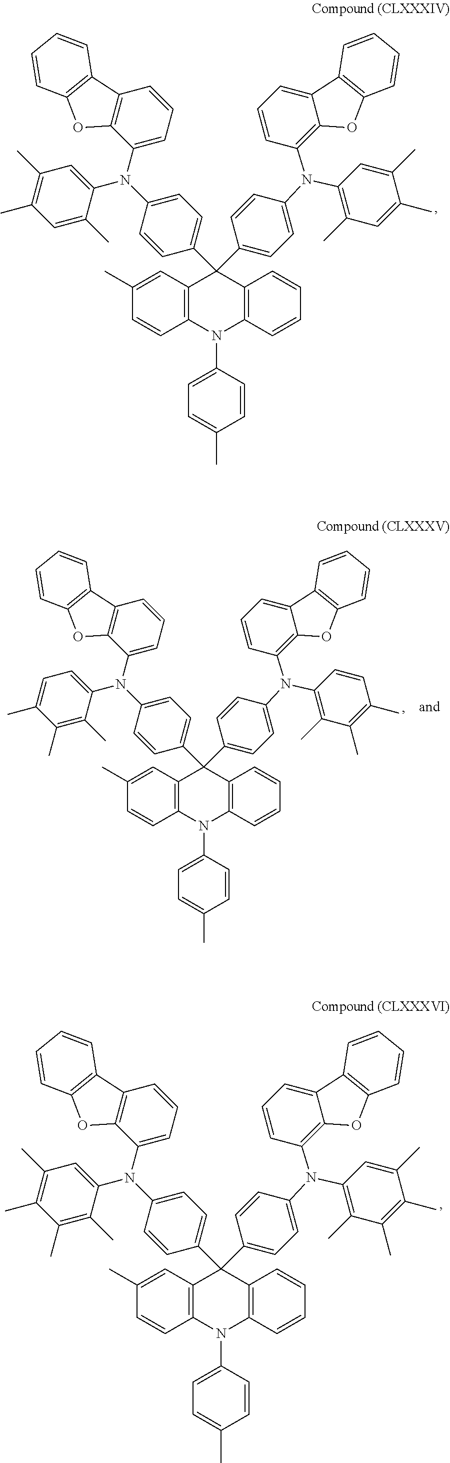

In a second embodiment of the 9,10-dihydroacridine derivative in accordance with the present invention, R⁶ is a substituted or unsubstituted aryl group having 5 to 60 carbon atoms or a substituted or unsubstituted hetroaryl group having 5 to 60 carbon atoms. Preferably, R⁶ is selected from the group consisting of:

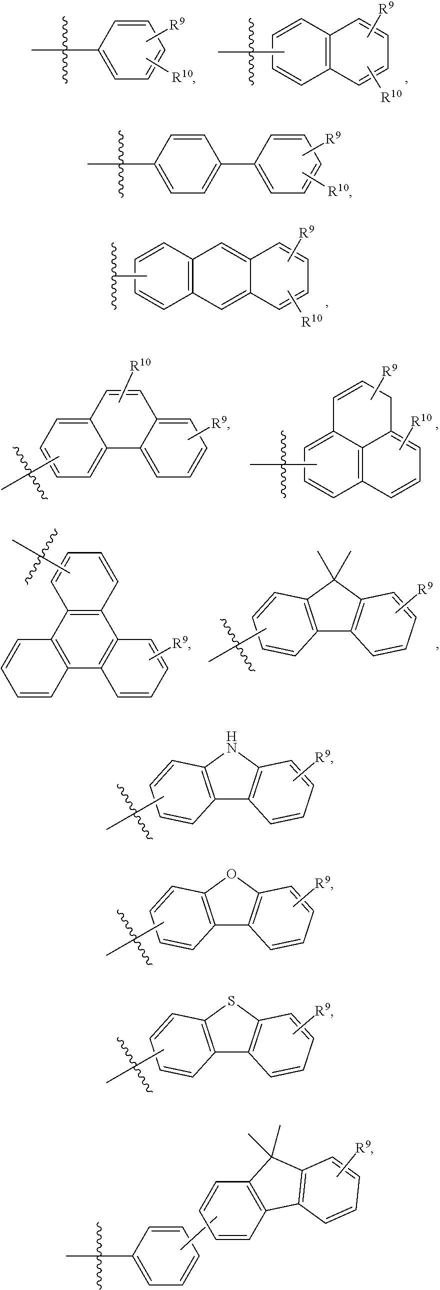

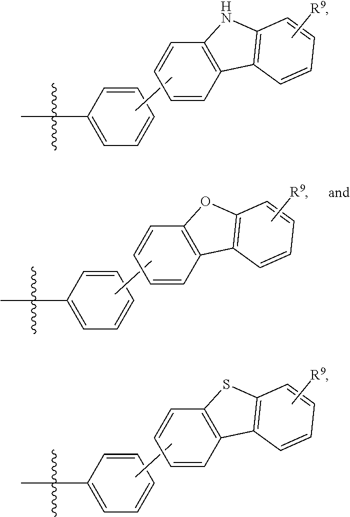

wherein R⁹ and R¹⁰ are identical or different and are each independently a hydrogen group or an alkyl group having 1 to 6 carbon atoms.

In the second embodiment of the 9,10-dihydroacridine derivative in accordance with the present invention, R⁴ and R⁵ are identical or different and are each independently selected from the group consisting of:

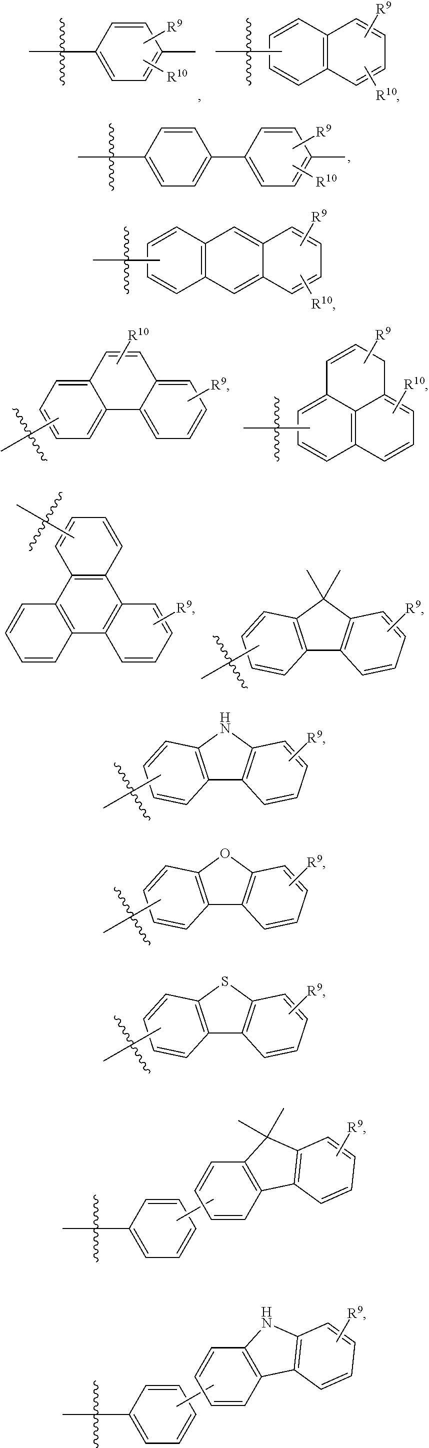

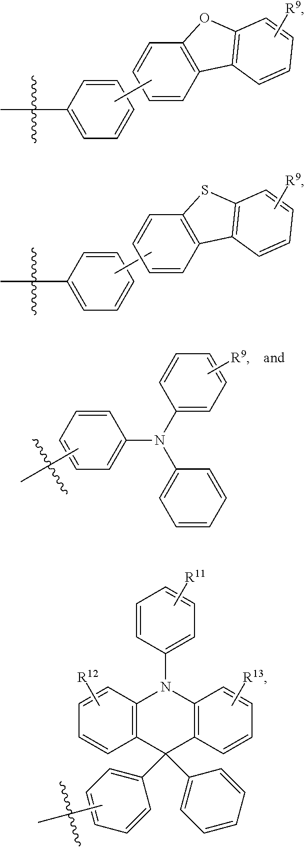

wherein R⁹ and R¹⁰ are identical or different and are each independently a hydrogen group or an alkyl group having 1 to 6 carbon atoms, and R¹¹, R¹², and R¹³ are identical or different and are each independently a hydrogen group or an alkyl group having 1 to 3 carbon atoms.

More preferably, R⁴ is

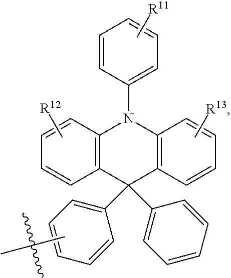

both of R⁵ and R⁶ are phenyl groups, and R¹¹, R¹², and R¹³ are identical or different and are each independently a hydrogen group or an alkyl group having 1 to 3 carbon atoms, wherein R¹¹ is identical with R¹, R¹² is identical with R², and R¹³ is identical with R³ as well. The 9,10-dihydroacridine derivative in accordance with the second embodiment of the present invention also has a symmetrical chemical structure.

Several illustrative examples of the 9,10-dihydroacridine derivative in accordance with the first embodiment of the present invention are, but not limited to:

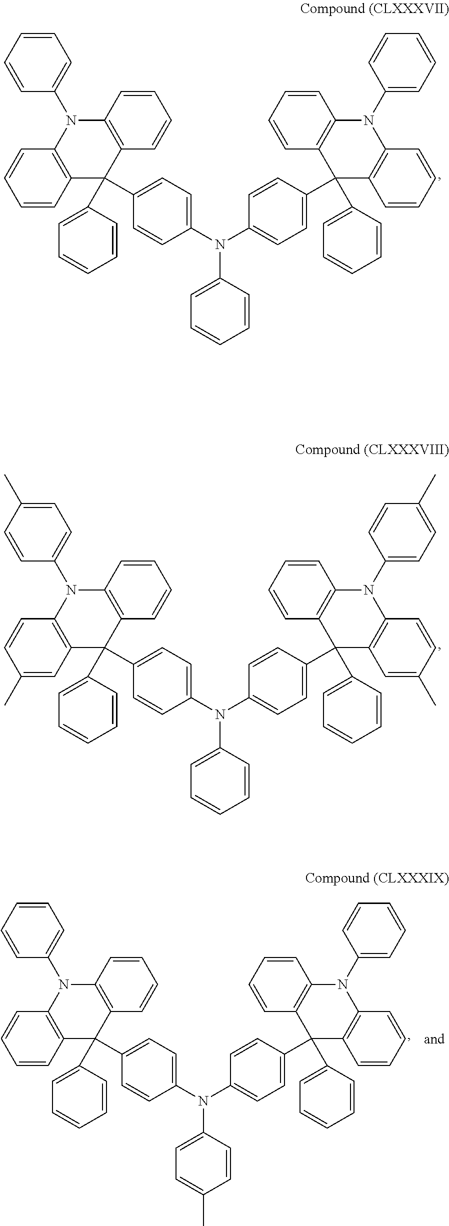 [SMILES: c1ccc(N(c2ccc(C3(c4ccccc4)c4ccccc4N(c4ccccc4)c4ccccc43)cc2)c2ccc(C3(c4ccccc4)c4ccccc4N(c4ccccc4)c4ccccc43)cc2)cc1 ; Cc1ccc(N2c3ccccc3C(c3ccccc3)(c3ccc(N(c4ccccc4)c4ccc(C5(c6ccccc6)c6ccccc6N(c6ccc(C)cc6)c6ccc(C)cc65)cc4)cc3)c3cc(C)ccc32)cc1 ; Cc1ccc(N(c2ccc(C3(c4ccccc4)c4ccccc4N(c4ccccc4)c4ccccc43)cc2)c2ccc(C3(c4ccccc4)c4ccccc4N(c4ccccc4)c4ccccc43)cc2)cc1]

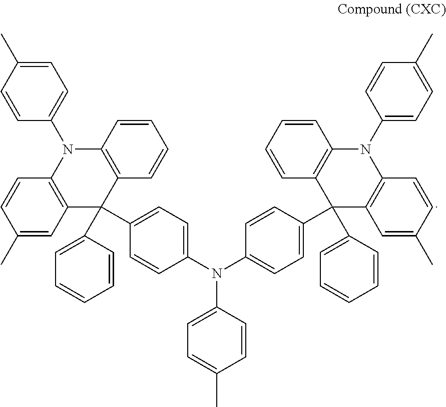 [SMILES: Cc1ccc(N(c2ccc(C3(c4ccccc4)c4ccccc4N(c4ccc(C)cc4)c4ccc(C)cc43)cc2)c2ccc(C3(c4ccccc4)c4ccccc4N(c4ccc(C)cc4)c4ccc(C)cc43)cc2)cc1]

With the aromaticity, the illustrative examples of 9,10-dihydroacridine derivative as mentioned above in both of the first and second embodiments have improved luminescence efficiencies and enhanced conductivities. Accordingly, the 9,10-dihydroacridine derivative in accordance with the present invention is suitable as a hole transport material, a hole injection material, or an emission material in OLEDs.

Another objective of the present invention is to provide an OLED with improved optical performance.

To achieve the objective, the present invention provides an organic light emitting device comprising the 9,10-dihydroacridine derivative as described above.

In accordance with the present invention, the 9,10-dihydroacridine derivative may be used as a hole transport material, a hole injection material, or an emission material. Preferably, the 9,10-dihydroacridine derivative is used as a hole transport material.

Preferably, the OLED comprises: a first electrode; a hole injection layer formed on the first electrode; a first hole transport layer formed on the hole injection layer, wherein the first hole transport layer is made of the 9,10-dihydroacridine derivative; an emission layer formed on the first hole transport layer; an electron transport layer formed on the emission layer; an electron injection layer formed on the electron transport layer; and a second electrode formed on the electron injection layer.

Preferably, the 9,10-dihydroacridine derivative may be selected from the group consisting of, but not limited to: Compounds (I) to (III), (XIX), (LXXXV), (CXXVI), (CLXIV), (CLXXV), (XXII), (XXIII), and (CLXXXVII).

Preferably, the OLED comprises a second hole transport layer formed between the hole injection layer and the first hole transport; or alternatively, formed between the first hole transport layer and the emission layer.

Preferably, the OLED comprises a hole blocking layer formed between the electron transport layer and the emission layer, to block holes overflow from the emission layer to the electron transport layer. Said hole blocking layer may be made of 2,9-dimethyl-4,7-diphenyl-1,10-phenanthroline (BCP) or 2,3,5,6-tetramethyl-phenyl-1,4-(bis-phthalimide) (TMPP), but not limited thereto.

Preferably, the OLED comprises electron blocking layer formed between the hole transport layer and the emission layer, to block electrons overflow from the emission layer to the hole transport layer. Said electron blocking layer may be made of 9,9′-[1,1′-biphenyl]-4,4′-diylbis-9H-carbazole (CBP) or 4,4′,4″-tri(N-carbazolyl)-triphenylamine (TCTA), but not limited thereto.

In the presence of such a hole blocking layer and/or a electron blocking layer in an OLED, the OLED has a higher efficiencies compared to a typical OLED lacking of the hole blocking layer and/or the electron blocking layer.

In addition to the 9,10-dihydroacridine derivative, said first and second hole transport layers are optionally mixed with another hole transport material, for example, but not limited to: N¹,N^{1′}-(biphenyl-4,4′-diyl)bis(N¹-(naphthalen-1-yl)-N⁴,N^{4′}-diphenylbenzene-1,4-diamine); or N⁴,N^{4′}-di(naphthalen-1-yl)-N⁴,N^{4′}-diphenylbiphenyl-4,4′-diamine (NPB).

In addition to the 9,10-dihydroacridine derivative, said hole injection layer is optionally mixed with another hole injection material, for example, but not limited to, polyaniline or polyethylenedioxythiophene.

Said emission layer can be made of an emission material including a host and a dopant. The host of the emission material is, for example, but not limited to: the 9,10-dihydroacridine derivative or 9-(4-(naphthalen-1-yl)phenyl)-10-(naphthalen-2-yl) anthracene.

In blue OLEDs, the dopant of the emission material is, for example, but not limited to: diaminoflourenes; diaminoanthracenes; diaminopyrenes; or organicmetallic compounds of iridium (II) having phenylpyridine ligands.

In green OLEDs, the dopant of the emission material is, for example, but not limited to: diaminoflourenes; diaminoanthracenes; or organometallic compounds of iridium (II) having phenylpyridine ligands.

In red OLEDs, the dopant of the emission material is, for example, but not limited to: organometallic compounds of iridium (II) having perylene ligands, fluoranthene ligands or periflanthene ligands.

With various host materials of the emission layer, the OLED can emit lights in red, green or blue.

Said electron transport layer may be made of an electron transport material, for example, but not limited to:
2-(4-(9,10-di(naphthalen-2-yl)anthracen-2-yl)phenyl)-1-phenyl-1H-benzo[d]imidazole;
bis(2-methyl-8quinolinolato)(p-phenylphenolato) aluminum; or
2-(4-buphenylyl)-5-(4-tert-butylphenyl)-1,3,4-oxadiazole.

Said electron injection layer may be made of an electron injection material, for example, but not limited to (8-oxidonaphthalen-1-yl)lithium(II).

Said first electrode is, for example, but not limited to, an indium-doped tin oxide electrode.

Said second electrode has a work function lower than that of the first electrode. The second electrode is, for example, but not limited to, an aluminum electrode, an indium electrode, or a magnesium electrode.

Other objectives, advantages and novel features of the invention will become more apparent from the following detailed description when taken in conjunction with the accompanying drawings.

### BRIEF DESCRIPTION OF THE DRAWINGS

FIG. 1A is a ¹H nuclear magnetic resonance (NMR) spectrum of Intermediate (1);

FIGS. 1B and 1C are detailed spectra from 6.2 ppm to 7.8 ppm of FIG. 1A of Intermediate (1);

FIG. 2A is a ¹H NMR spectrum of Intermediate (2);

FIGS. 2B and 2C are detailed spectra from 6.0 ppm to 7.5 ppm of FIG. 2A of Intermediate (2);

FIG. 3A is a ¹H NMR spectrum of Intermediate (3);

FIGS. 3B and 3C are detailed spectra from 6.2 ppm to 7.8 ppm of FIG. 3A of Intermediate (3);

FIG. 4A is a ¹H NMR spectrum of Compound (I) of Example 1 in accordance with the present invention;

FIGS. 4B and 4C are detailed spectra from 6.5 ppm to 7.8 ppm of FIG. 4A of Compound (I) of Example 1 in accordance with the present invention;

FIG. 5A is a ¹H NMR spectrum of Compound (II) of Example 2 in accordance with the present invention;

FIGS. 5B and 5C are detailed spectra from 6.3 ppm to 7.8 ppm of FIG. 5A of Compound (II) of Example 2 in accordance with the present invention;

FIG. 6A is a ¹H NMR spectrum of Compound (III) of Example 3 in accordance with the present invention;

FIGS. 6B and 6C are detailed spectra from 6.3 ppm to 7.7 ppm of FIG. 6A of Compound (III) of Example 3 in accordance with the present invention;

FIG. 7A is a ¹H NMR spectrum of Compound (XIX) of Example 4 in accordance with the present invention;

FIGS. 7B and 7C are detailed spectra from 6.3 ppm to 7.7 ppm of FIG. 7A of Compound (XIX) of Example 4 in accordance with the present invention;

FIG. 8A is a ¹H NMR spectrum of Compound (LXXXV)) of Example 5 in accordance with the present invention;

FIGS. 8B and 8C are detailed spectra from 6.3 ppm to 7.7 ppm of FIG. 8A of Compound (LXXXV)) of Example 5 in accordance with the present invention;

FIG. 9A is a ¹H NMR spectrum of Compound (CXXVI) of Example 6 in accordance with the present invention;

FIGS. 9B and 9C are detailed spectra from 6.3 ppm to 7.7 ppm of FIG. 1A of Compound (CXXVI) of Example 6 in accordance with the present invention;

FIG. 10A is a ¹H NMR spectrum of Compound (CLXIV) of Example 7 in accordance with the present invention;

FIGS. 10B and 10C are detailed spectra from 6.3 ppm to 8.8 ppm of FIG. 10A of Compound (CLXIV) of Example 7 in accordance with the present invention

FIG. 11A is a ¹H NMR spectrum of Compound (CLXXV) of Example 8 in accordance with the present invention;

FIGS. 11B and 11C are detailed spectra from 6.3 ppm to 8.1 ppm of FIG. 11A of Compound (CLXXV) of Example 8 in accordance with the present invention;

FIG. 12A is a ¹H NMR spectrum of Compound (XXII) of Example 9 in accordance with the present invention;

FIGS. 12B and 12C are detailed spectra from 6.3 ppm to 7.6 ppm of FIG. 12A of Compound (XXII) of Example 9 in accordance with the present invention;

FIG. 13A is a ¹H NMR spectrum of Compound (XXIII) of Example 10 in accordance with the present invention;

FIGS. 13B and 13C are detailed spectra from 6.3 ppm to 8.5 ppm of FIG. 13A of Compound (XXIII) of Example 10 in accordance with the present invention

FIG. 14A is a ¹H NMR spectrum of Compound (CLXXXVII) of Example 11 in accordance with the present invention;

FIGS. 14B and 14C are detailed spectra from 6.7 ppm to 7.6 ppm of FIG. 14A of Compound (CLXXXVII) of Example 11 in accordance with the present invention;

FIG. 15 is a side view of the OLED in accordance with the present invention.

### DETAILED DESCRIPTION OF THE PREFERRED EMBODIMENTS

Hereinafter, one skilled in the arts can easily realize the advantages and effects of a 9,10-dihydroacridine derivative and an organic light emitting device comprising the same in accordance with the present invention from the following examples. Therefore, it should be understood that the descriptions proposed herein are just preferable examples only for the purpose of illustrations, not intended to limit the scope of the invention. Various modifications and variations could be made in order to practice or apply the present invention without departing from the spirit and scope of the invention.

Synthesis of Intermediate (1)

Intermediate (1) used for preparing a 9,10-dihydroacridine derivative was synthesized by following the steps described below. The synthesis pathway of the Intermediate (1) was summarized in Scheme 1.

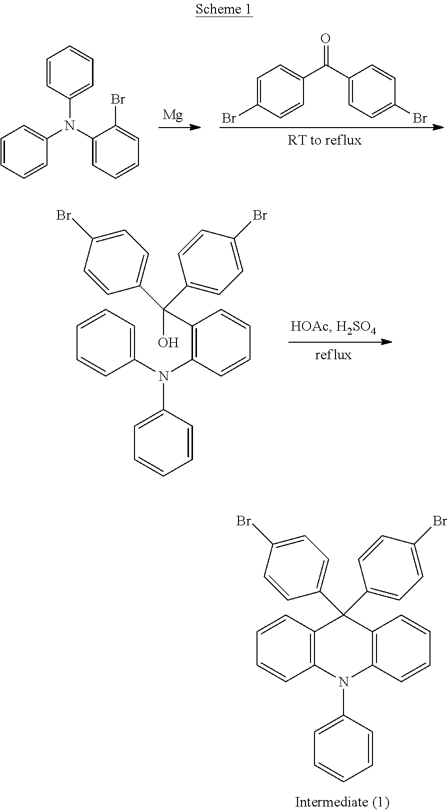

First, magnesium (1.55 grams, 65 millimoles (mmol)) was charged into a two-neck flask and flame-dried. 2-bromo-N,N-diphenylbenzenamine (20.0 grams, 62 mmol) dissolved in 150 millileters (ml) of tetrahydrofuran (THF) was added into the two-neck flask to obtain (2-(diphenylamino)phenyl) magnesium bromide. Then the obtained 2-(diphenylamino)phenyl) magnesium bromide was refluxed for 2 hours under nitrogen atmosphere and then cooled to room temperature.

Next, bis(4-bromophenyl) methanone (18.7 grams, 56 mmol) was rapidly mixed with the obtained (2-(diphenylamino)phenyl) magnesium bromide, and also refluxed for 2 hours to form a reaction mixture.

After cooling the reaction mixture to room temperature, the reaction mixture was neutralized by saturated NH₄Cl solution and then extracted by ethyl acetate. Then the organic layer was dried over magnesium sulfate (MgSO₄) and evaporated. Unreacted starting materials collected in the organic layer were further removed by short liquid column chromatography and then evaporated; the remainder, bis(4-bromophenyl)(2-(diphenylamino)phenyl) methanol, was charged into another two-neck flask, and then 100 ml of acetic acid (HOAc) and 1 ml of concentrated H₂SO₄ were added into the two-neck flask to form another reaction mixture.

Said another reaction mixture was also refluxed for 2 hours, and a white precipitate appeared during the process. After that, the reaction mixture was cooled to room temperature, and the white precipitates were filtered and dried in a vacuum oven to form a product. The product was re-crystallized twice from hot dichloromethane to obtain a white powder with a yield of 82%.

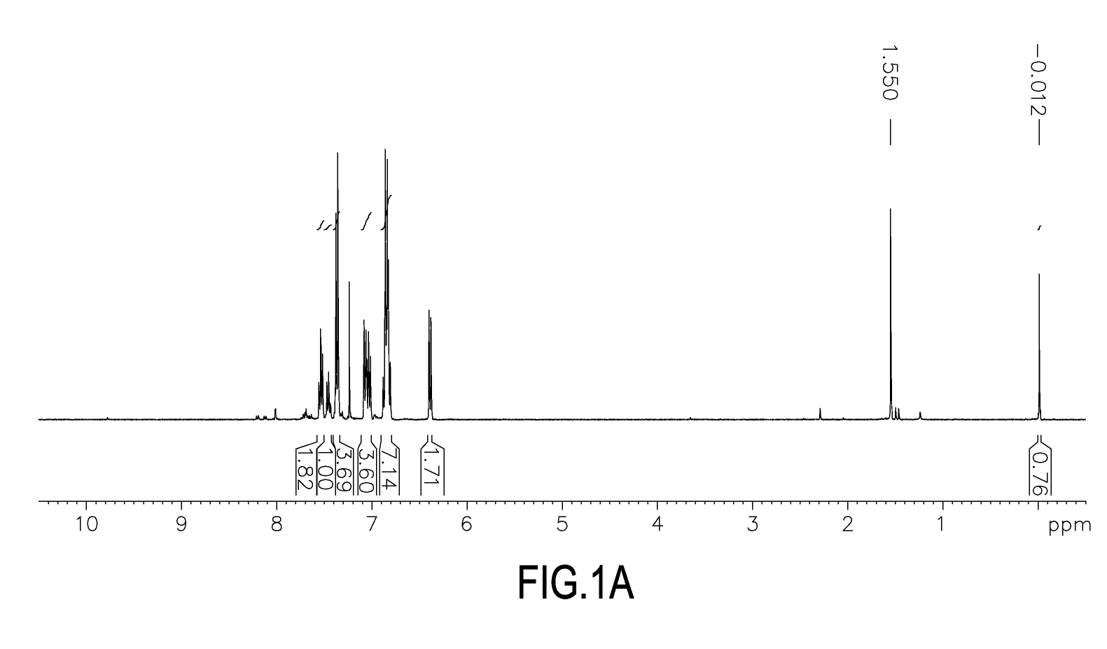

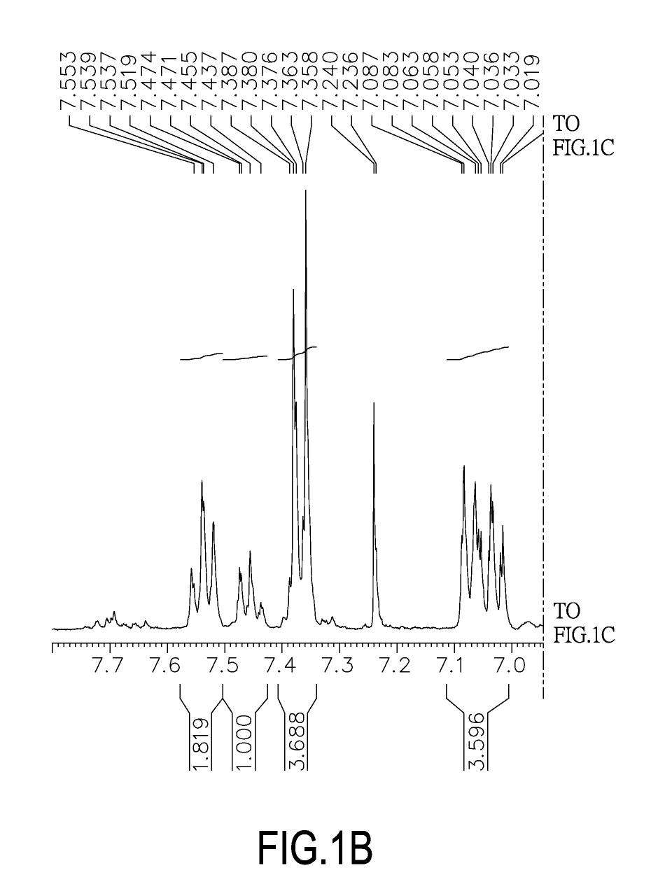

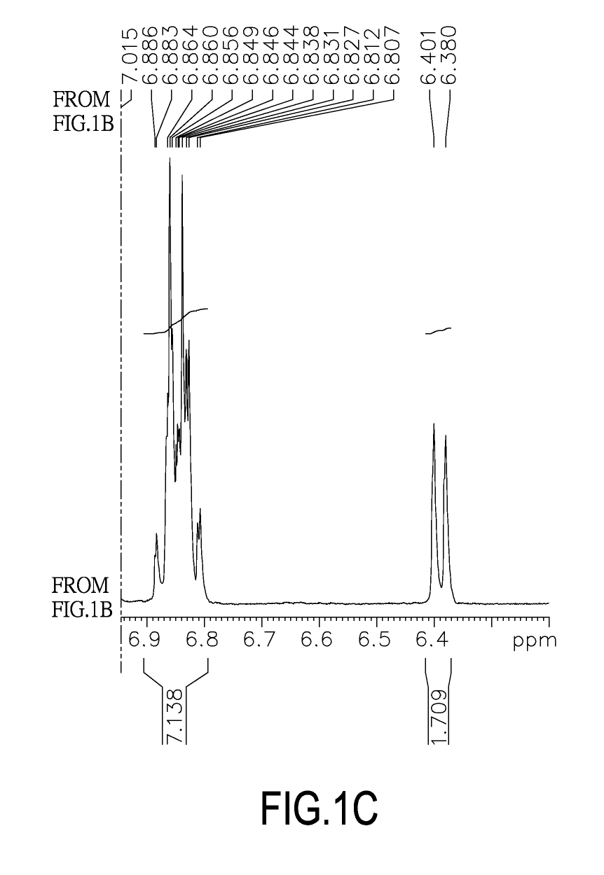

The white powder was characterized by ¹H NMR spectrum (400 MHz, CDCl₃). With reference to FIGS. 1A to 1C, the white powder was identified as Intermediate (1) by ¹H NMR spectroscopy.

Synthesis of Intermediate (2)

Intermediate (2) used for preparing a 9,10-dihydroacridine derivative was synthesized in a similar manner as Intermediate (1), except that 2-bromo-N,N-diphenylbenzenamine was replaced by 2-bromo-N,N-di-(p-tolyl)benzenamine synthesis pathway of Intermediate (2) was summarized in Scheme 2.

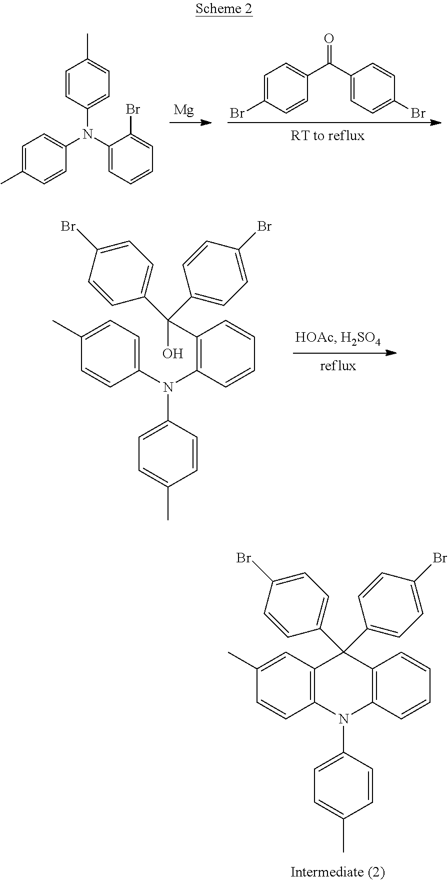

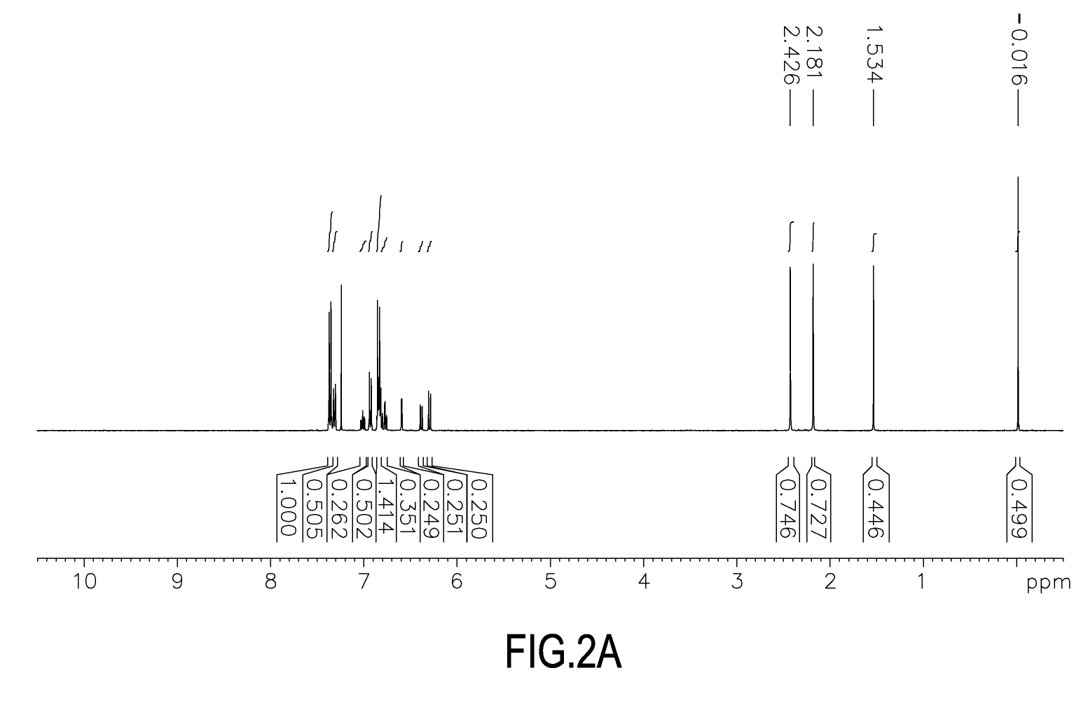

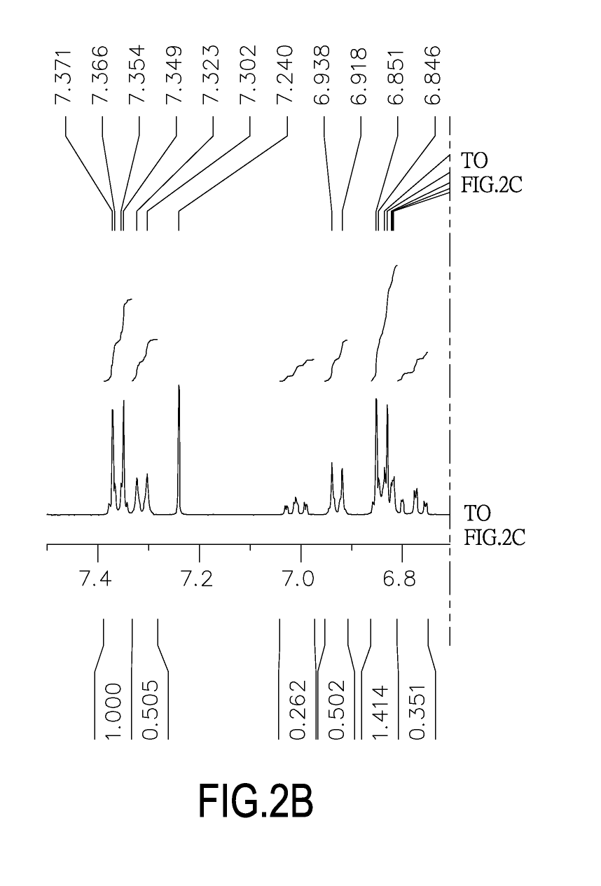

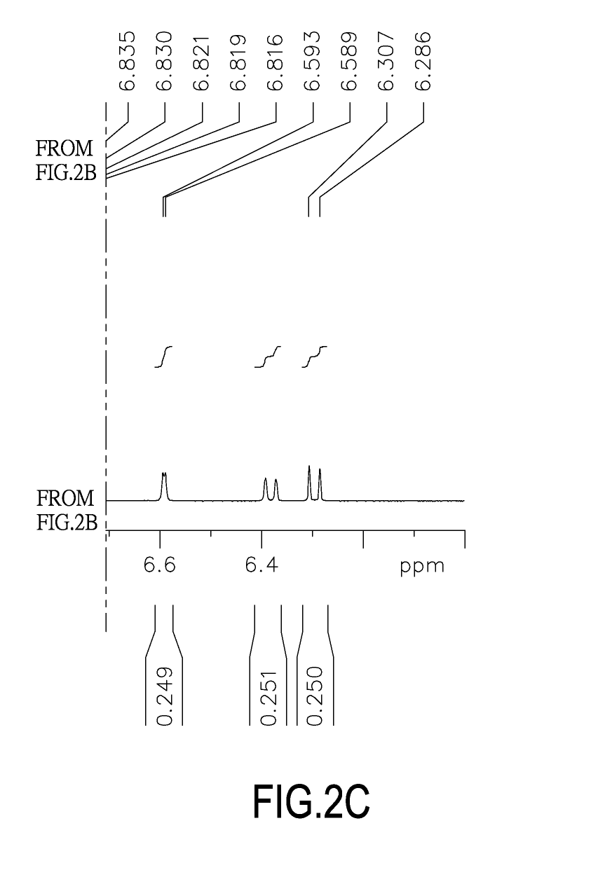

After the synthesis was completed, a white powder was obtained with a yield of 78%. With reference to FIGS. 2A to 2C, the white powder was identified as Intermediate (2) by ¹H NMR spectroscopy (400 MHz, CDCl₃).

Synthesis of Intermediate (3)

Intermediate (3) used for preparing a 9,10-dihydroacridine derivative was synthesized in a similar manner as Intermediate (1), except that bis(4-bromophenyl) methanone was replaced by (4-bromophenyl)(phenyl)methanone. The synthesis pathway of Intermediate (3) was summarized in Scheme 3.

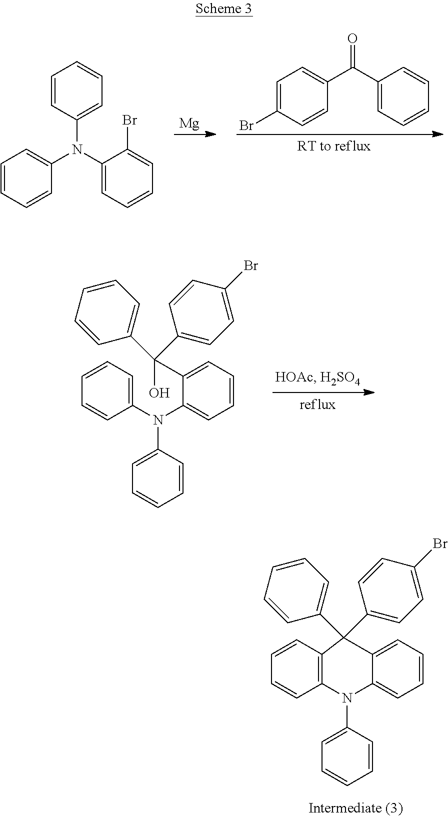

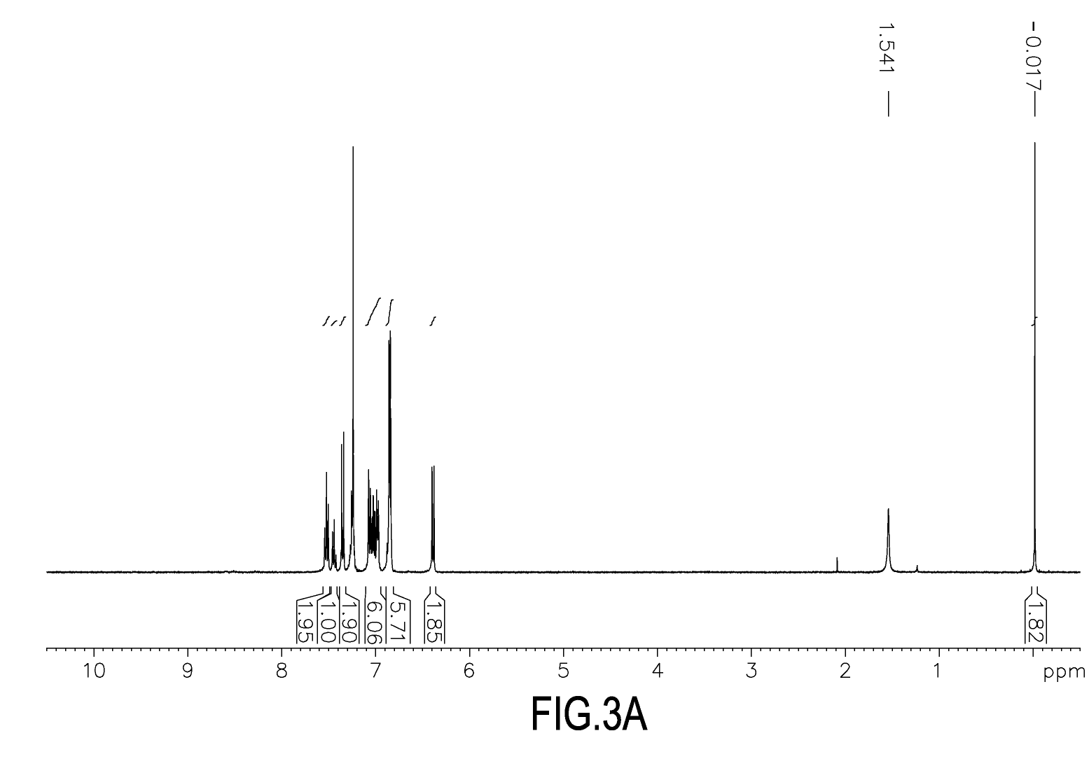

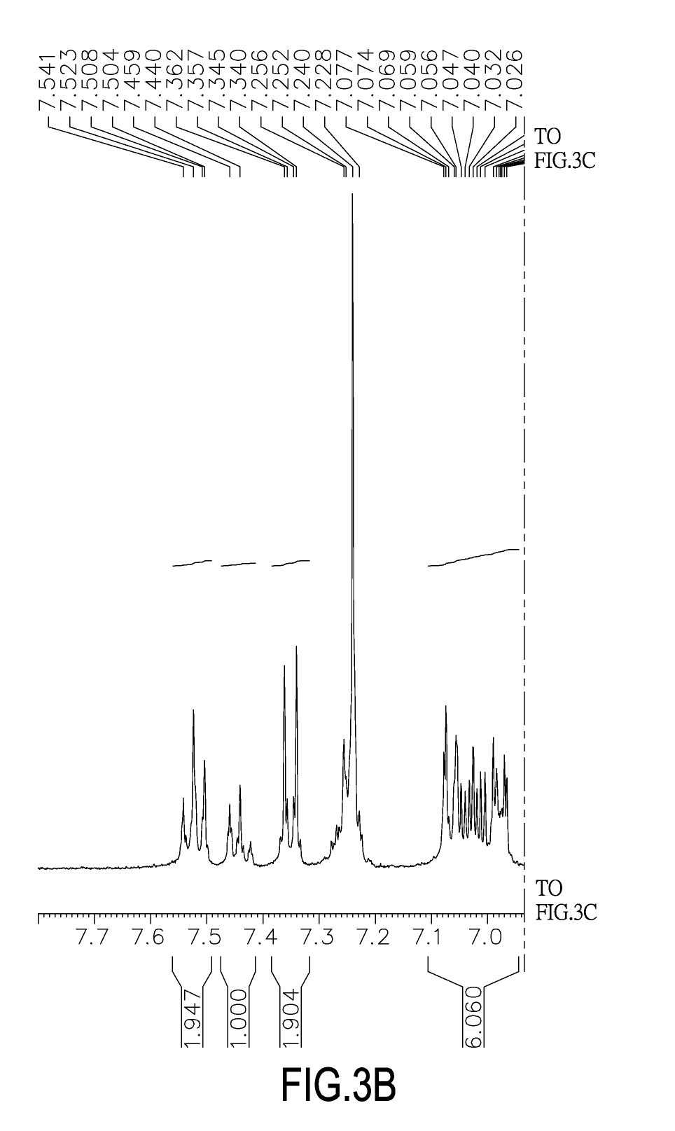

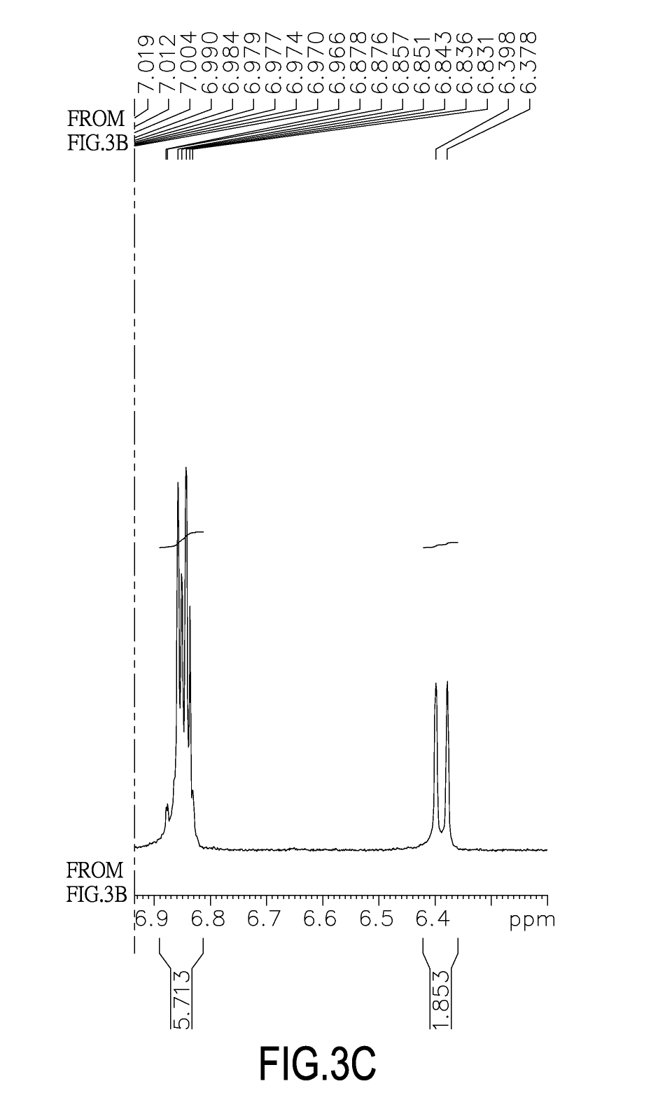

After the synthesis was completed, a white powder was obtained with a yield of 80%. The white powder was also characterized by ¹H NMR spectrum (400 MHz, CDCl₃). With reference to FIGS. 3A to 3C, the white powder was identified as Intermediate (3) by ¹H NMR spectroscopy (400 MHz, CDCl₃).

### Examples 1 to 8

### Preparation of the 9,10-Dihydroacridine Derivatives of the Present Invention

The 9,10-dihydroacridine derivatives of Examples 1 to 8 in accordance with the present invention were prepared by a similar manner as described below. The general synthesis pathway of the 9,10-dihydroacridine derivatives in Examples 1 to 8 was summarized in Scheme 4.

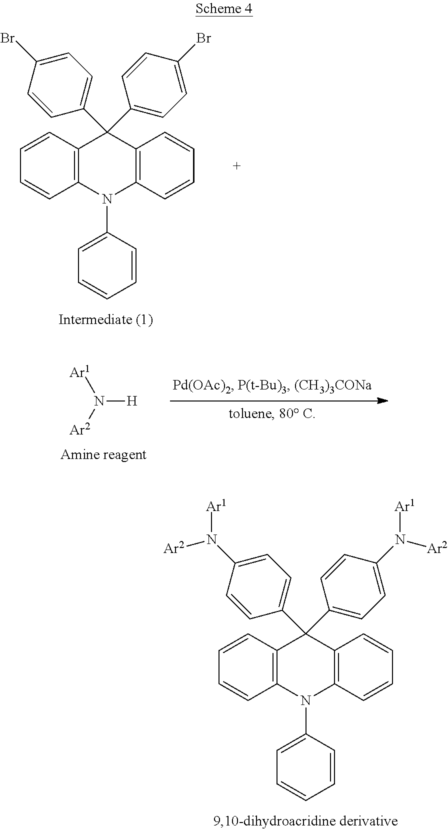

First, 10.0 mmol of Intermediate (1), 24 mmol of amine reagent, 0.2 mmol of Pd(OAc)₂, 0.8 mmol of tri-tert-butylphosphine (P(t-Bu)₃), and 29 mmol of sodiumt-butoxide ((CH₃)₃CONa) were dissolved in 48 ml of toluene to form a reaction mixture. The reaction mixture was stirred at 80° C. for 8 hours and then cooled to room temperature.

Next, the cooled reaction mixture was added to a mixed solution of 60 ml of THF/H₂O (1:1 v/v) for extraction. An organic layer was collected and dried over MgSO₄ and concentrated.

After that, the remainder was purified by column chromatography. Finally, a white powder product was prepared.

The differences among Examples 1 to 8 were amine reagents used for preparing the 9,10-dihydroacridine derivatives. The amine reagents, products, and their respective yields in Examples 1 to 8 were listed in Table 1.

TABLE 1
the amine reagents, products, and their respective yields in Examples 1
to 8

| | Amine Reagent | Product | Yield |
|---|---|---|---|
| Example 1 | 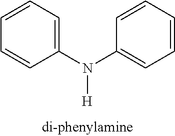 [SMILES: c1ccc(Nc2ccccc2)cc1] | 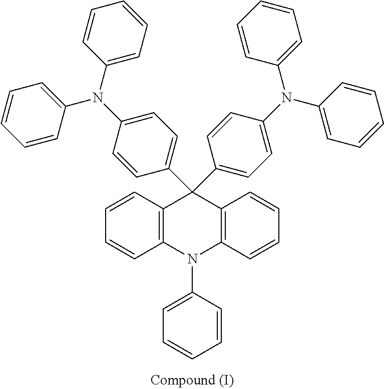 [SMILES: c1ccc(N(c2ccccc2)c2ccc(C3(c4ccc(N(c5ccccc5)c5ccccc5)cc4)c4ccccc4N(c4ccccc4)c4ccccc43)cc2)cc1] | 87% |
| Example 2 | 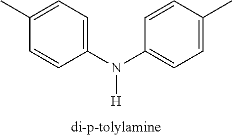 | 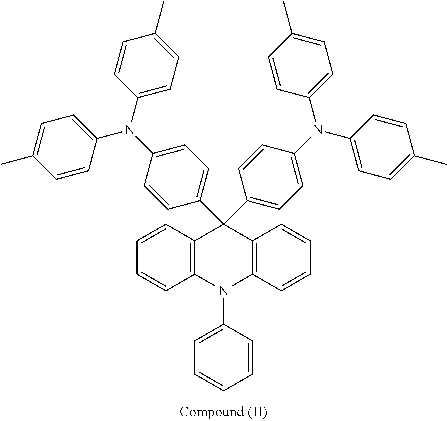 | 83% |
| Example 3 | 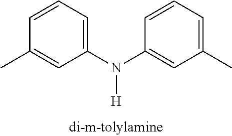 | 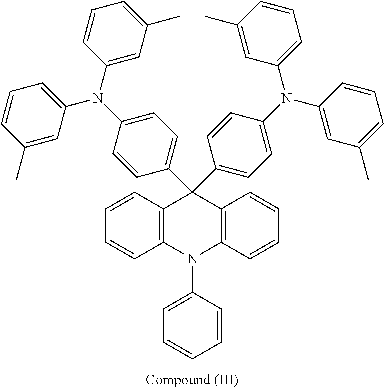 [SMILES: Cc1cccc(N(c2ccc(C3(c4ccc(N(c5cccc(C)c5)c5cccc(C)c5)cc4)c4ccccc4N(c4ccccc4)c4ccccc43)cc2)c2cccc(C)c2)c1] | 82% |
| Example 4 | 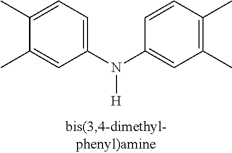 | 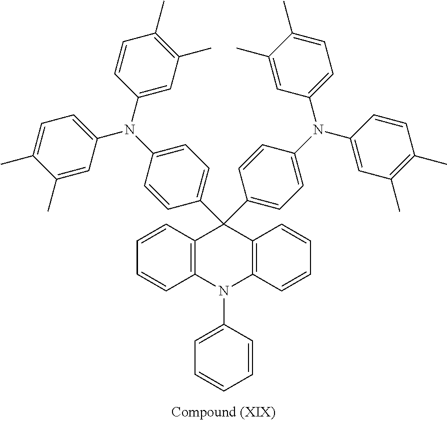 | 76% |
| Example 5 | 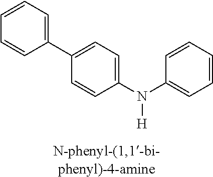 [SMILES: c1ccc(Nc2ccc(-c3ccccc3)cc2)cc1] | 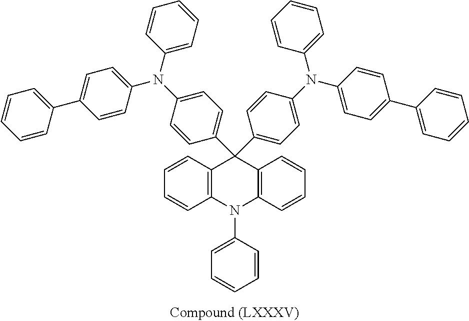 [SMILES: c1ccc(-c2ccc(N(c3ccccc3)c3ccc(C4(c5ccc(N(c6ccccc6)c6ccc(-c7ccccc7)cc6)cc5)c5ccccc5N(c5ccccc5)c5ccccc54)cc3)cc2)cc1] | 78% |
| Example 6 | 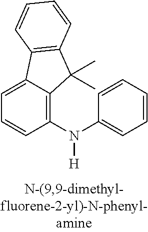 [SMILES: CC1(C)c2ccccc2-c2cccc(Nc3ccccc3)c21] | 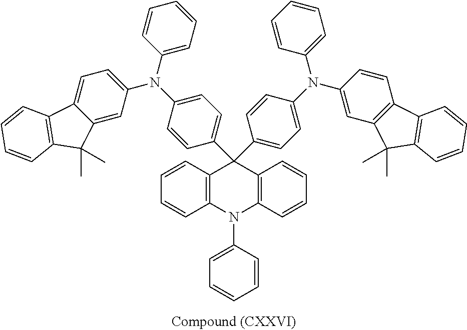 [SMILES: CC1(C)c2ccccc2-c2ccc(N(c3ccccc3)c3ccc(C4(c5ccc(N(c6ccccc6)c6ccc7c(c6)C(C)(C)c6ccccc6-7)cc5)c5ccccc5N(c5ccccc5)c5ccccc54)cc3)cc21] | 75% |
| Example 7 | 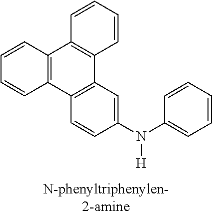 [SMILES: c1ccc(Nc2ccc3c4ccccc4c4ccccc4c3c2)cc1] | 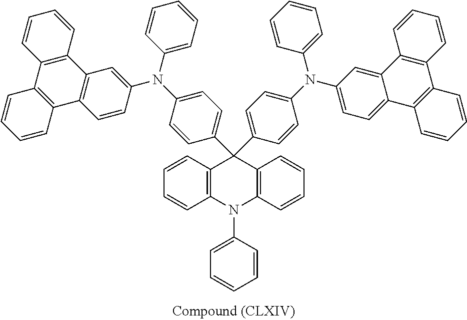 [SMILES: c1ccc(N(c2ccc(C3(c4ccc(N(c5ccccc5)c5ccc6c7ccccc7c7ccccc7c6c5)cc4)c4ccccc4N(c4ccccc4)c4ccccc43)cc2)c2ccc3c4ccccc4c4ccccc4c3c2)cc1] | 75% |
| Example 8 | 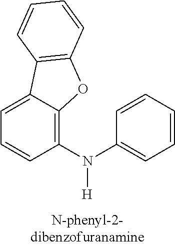 [SMILES: c1ccc(Nc2cccc3c2oc2ccccc23)cc1] | 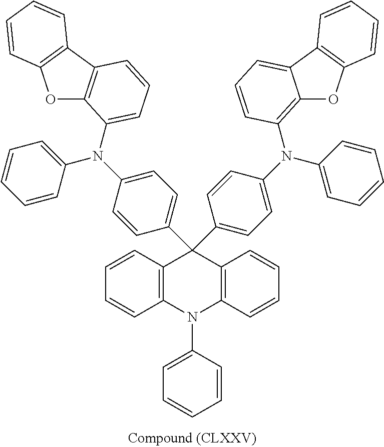 [SMILES: c1ccc(N2c3ccccc3C(c3ccc(N(c4ccccc4)c4cccc5c4oc4ccccc45)cc3)(c3ccc(N(c4ccccc4)c4cccc5c4oc4ccccc45)cc3)c3ccccc32)cc1] | 82% |

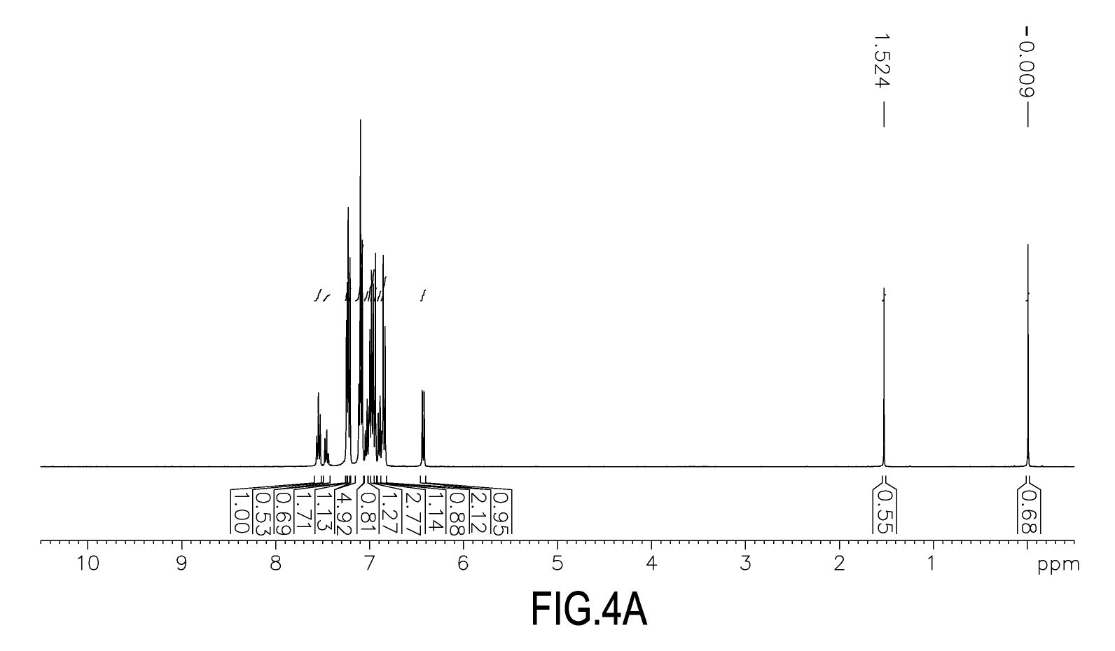

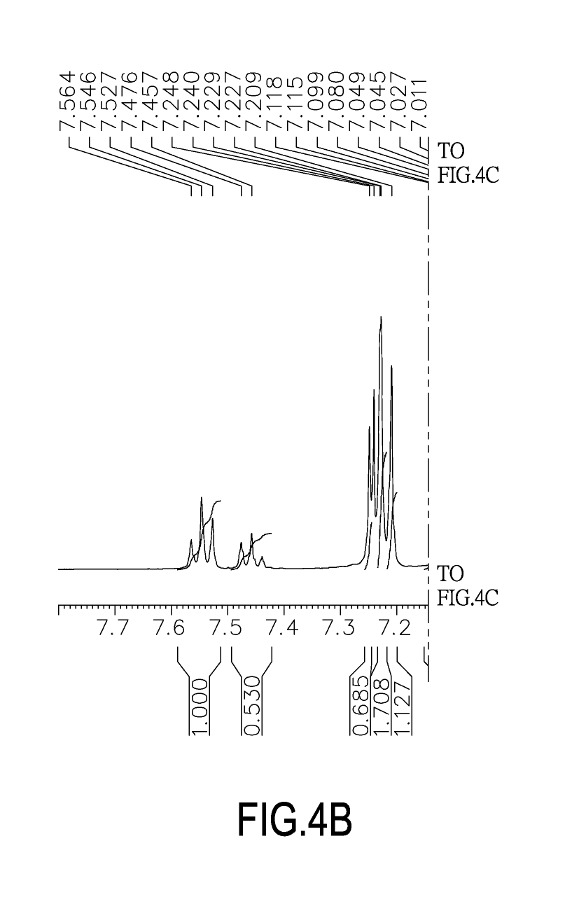

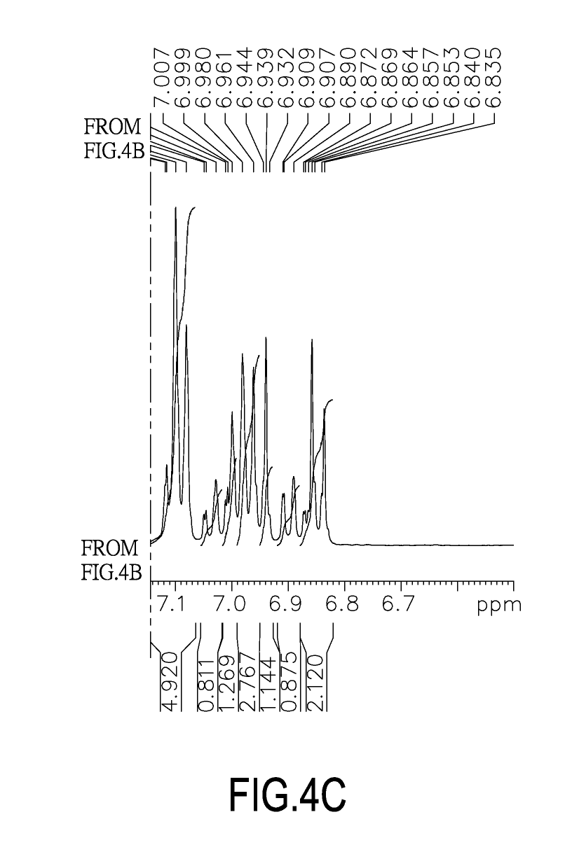

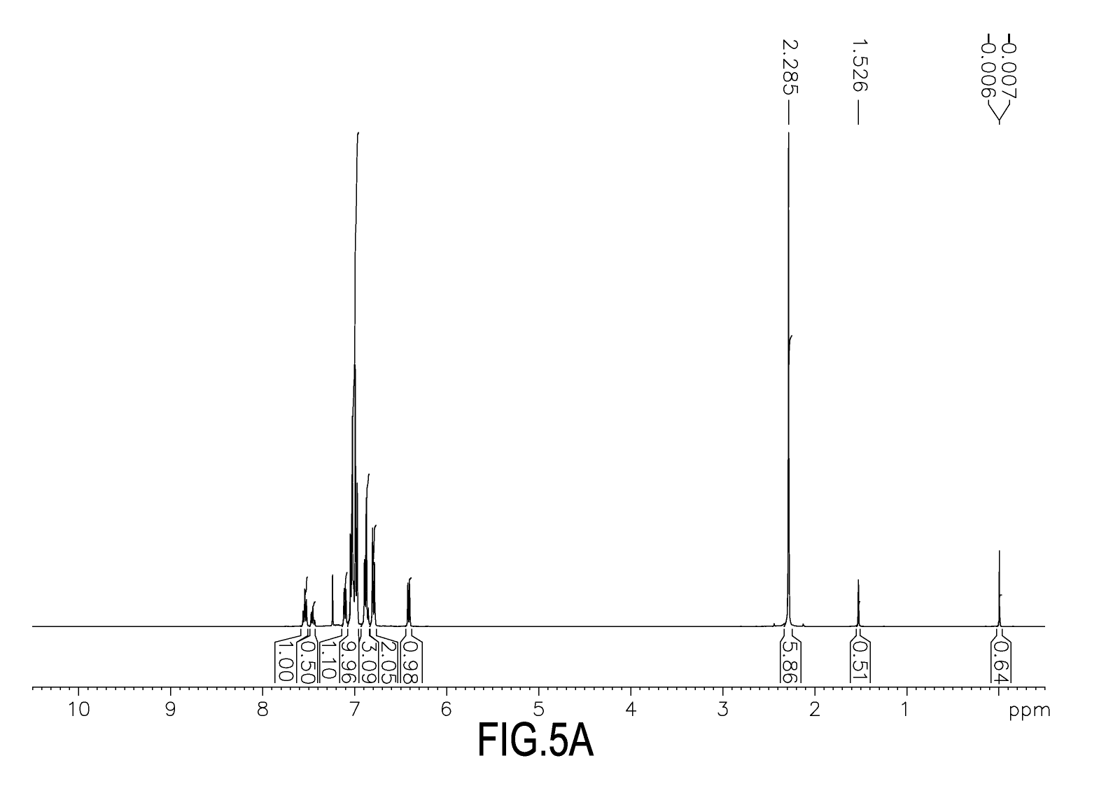

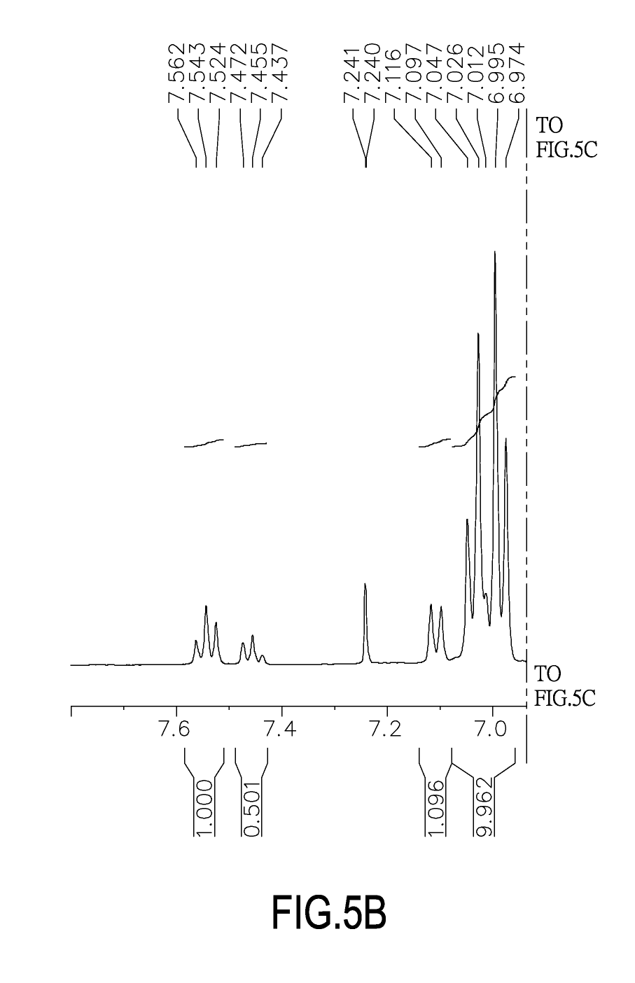

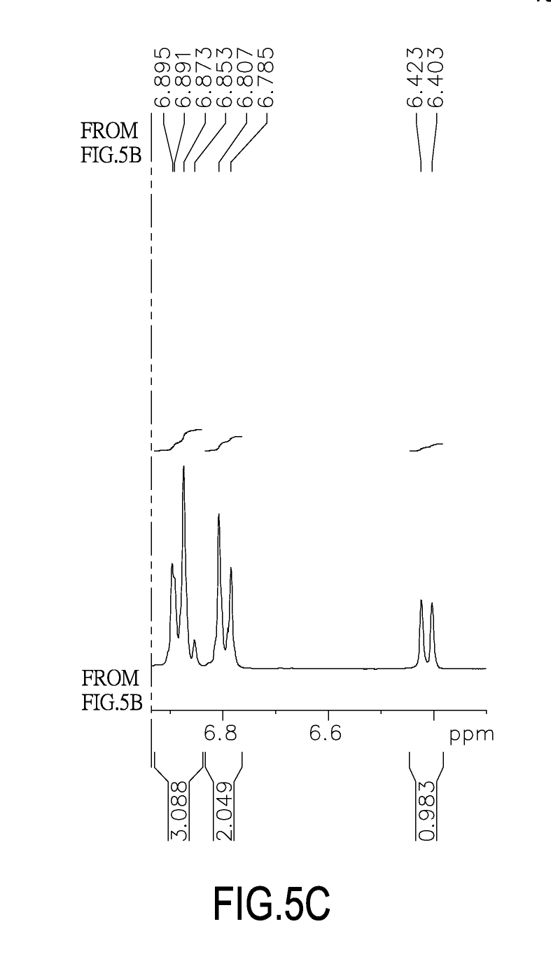

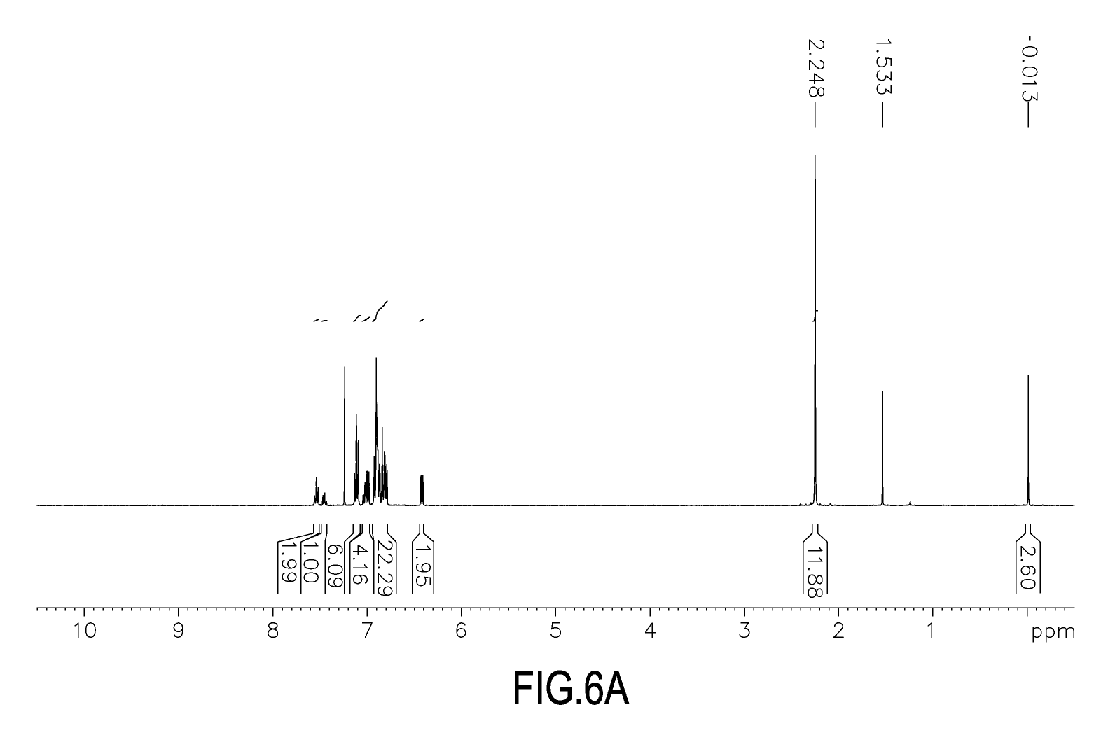

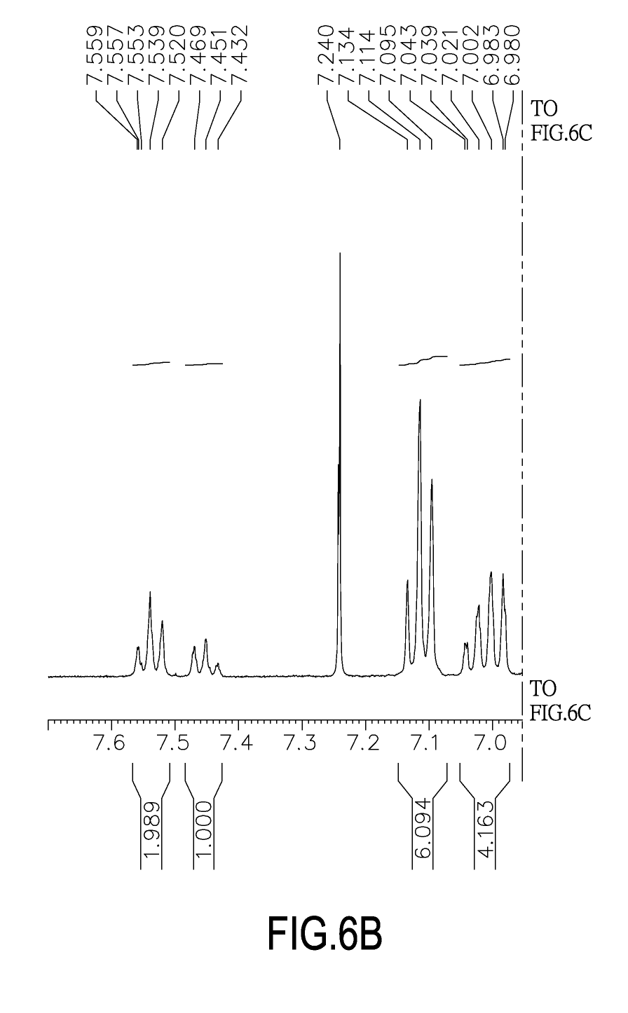

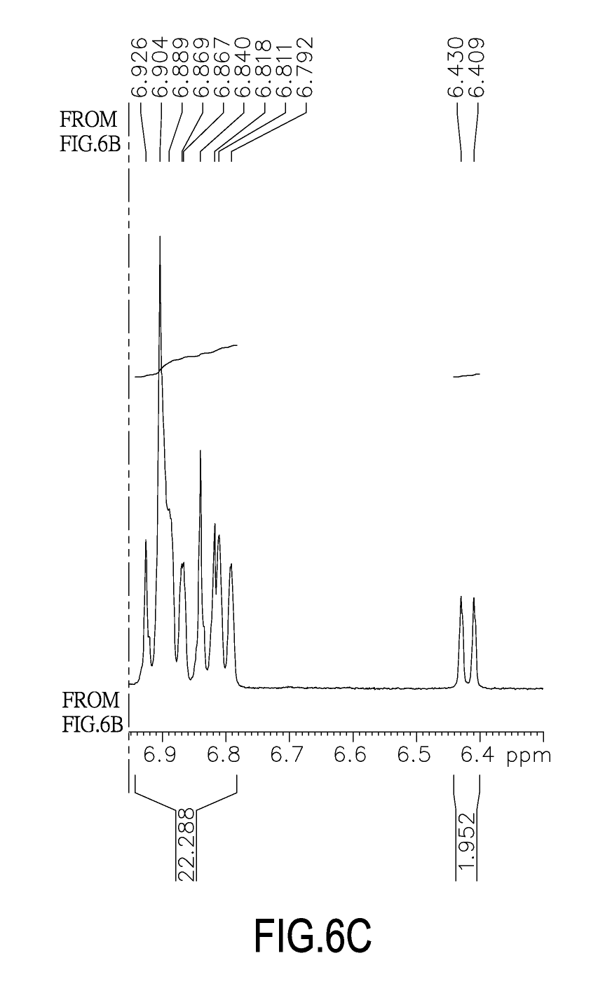

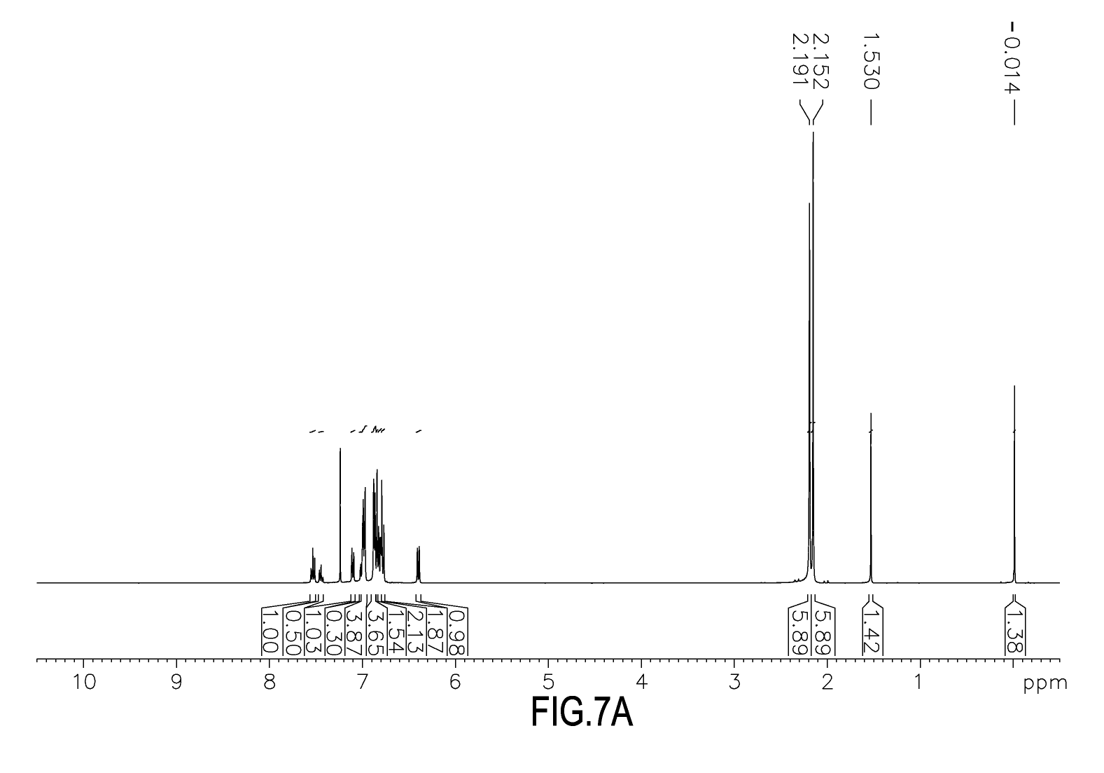

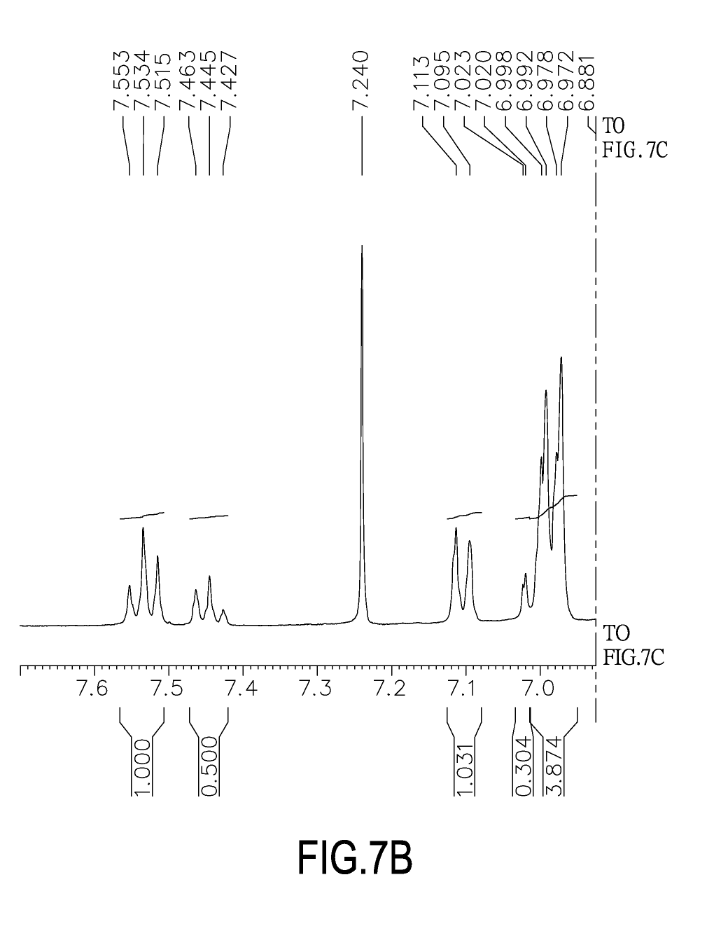

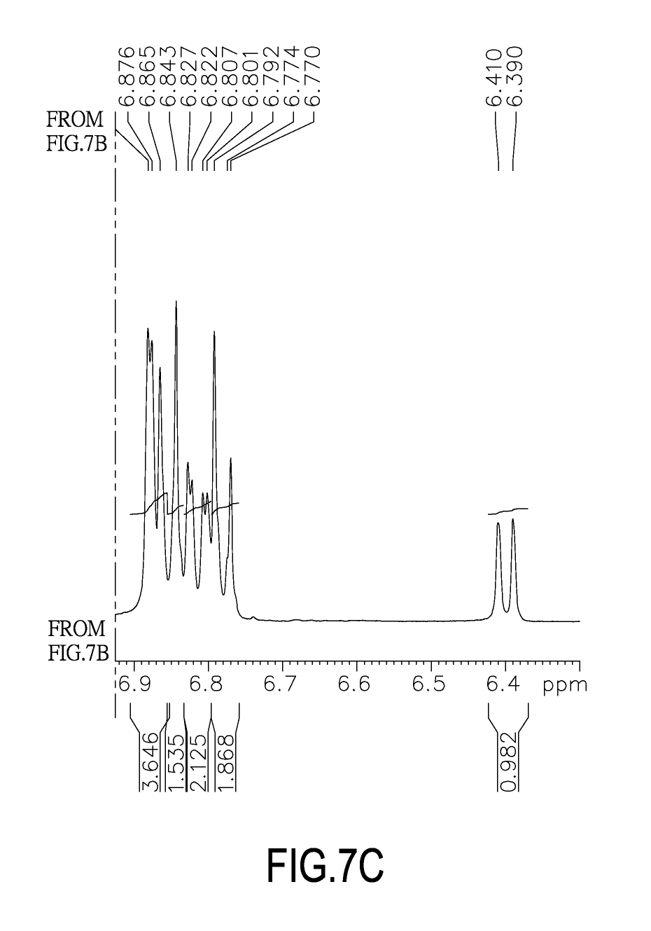

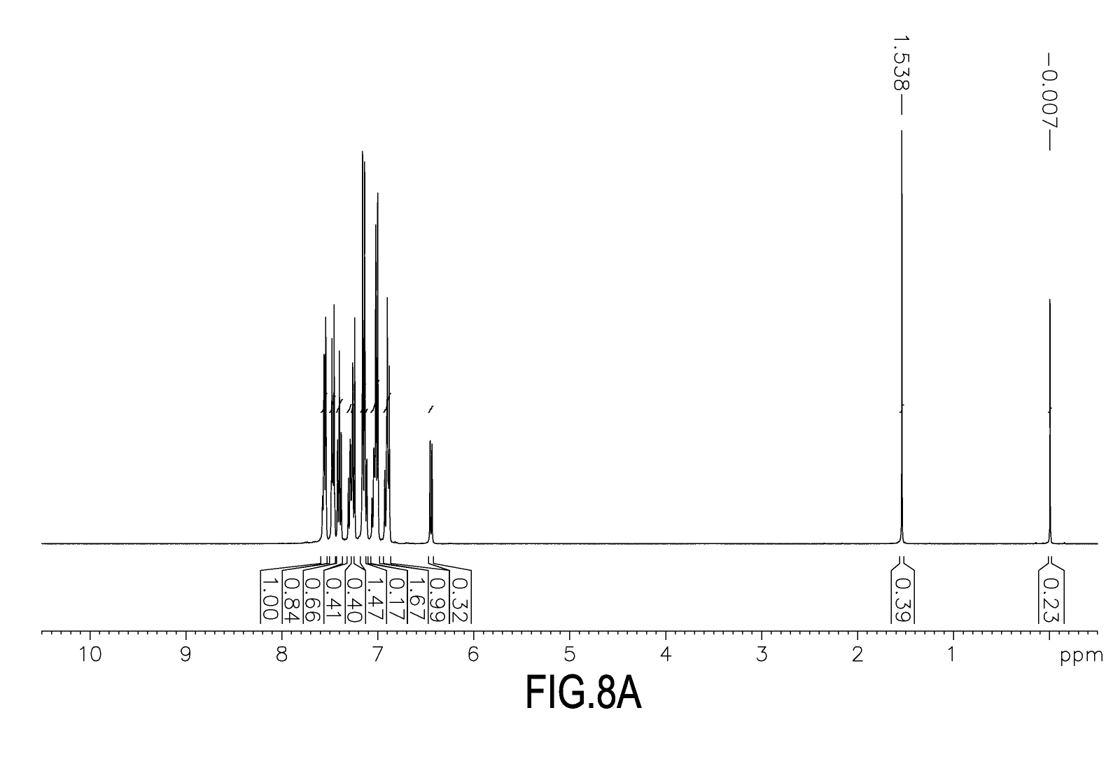

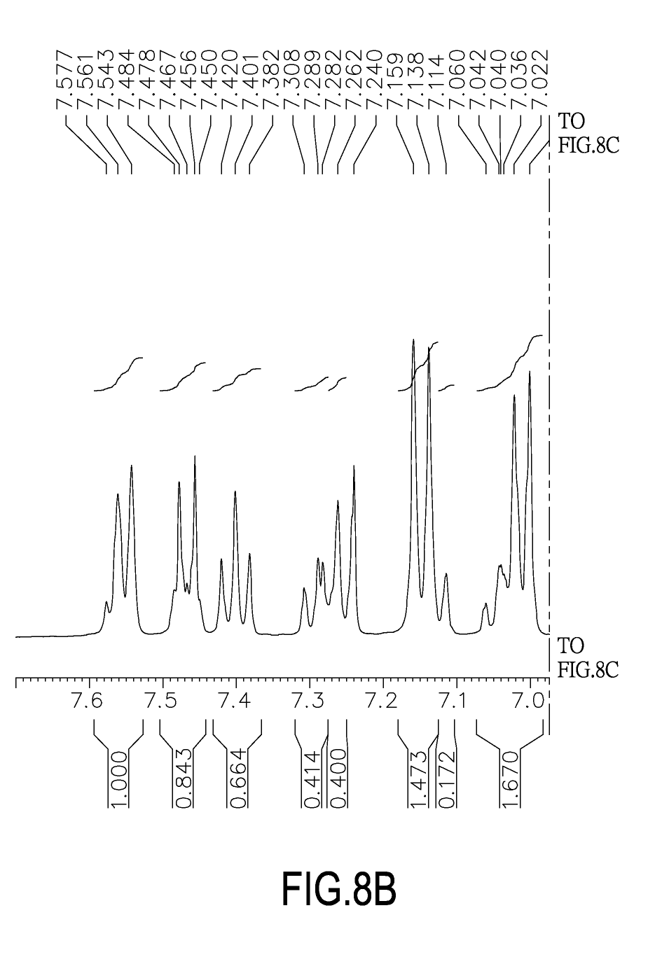

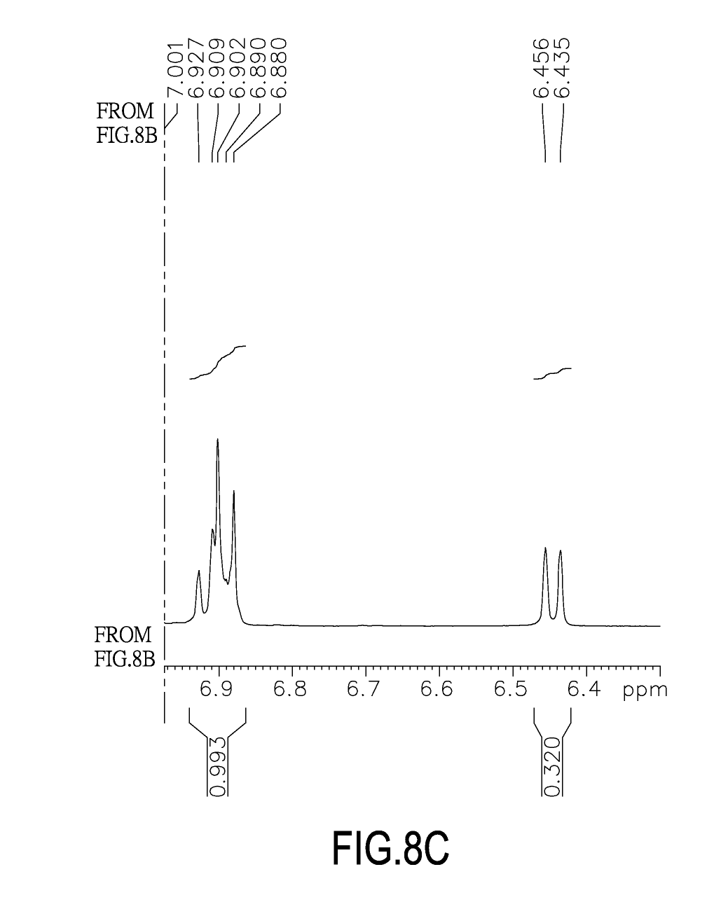

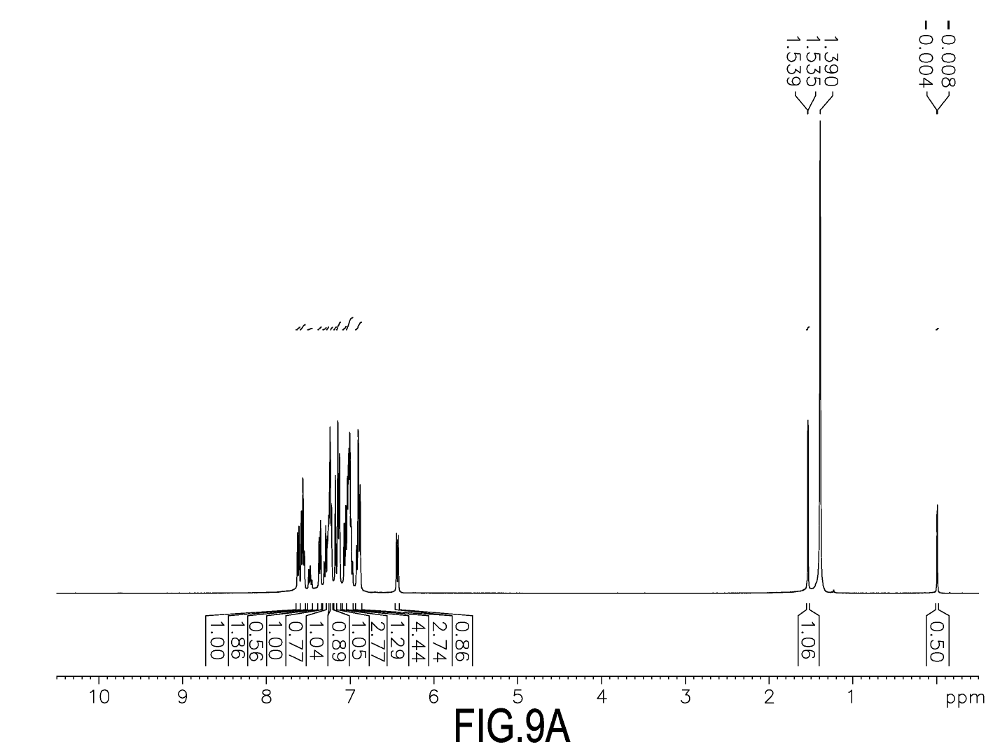

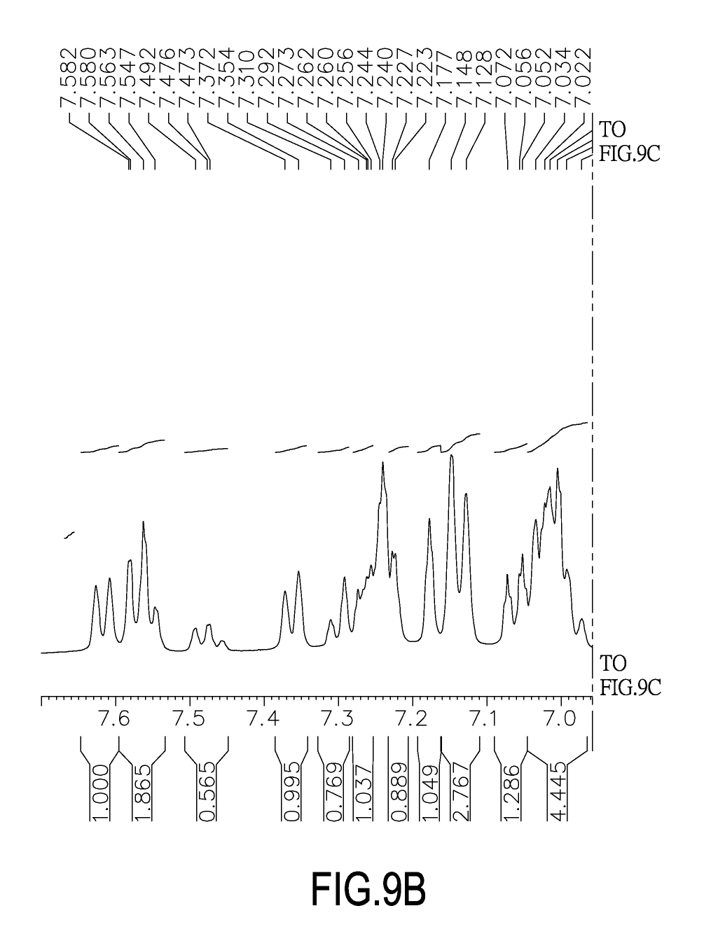

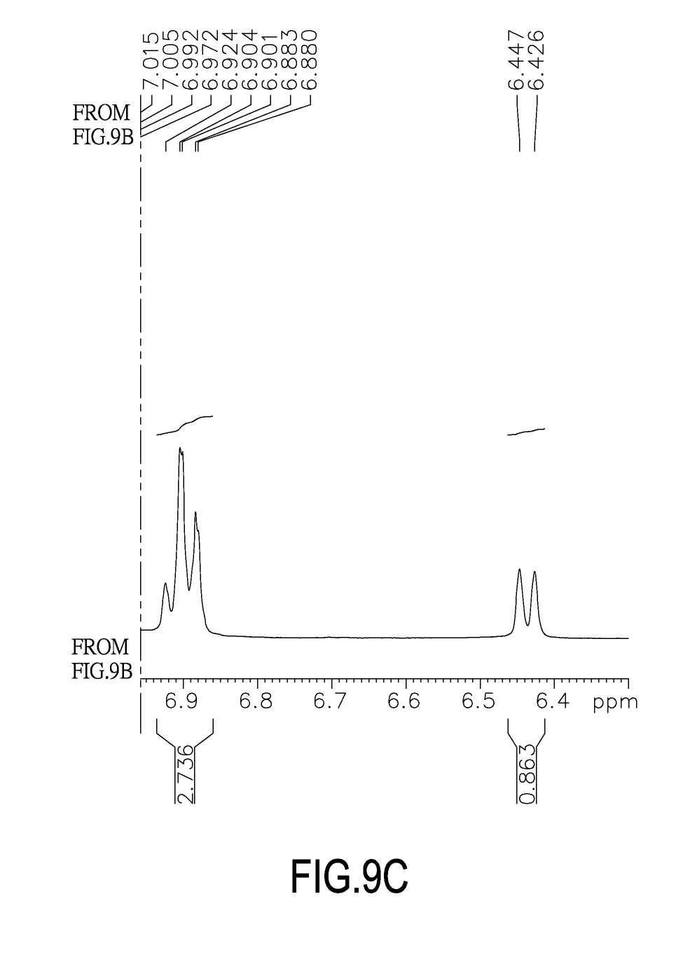

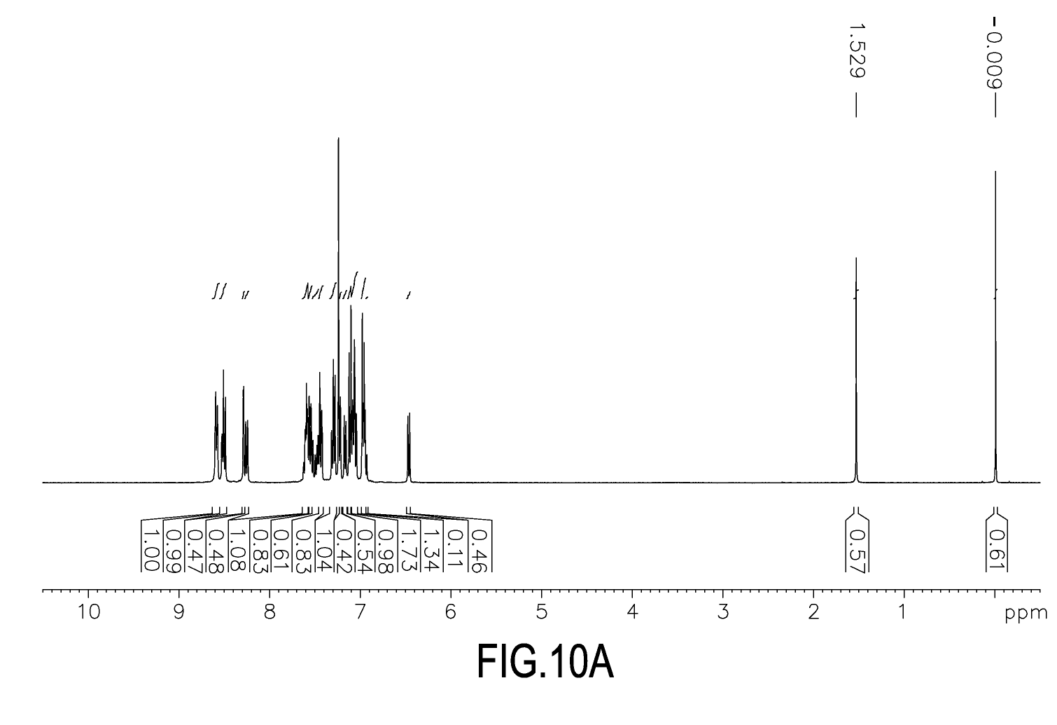

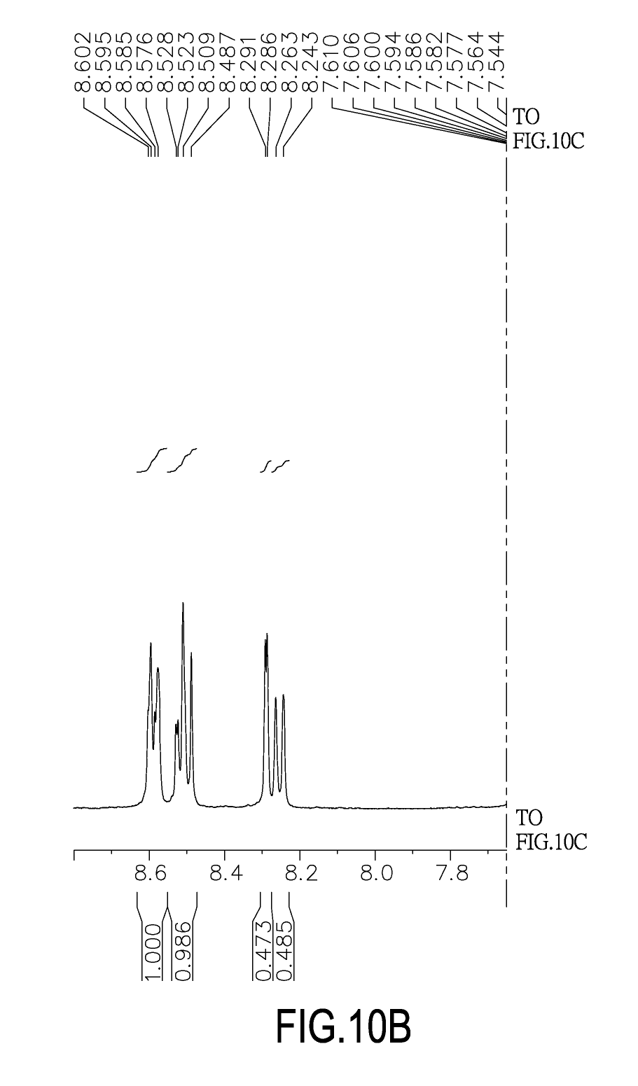

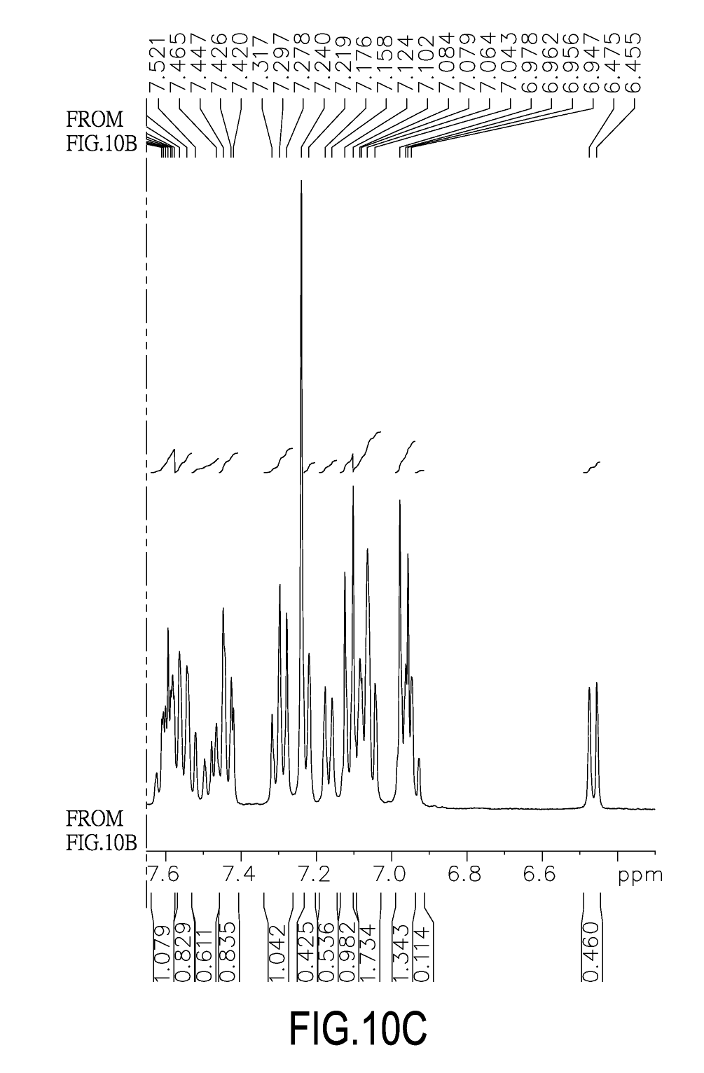

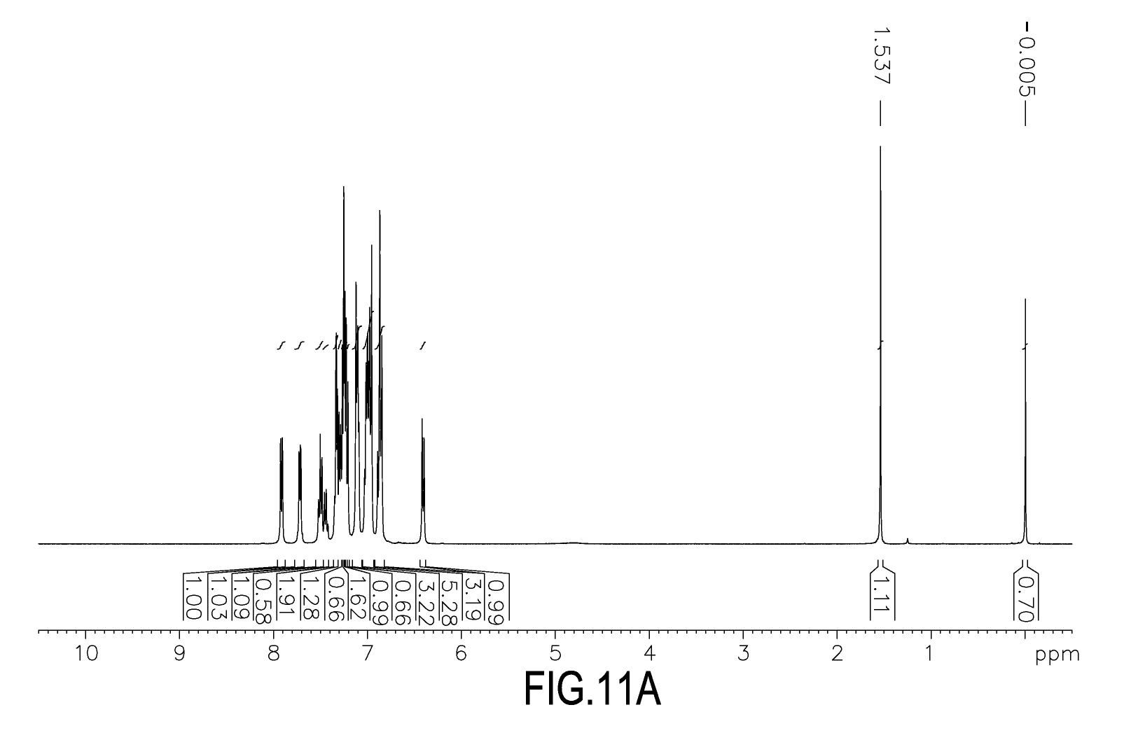

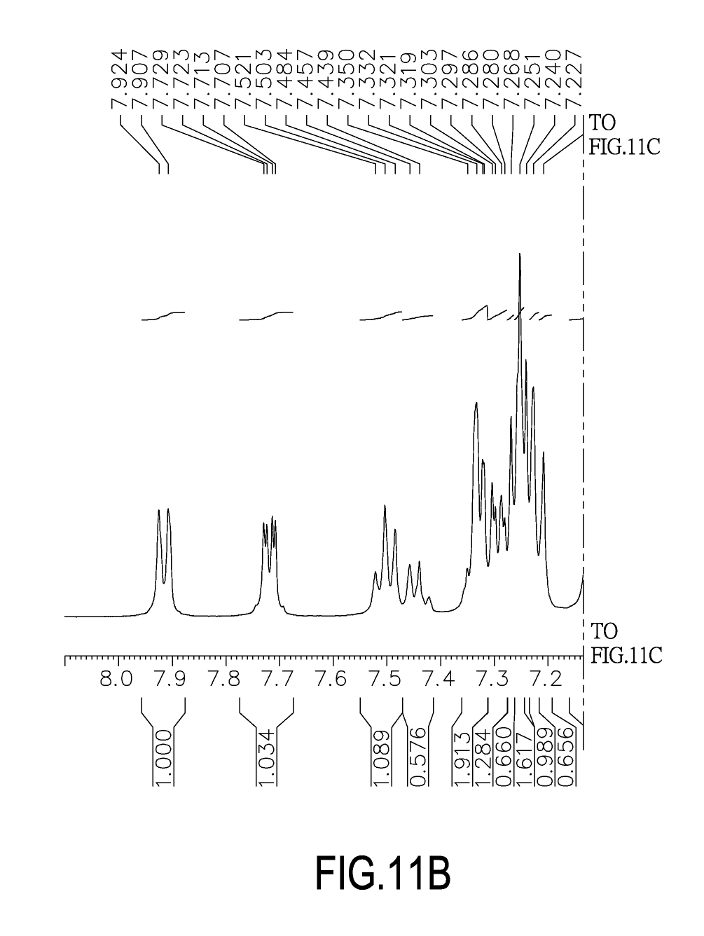

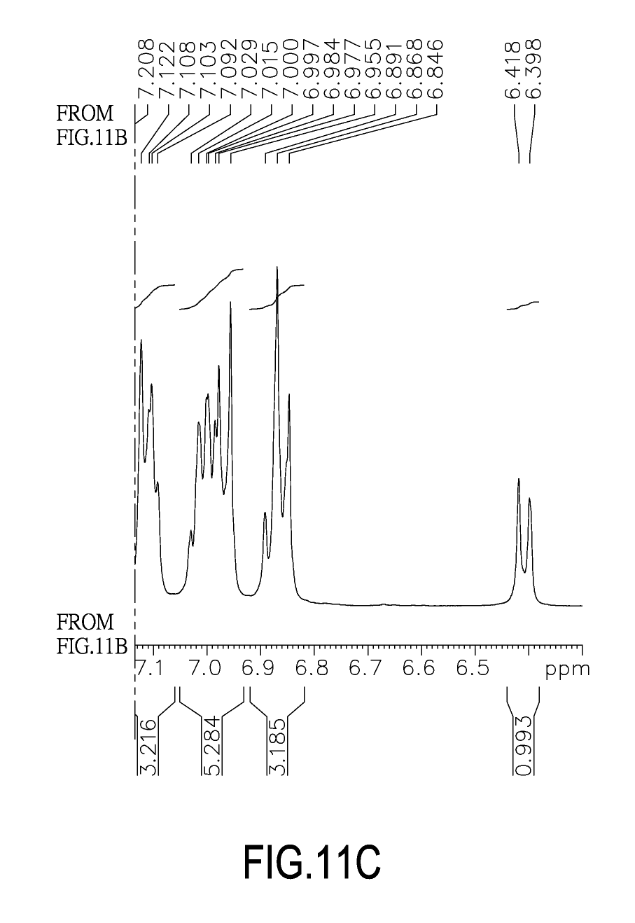

Furthermore, the white powder products of Examples 1 to 8 were also characterized by ¹H NMR spectrum (400 MHz, CDCl₃). With reference to FIGS. 4A to 4C, 5A to 5C, 6A to 6C, 7A to 7C, 8A to 8C, 9A to 9C, 10A to 10C, and 11A to 11C, the white powder products of Examples 1 to 8 were identified as Compounds (I) to (III), (XIX), (LXXXV), (CXXVI), (CLXIV), and (CLXXV) by ¹H NMR spectroscopy (400 MHz, CDCl₃). The results demonstrate that the 9,10-dihydroacridine derivative of the present invention is successfully synthesized.

### Examples 9 and 10

### Preparation of the 9,10-Dihydroacridine Derivatives of the Present Invention

The 9,10-dihydroacridine derivatives of Examples 9 and 10 in accordance with the present invention were prepared by a similar manner as Examples 1 to 8, except that the Intermediate (1) is replaced by Intermediate (2). The general synthesis pathway of the 9,10-dihydroacridine derivatives in Examples 9 and 10 was summarized in Scheme 5.

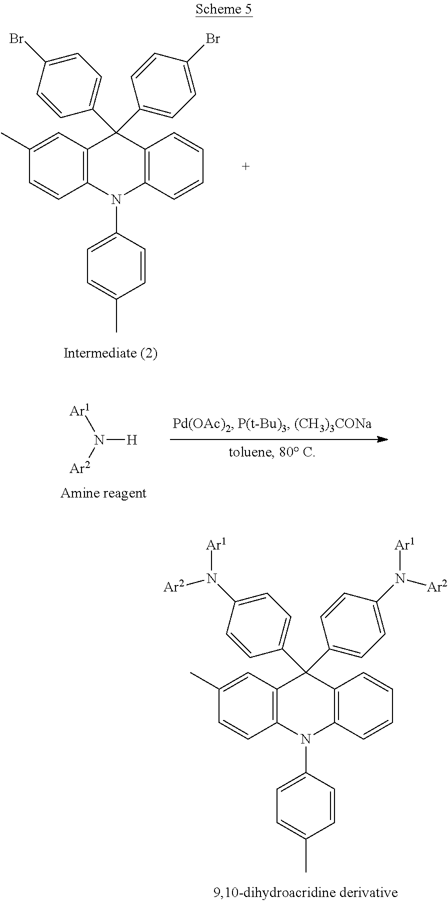

After purification, a white powder product was finally prepared.

The amine reagent used for preparing the 9,10-dihydroacridine derivative in Example 9 is different from that in Example 10. The amine reagents, products, and their respective yields in Examples 9 and 10 were listed in Table 2.

TABLE 2
the amine reagents, products, and their respective yields in Examples 9
and 10

| | Amine Reagent | Product | Yield |
|---|---|---|---|
| Example 9 | 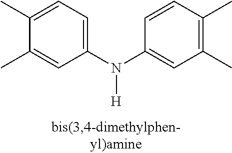 | 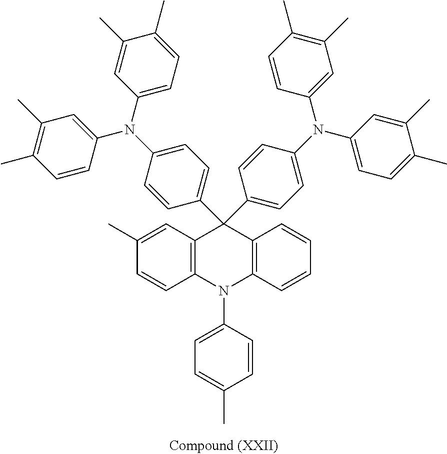 | 65% |
| Example 10 | 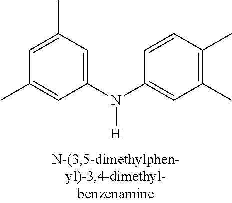 | 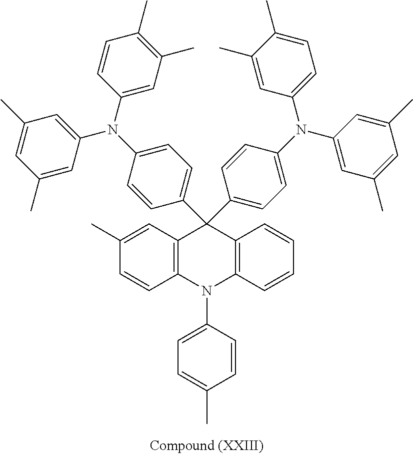 | 83% |

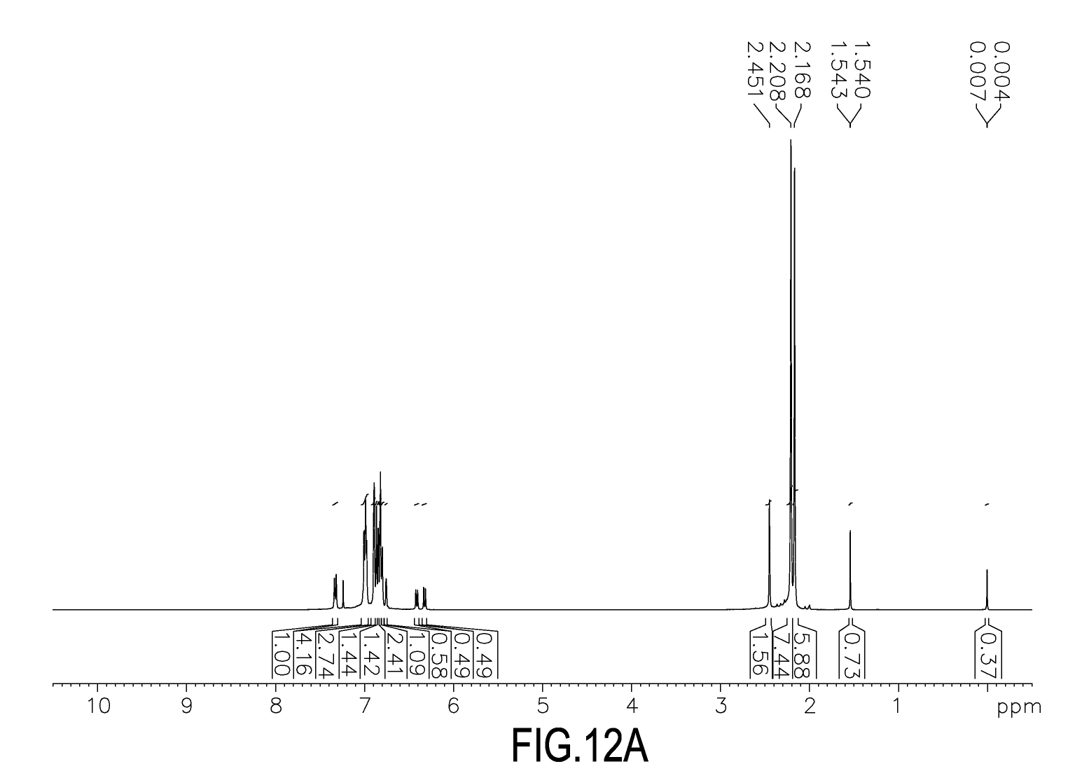

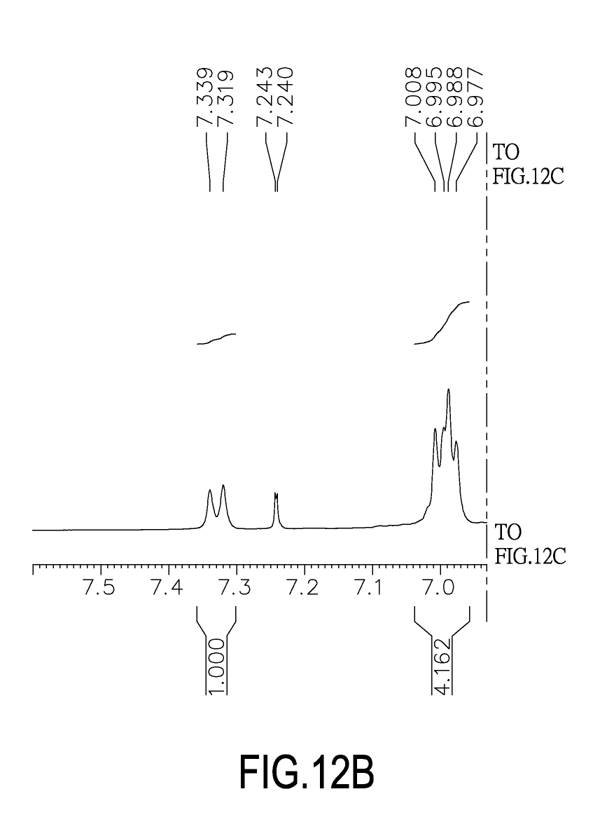

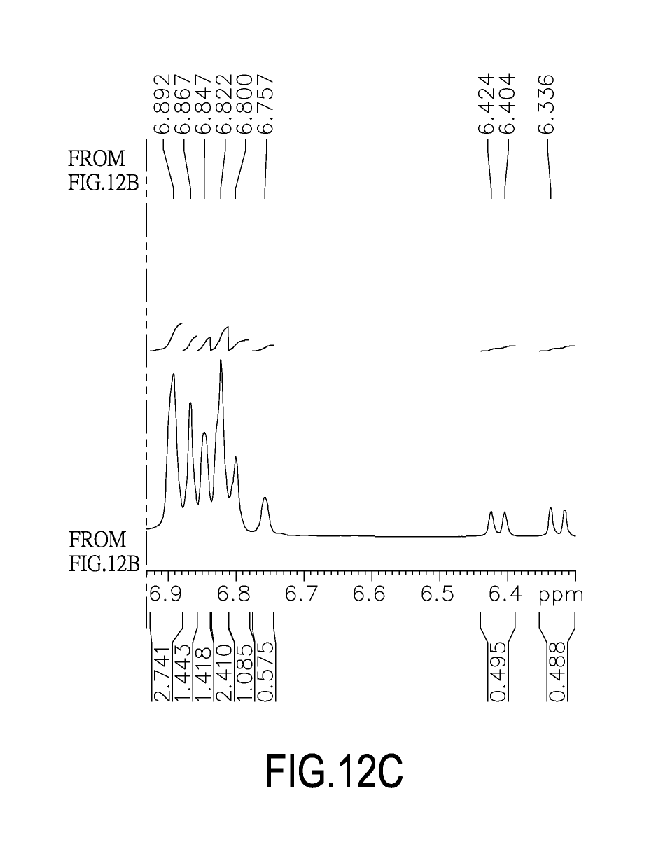

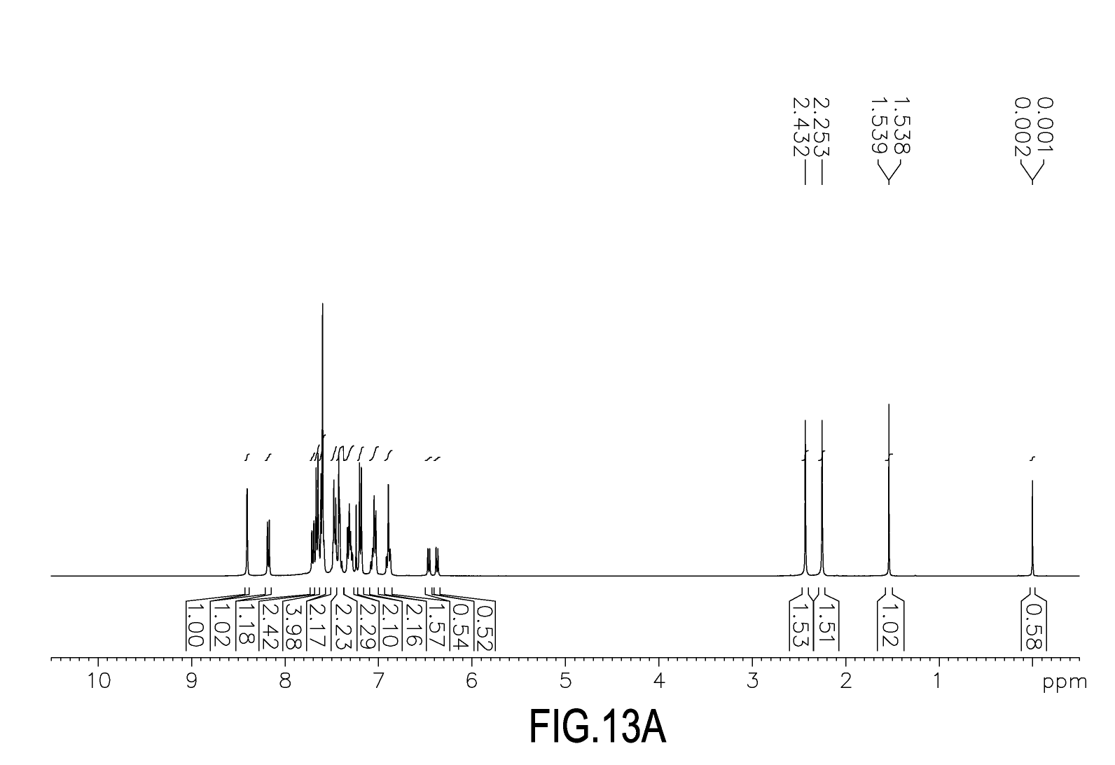

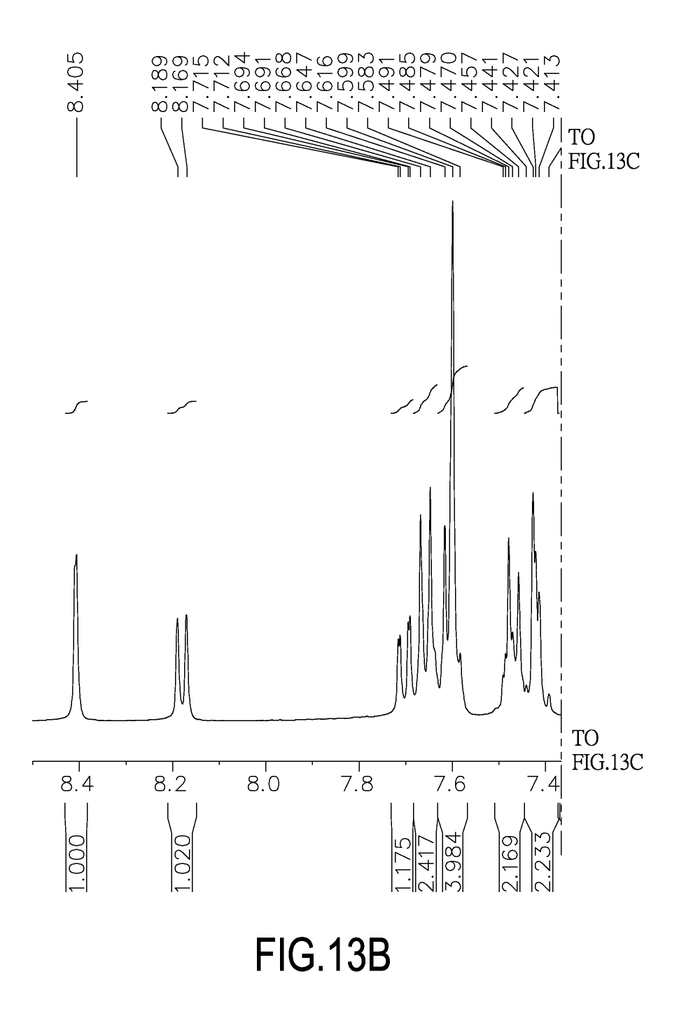

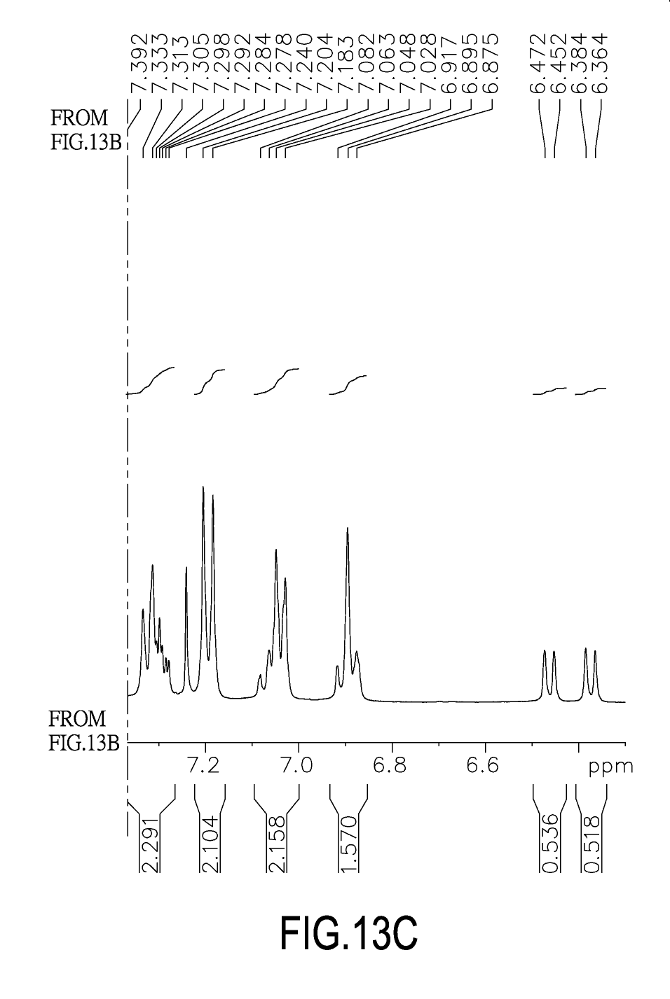

With reference to FIGS. 12A to 12C and 13A to 13C, the white powder products of Examples 9 and 10 were identified as Compounds (XXII) and (XXIII) by ¹H NMR spectroscopy (400 MHz, CDCl₃). The results demonstrate again that the 9,10-dihydroacridine derivative of the present invention is successfully synthesized.

### Example 11

### Preparation of the 9,10-Dihydroacridine Derivative of the Present Invention

The 9,10-dihydroacridine derivative of Example 11 in accordance with the present invention was prepared as described below. The synthesis pathway of the 9,10-dihydroacridine derivative in Example 11 was summarized in Scheme 6.

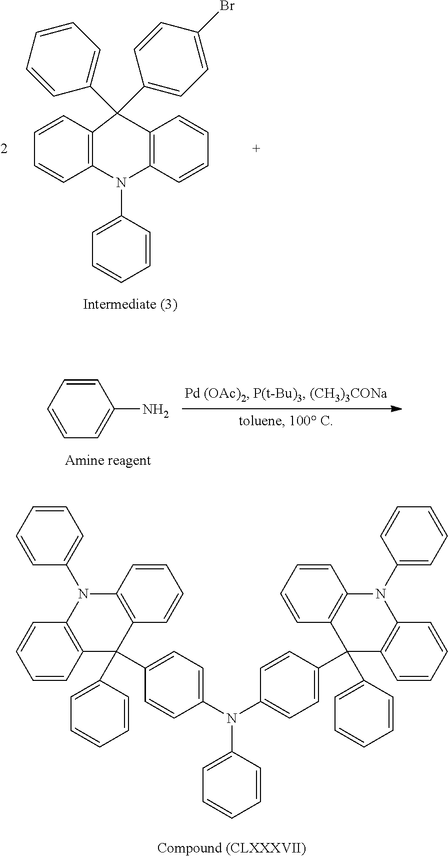 [SMILES: Brc1ccc(C2(c3ccccc3)c3ccccc3N(c3ccccc3)c3ccccc32)cc1 ; Nc1ccccc1 ; c1ccc(N(c2ccc(C3(c4ccccc4)c4ccccc4N(c4ccccc4)c4ccccc43)cc2)c2ccc(C3(c4ccccc4)c4ccccc4N(c4ccccc4)c4ccccc43)cc2)cc1]

First, 107.4 mmol of Intermediate (3), 53.7 mmol of aniline as an amine reagent, 0.3 mmol of Pd(OAc)₂, 1.2 mmol of P(t-Bu)₃, and 80.5 mmol of (CH₃)₃CONa were dissolved in 100 ml of toluene to form a reaction mixture. The reaction mixture was stirred at 100° C. for 8 hours and then cooled to room temperature.

Next, the cooled reaction mixture was added to a mixed solution of 60 ml of THF/H₂O (1:1 v/v) for extraction. An organic layer was collected and dried over MgSO₄ and concentrated.

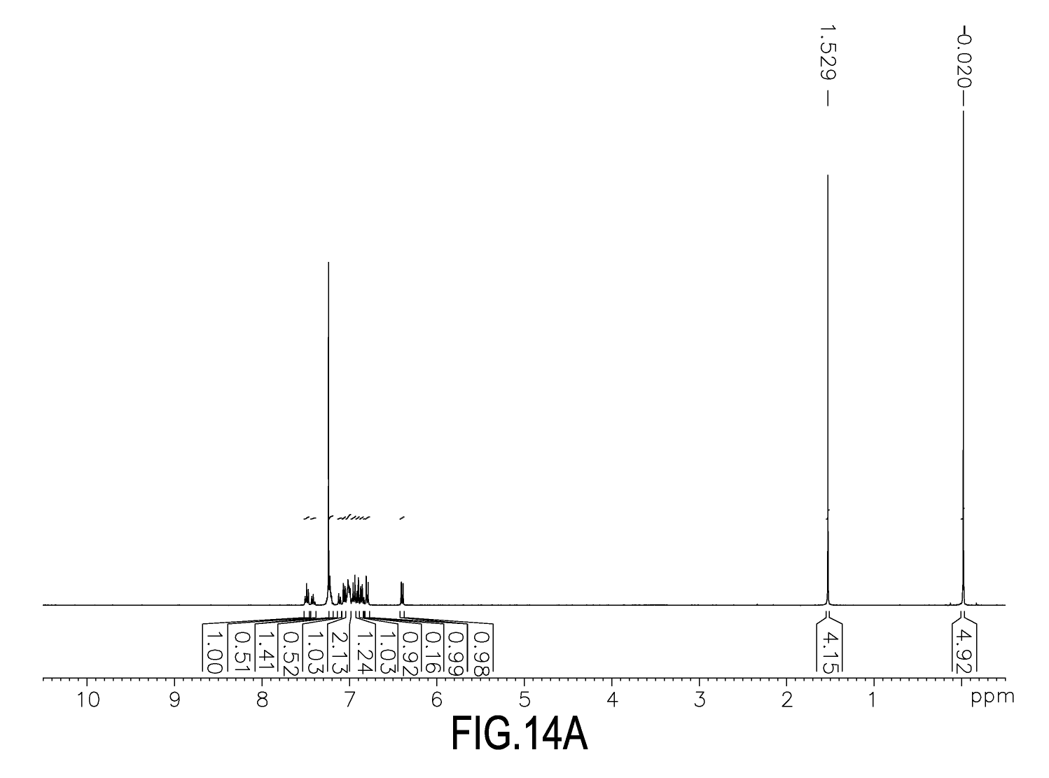

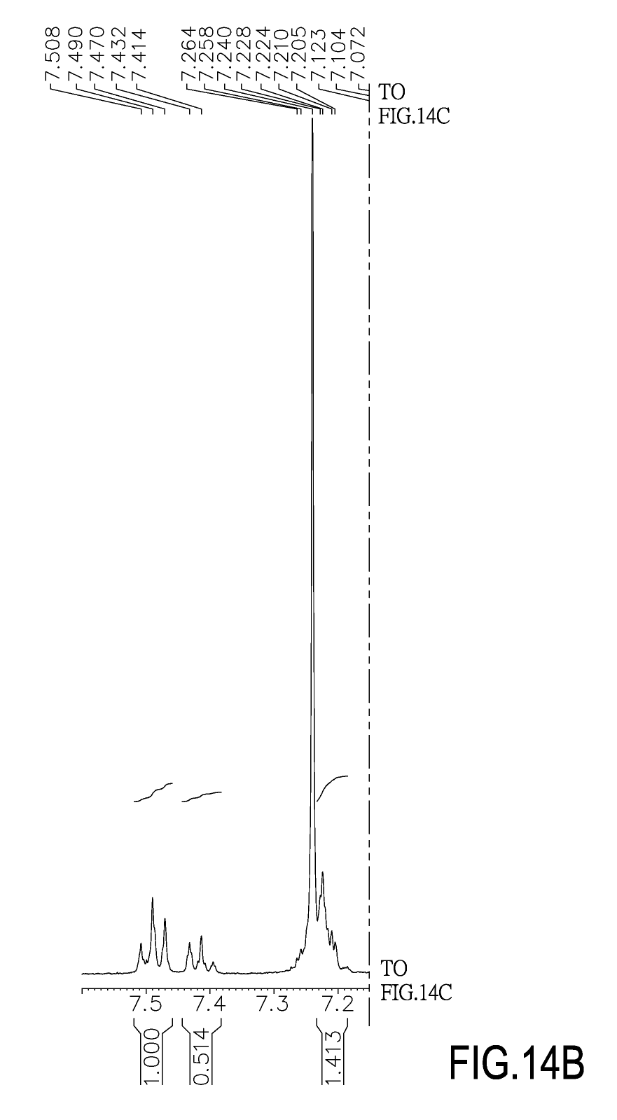

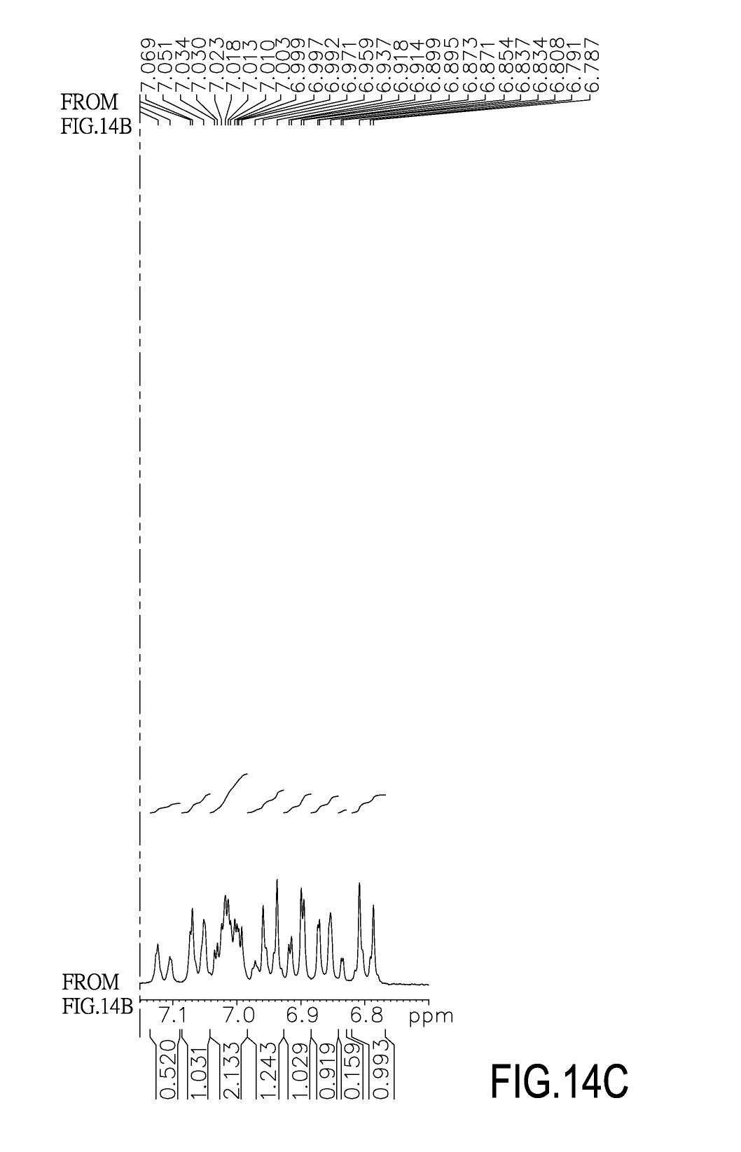

After that, the remainder was purified by column chromatography, and separated by filtering and then washed with ethyl acetate to form a white powder product in a yield about 91%. With reference to FIGS. 14A to 14C, the white powder product was identified as Compound (CLXXXVII) by ¹H NMR spectroscopy.

It demonstrates that the 9,10-dihydroacridine derivative of the present invention is successfully synthesized according to the method.

### Examples 12 to 20

### Blue OLEDs

Blue OLEDs of Examples 12 to 20 were prepared by a similar manner as follows:

First, an indium-doped tin oxide film was formed on a substrate to obtain a first electrode as the anode. Next, a hole injection layer (HIL), a first hole transport layer (first HTL), and a second hole transport layer (second HTL) were formed on the first electrode by vacuum deposition in sequence. Then an emission layer (EML) was formed on the hole transport layer by casting. After that, an electron transport layer (ETL) and an electron injection layer (EIL) were formed on the emission layer by spin coating in sequence. Finally, a second electrode as the cathode was formed on the electron injection layer to obtain a blue OLED.

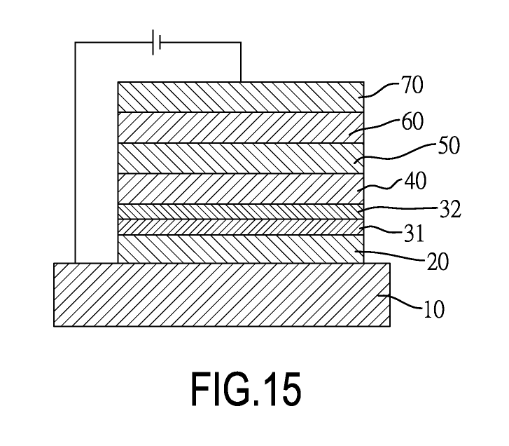

With reference to FIG. 15, all the blue OLEDs of Examples 12 to 22 each have a first electrode 10, a hole injection layer 20, a first hole transport layer 31, a second hole transport layer 32, an emission layer 40, an electron transport layer 50, an electron injection layer 60, and a second electrode 70 in sequence.

The thicknesses and materials of the first electrode 10, the hole injection layer 20, the first hole transport layer 31, the second hole transport layer 32, the emission layer 40, the electron transport layer 50, the electron injection layer 60, and the second electrode 70 are listed in Table 3.

TABLE 3
the thickness and materials of components in the blue OLED

| Component | Thickness | Material |
|---|---|---|
| First | 150 nm | Indium-doped tin oxide |
| electrode | | |
| HIL | 300 Å | 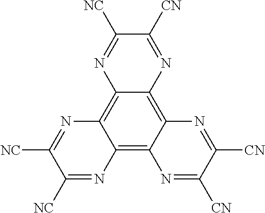 [SMILES: N#Cc1nc2c3nc(C#N)c(C#N)nc3c3nc(C#N)c(C#N)nc3c2nc1C#N] |
| First HTL | 550 Å | 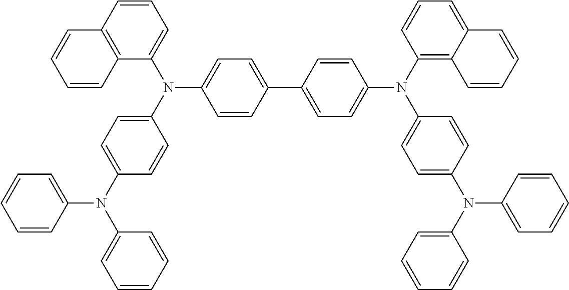 [SMILES: c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1] |
| Second HTL | 200 Å | 9,10-dihydroacridine derivative as shown in Table 4 |
| EML | 250 Å | 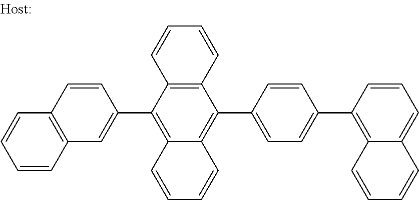 [SMILES: c1ccc2cc(-c3c4ccccc4c(-c4ccc(-c5cccc6ccccc56)cc4)c4ccccc34)ccc2c1] |
| | | 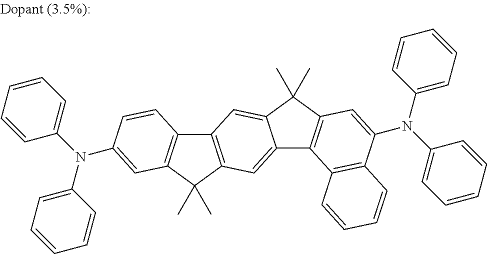 [SMILES: CC1(C)c2cc(N(c3ccccc3)c3ccccc3)ccc2-c2cc3c(cc21)-c1c(cc(N(c2ccccc2)c2ccccc2)c2ccccc12)C3(C)C] |
| ETL | 250 Å | 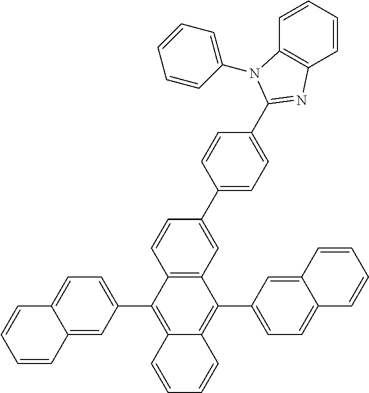 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1] |
| EIL | 20 Å | 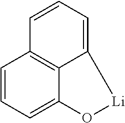 |
| Second | 150 nm | Aluminum |
| electrode | | |

On the other hand, a blue OLED comprising N,N′-di(naphthalene-1-yl)-N,N′-diphenylbenzidine (NBP) as the second hole transport material was provided as Comparative Example 1. To verify the optical performances of the blue OLEDs, the structures, materials, and thicknesses of the blue OLEDs of Comparative Example 1 were similar with those of Examples 12 to 20 except for the hole transport material.

The optical performances of the blue OLEDs of Examples 12 to 20 in accordance with the present invention and Comparative Example were measured by using PR650 as photometer and Keithley 2400 as power supply. The current efficiencies of the blue OLEDs at a certain voltage were respectively determined by dividing each electroluminescence radiance of the devices by each respective current density needed to run the devices. Color coordinates (x,y) were determined according to the CIE chromaticity scale (Commission Internationale de L'Eclairage, 1931). The results were shown in Table 4.

TABLE 4
the current efficiencies and color coordinates (x, y) of the blue OLEDs
of Examples 12 to 20 and Comparative Example 1

| | | Current | |
|---|---|---|---|
| | | efficiency at | Color coordinates |
| Sample | Second HTL material | 1,000 nits | (x, y) at 1,000 nits |
| Example 12 | Compound (I) | 9.85 cd/A | (0.138, 0.172) |
| Example 13 | Compound (II) | 8.36 cd/A | (0.138, 0.173) |
| Example 14 | Compound (III) | 10.8 cd/A | (0.138, 0.169) |
| Example 15 | Compound (XIX) | 7.49 cd/A | (0.138, 0.166) |
| Example 16 | Compound (LXXXV) | 9.05 cd/A | (0.139, 0.180) |
| Example 17 | Compound (CXXVI) | 8.74 cd/A | (0.139, 0.170) |
| Example 18 | Compound (CLXIV) | 9.31 cd/A | (0.144, 0.195) |
| Example 19 | Compound (CLXXV) | 7.45 cd/A | (0.137, 0.168) |
| Example20 | Compound (XXIII) | 6.54 cd/A | (0.140, 0.153) |
| Comparative Example 1 | 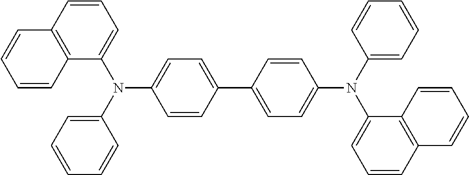 [SMILES: c1ccc(N(c2ccc(-c3ccc(N(c4ccccc4)c4cccc5ccccc45)cc3)cc2)c2cccc3ccccc23)cc1] | 7.32 cd/A | (0.139, 0.164) |

Based on the aforementioned results, the 9,10-dihydroacridine derivatives from Examples 12 to 20, including Compounds (I) to (III), (XIX), (LXXXV), (CXXVI), (CLXIV), (CLXXV), and (XXIII), are suitable as the hole transport materials in the blue OLEDs. Therefore, the current efficiencies and chromaticities of the blue OLEDs of Examples 12 to 20 having the 9,10-dihydroacridine derivatives are effectively improved over those of Comparative Example 1.

### Examples 21 to 31

### Green OLEDs

As described above, the green OLEDs of Examples 21 to 31 were prepared by a similar manner as the blue OLEDs as described above. The thicknesses and materials of the first electrode 10, the hole injection layer 20, the first hole transport layer 31, the second hole transport layer 32, the emission layer 40, the electron transport layer 50, the electron injection layer 60, and the second electrode 70 are listed in Table 5.

TABLE 5
the thickness and materials of components in the green OLEDs

| Component | Thickness | Material |
|---|---|---|
| First | 150 nm | Indium-doped tin oxide |
| electrode | | |
| HIL | 300 Å | 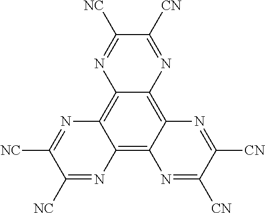 [SMILES: N#Cc1nc2c3nc(C#N)c(C#N)nc3c3nc(C#N)c(C#N)nc3c2nc1C#N] |
| First HTL | 550 Å | 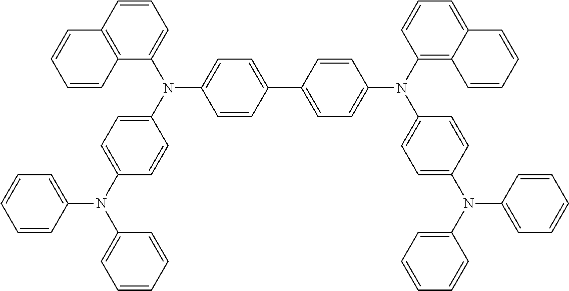 [SMILES: c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1] |
| Second HTL | 200 Å | the 9,10-dihydroacridine derivatives as shown i |
| | | Table 6 |
| EML | 400 Å | 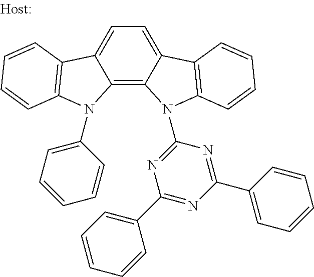 [SMILES: c1ccc(-c2nc(-c3ccccc3)nc(-n3c4ccccc4c4ccc5c6ccccc6n(-c6ccccc6)c5c43)n2)cc1] |
| | | 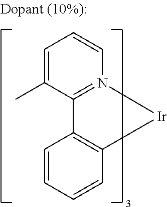 |
| ETL | 350 Å | 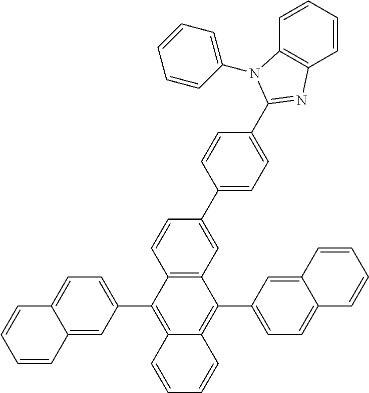 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1] |
| EIL | 20 Å | 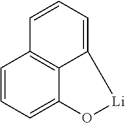 |
| Second | 150 nm | Aluminum |
| electrode | | |

On the other hand, a green OLED comprising NBP as the second hole transport material was provided as Comparative Example 2. To verify the optical performances of green OLEDs, the structures, materials, and thicknesses of the green OLEDs of Comparative Example 2 were similar with those of Examples 21 to 31 except for the second hole transport material.

The optical performances of the green OLEDs of Examples 21 to 31 in accordance with the present invention and Comparative Example were measured by using PR650 as photometer and Keithley 2400 as power supply. The results were shown in Table 6.

TABLE 6
the current efficiencies and color coordinates (x, y) of the green
OLEDs of Examples 21 to 31 and Comparative Example 2

| | | Current | |
|---|---|---|---|
| | | efficiency at | Color coordinates |
| Sample | Second HTL material | 1,000 nits | (x, y) at 1,000 nits |
| Example21 | Compound (I) | 51.9 cd/A | (0.348, 0.610) |
| Example22 | Compound (II) | 50.4 cd/A | (0.340, 0.610) |
| Example23 | Compound (III) | 50.1 cd/A | (0.349, 0.608) |
| Example24 | Compound (XIX) | 54.0 cd/A | (0.346, 0.612) |
| Example25 | Compound (LXXXV) | 51.9 cd/A | (0.348, 0.610) |
| Example26 | Compound (CXXVI) | 52.0 cd/A | (0.350, 0.608) |
| Example27 | Compound (CLXIV) | 51.6 cd/A | (0.341, 0.614) |
| Example28 | Compound (CLXXV) | 49.7 cd/A | (0.358, 0.602) |
| Example29 | Compound (XXII) | 54.2 cd/A | (0.339, 0.616) |
| Example30 | Compound (XXIII) | 57.2 cd/A | (0.336, 0.618) |
| Example31 | Compound | 46.8 cd/A | (0.345, 0.611) |
| | (CLXXXVII) | | |
| Comparative Example 2 | 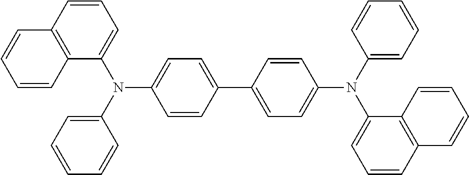 [SMILES: c1ccc(N(c2ccc(-c3ccc(N(c4ccccc4)c4cccc5ccccc45)cc3)cc2)c2cccc3ccccc23)cc1] | 28.6 cd/A | (0.356, 0.605) |

The results demonstrated that all 9,10-dihydroacridine derivatives from Examples 21 to 31, including Compounds (I) to (III), (XIX), (LXXXV), (CXXVI), (CLXIV), (CLXXV), (XXII), (XXIII), and (CLXXXVII), are suitable as the hole transport material in the green OLEDs, and thereby the current efficiencies and chromaticities of the green OLEDs of Examples 21 to 31 are effectively improved over those of Comparative Example 2.

### Examples 32 to 41

### Red OLEDs

As described above, the red OLEDs of Examples 32 to 41 were prepared by a similar manner as the blue OLEDs. The thicknesses and materials of the first electrode 10, the hole injection layer 20, the first hole transport layer 31, the second hole transport layer 32, the emission layer 40, the electron transport layer 50, the electron injection layer 60, and the second electrode 70 are listed in Table 7.

TABLE 7
the thickness and materials of components in the red OLEDs

| Component | Thickness | Material |
|---|---|---|
| First | 150 nm | Indium-doped tin oxide |
| electrode | | |
| HIL | 300 Å | 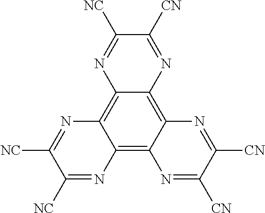 [SMILES: N#Cc1nc2c3nc(C#N)c(C#N)nc3c3nc(C#N)c(C#N)nc3c2nc1C#N] |
| First HTL | 550 Å | 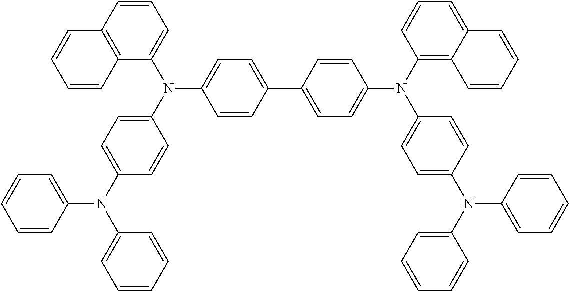 [SMILES: c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1] |
| Second HTL | 200 Å | the 9,10-dihydroacridine derivative as shown in |
| | | Table 8 |
| EML | 300 Å | 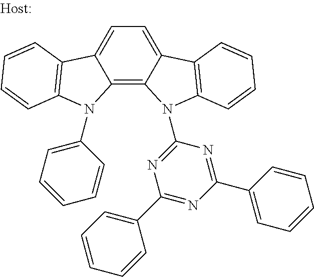 [SMILES: c1ccc(-c2nc(-c3ccccc3)nc(-n3c4ccccc4c4ccc5c6ccccc6n(-c6ccccc6)c5c43)n2)cc1] |
| | | 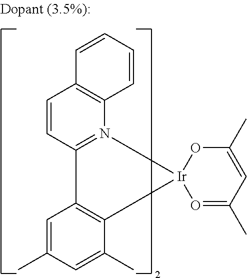 |
| ETL | 350 Å | 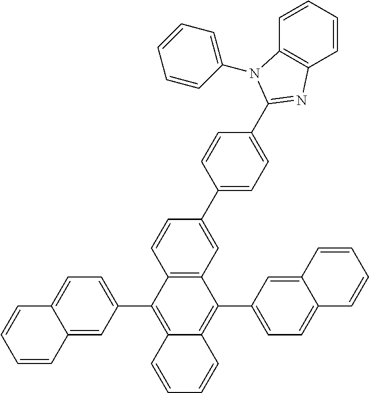 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1] |
| EIL | 20 Å | 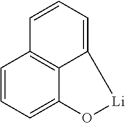 |
| Second | 150 nm | Aluminum |
| electrode | | |

On the other hand, a red OLED comprising NBP as the second hole transport material was provided as Comparative Example 3. To verify the optical performances of the red OLEDs, the structures, materials, and thicknesses of the red OLEDs of Comparative Example 3 were similar with those of Examples 32 to 41 except for the second hole transport material.

The optical performances of the red OLEDs of Examples 32 to 41 in accordance with the present invention and Comparative Example 3 were measured by using PR650 as photometer and Keithley 2400 as power supply. The results were shown in Table 8.

TABLE 8
the current efficiencies and color coordinates (x, y) of the red OLEDs
of Examples 32 to 41 and Comparative Example 3

| | | Current | |
|---|---|---|---|
| | | efficiency at | Color coordinates |
| Sample | Second HTL material | 1,000 nits | (x, y) at 1,000 nits |
| Example32 | Compound (I) | 14.7 cd/A | (0.666, 0.332) |
| Example33 | Compound (III) | 11.5 cd/A | (0.667, 0.332) |
| Example34 | Compound (XIX) | 9.75 cd/A | (0.665, 0.333) |
| Example35 | Compound (LXXXV) | 15.5 cd/A | (0.666, 0.332) |
| Example36 | Compound (CXXVI) | 14.0 cd/A | (0.667, 0.332) |
| Example37 | Compound (CLXIV) | 13.5 cd/A | (0.664, 0.333) |
| Example38 | Compound (CLXXV) | 12.5 cd/A | (0.663, 0.334) |
| Example39 | Compound (XXII) | 11.7 cd/A | (0.666, 0.332) |
| Example40 | Compound (XXIII) | 12.1 cd/A | (0.666, 0.333) |
| Example41 | Compound | 9.11 cd/A | (0.660, 0.334) |
| | (CLXXXVII) | | |
| Comparative Example 3 | 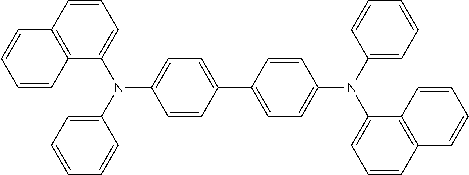 [SMILES: c1ccc(N(c2ccc(-c3ccc(N(c4ccccc4)c4cccc5ccccc45)cc3)cc2)c2cccc3ccccc23)cc1] | 5.62 | (0.662, 0.335) |

The results demonstrated that all 9,10-dihydroacridine derivatives from Examples 32 to 41, including Compounds (I), (III), (XIX), (LXXXV), (CXXVI), (CLXIV), (CLXXV), (XXII), (XXIII), and (CLXXXVII), are suitable as hole transport material in red OLEDs, and thereby the current efficiencies and chromaticities of the red OLEDs of Examples 32 to 41 are also effectively improved over those of Comparative Example 3.

Based on the results, the novel 9,10-dihydroacridine derivative is suitable as a hole transport material in a variety of OLEDs. With the aromaticity, OLEDs comprising the novel 9,10-dihydroacridine derivative(s) do have improved current efficiencies and improved chromaticities.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A 9,10-dihydroacridine derivative represented by the following Formula (I): 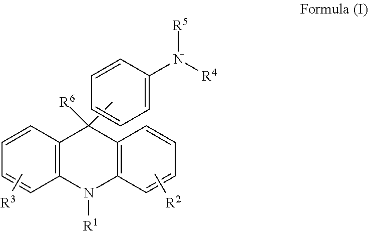
wherein R¹ is a substituted or unsubstituted aryl group having 5 to 20 carbon atoms or a substituted or unsubstituted heteroaryl group having 5 to 20 carbon atoms;
R² and R³ are each independently selected from the group consisting of: a hydrogen group, a substituted or unsubstituted alkyl group having 1 to 20 carbon atoms, a substituted or unsubstituted aryl group having 5 to 20 carbon atoms, and a substituted or unsubstituted heteroaryl group having 5 to 20 carbon atoms;
R⁴ and R⁵ are each independently a substituted or unsubstituted aryl group having 5 to 40 carbon atoms or a substituted or unsubstituted heteroaryl group having 5 to 40 carbon atoms; and
R⁶ is 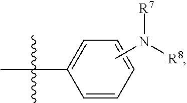
a substituted or unsubstituted aryl group having 5 to 60 carbon atoms, or a substituted or unsubstituted heteroaryl group having 5 to 60 carbon atoms, wherein R⁷ and R⁸ are each independently a substituted or unsubstituted aryl group having 5 to 40 carbon atoms or a substituted or unsubstituted heteroaryl group having 5 to 40 carbon atoms.

2. The 9,10-dihydroacridine derivative as claimed in claim 1, wherein R⁶ is 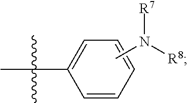
and R⁴, R⁵, R⁷ and R⁸ are each independently selected from the group consisting of: 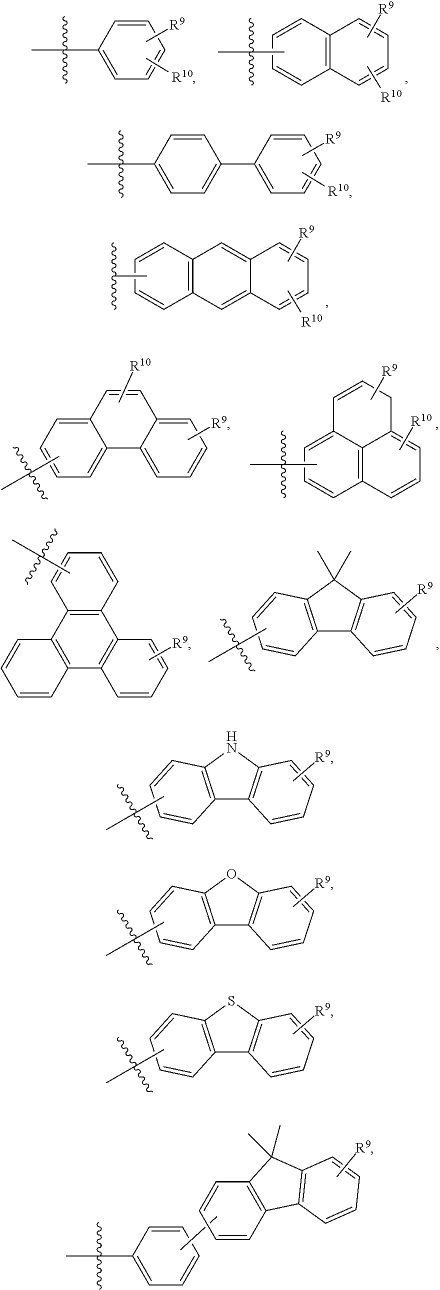 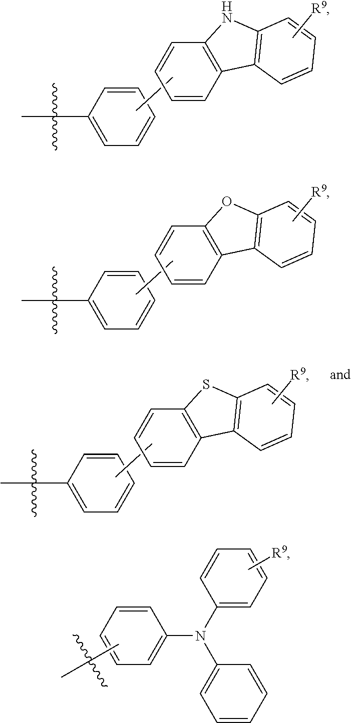
wherein R⁹ and R¹⁰ are each independently a hydrogen group or an alkyl group having 1 to 6 carbon atoms.

3. The 9,10-dihydroacridine derivative as claimed in claim 2, wherein R¹ is selected from the group consisting of: 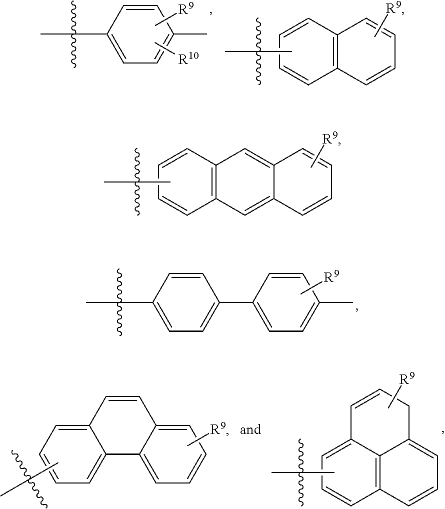
wherein R⁹ and R¹⁰ are each independently a hydrogen group or an alkyl group having 1 to 6 carbon atoms; and R² and R³ are each independently selected from the group consisting of: a hydrogen group, a substituted or unsubstituted alkyl group having 1 to 10 carbon atoms, a substituted or unsubstituted aryl group having 5 to 15 carbon atoms, and a substituted or unsubstituted heteroaryl group having 5 to 15 carbon atoms.

4. The 9,10-dihydroacridine derivative as claimed in claim 3, wherein the 9,10-dihydroacridine derivative is:

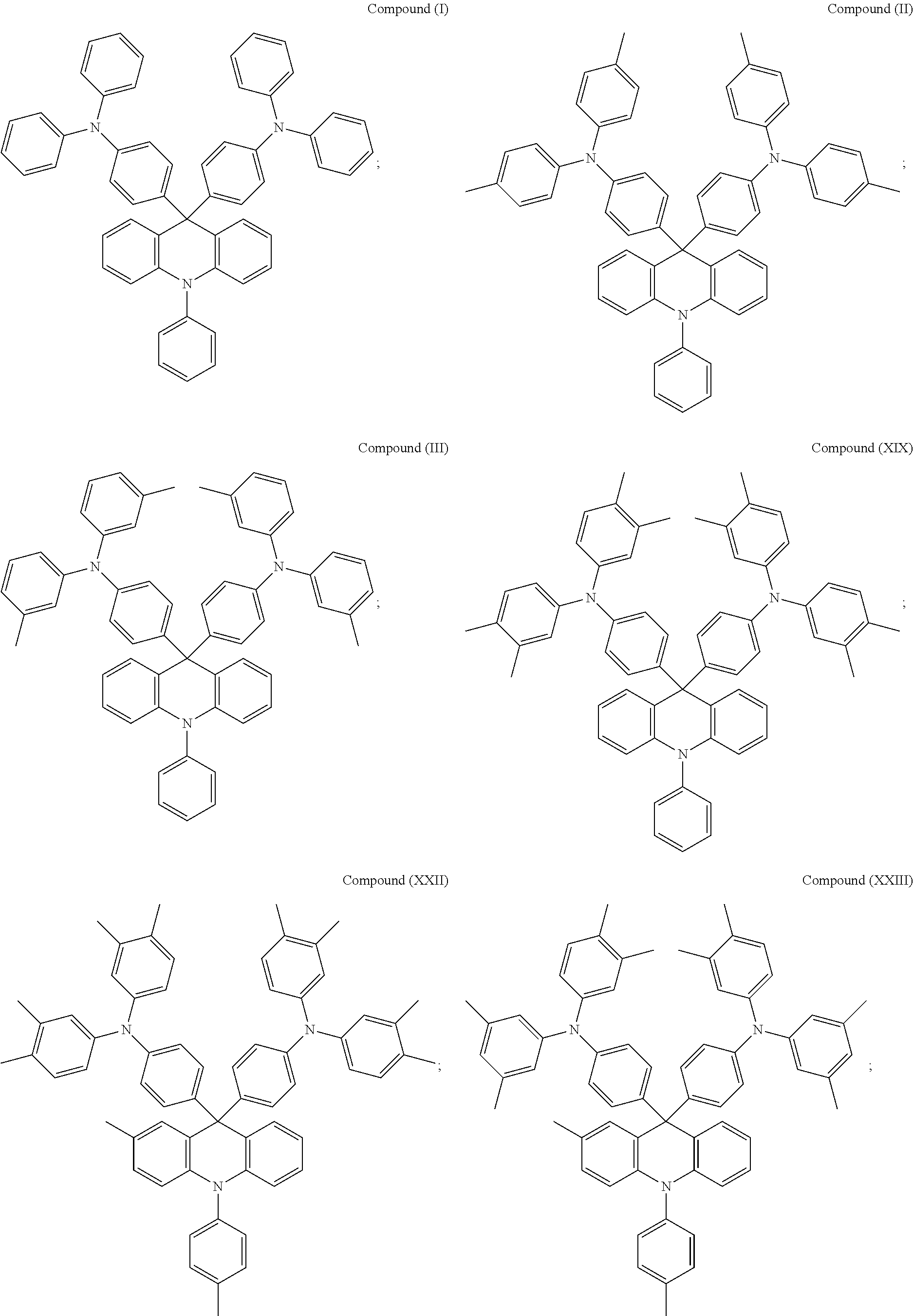

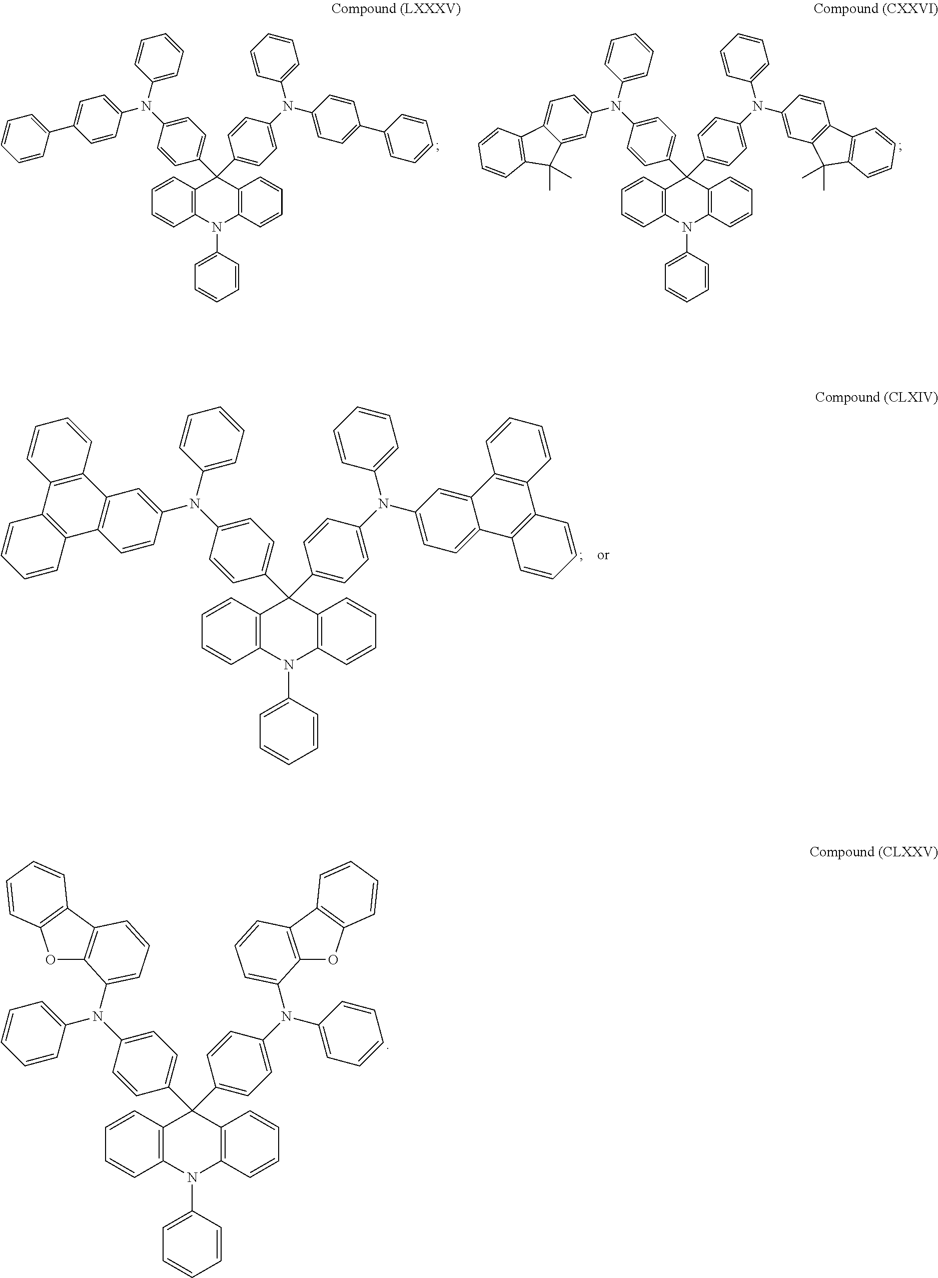

5. The 9,10-dihydroacridine derivative as claimed in claim 1, wherein R⁶ is a substituted or unsubstituted aryl group having 5 to 60 carbon atoms or a substituted or unsubstituted heteroaryl group having 5 to 60 carbon atoms.

6. The 9,10-dihydroacridine derivative as claimed in claim 5, wherein R⁶ is selected from the group consisting of: 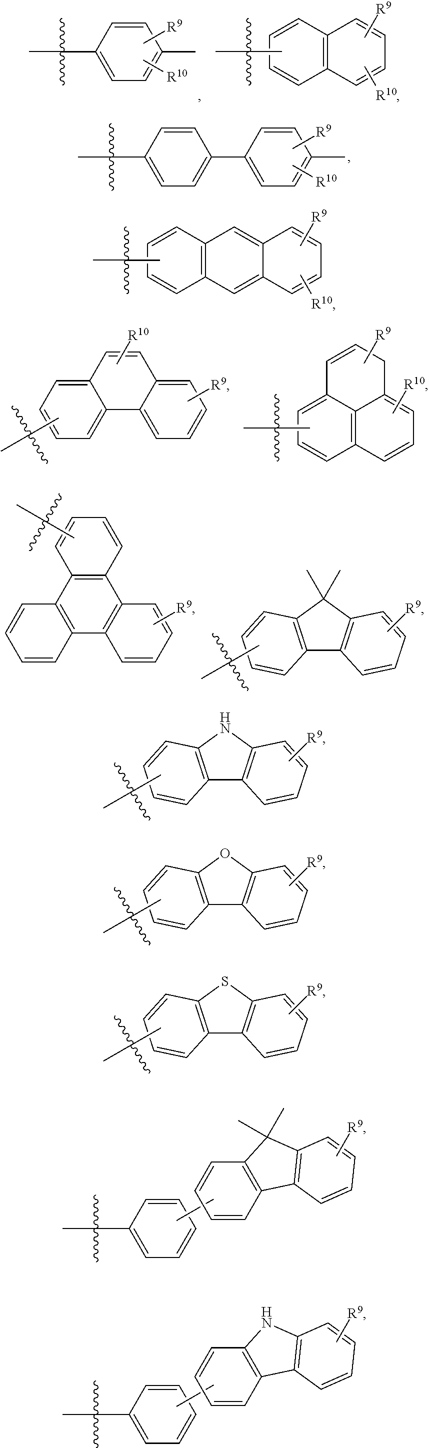 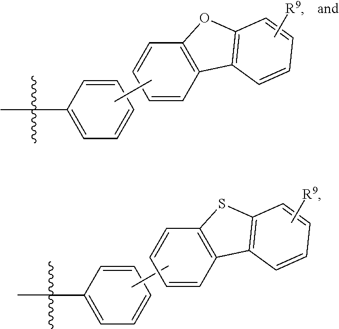
wherein R⁹ and R¹⁰ are each independently a hydrogen group or an alkyl group having 1 to 6 carbon atoms.

7. The 9,10-dihydroacridine derivative as claimed in claim 6, wherein R⁴ and R⁵ are each independently selected from the group consisting of: 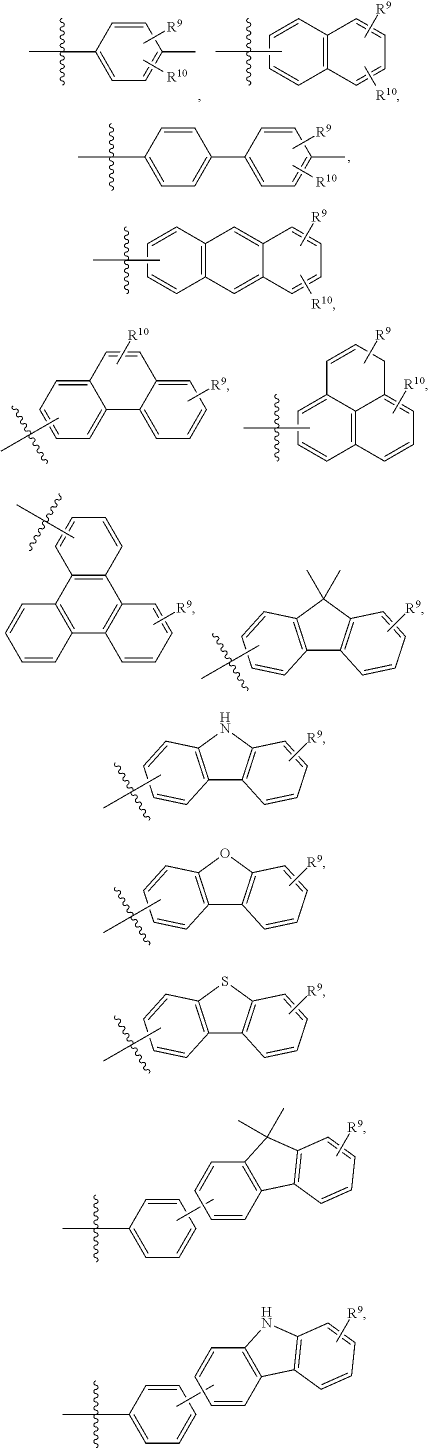 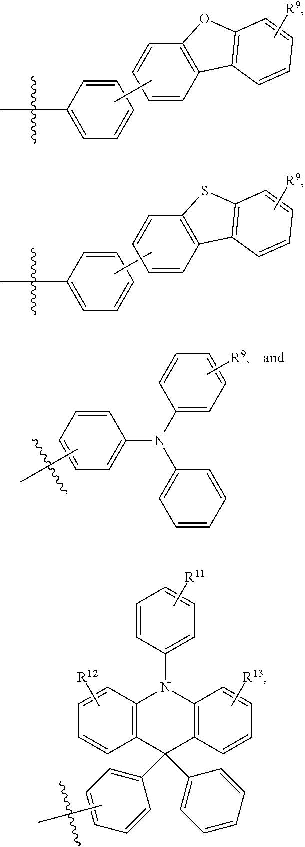
wherein R⁹ and R¹⁰ are each independently a hydrogen group or an alkyl group having 1 to 6 carbon atoms, and R¹¹, R¹², and R¹³ are each independently a hydrogen group or an alkyl group having 1 to 3 carbon atoms.

8. The 9,10-dihydroacridine derivative as claimed in claim 7, wherein R¹ is selected from the group consisting of: 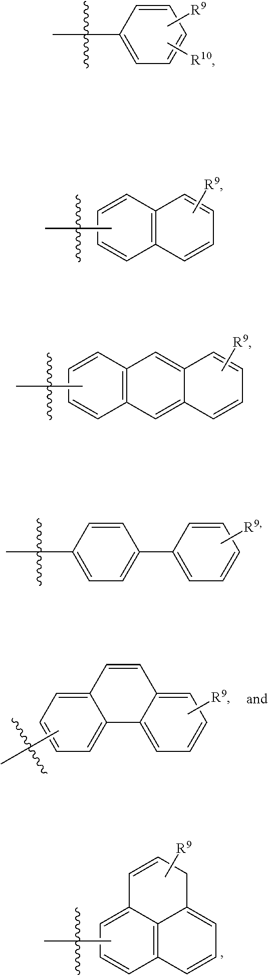
wherein R⁹ and R¹⁰ are each independently a hydrogen group or an alkyl group having 1 to 6 carbon atoms; and R² and R³ are each independently selected from the group consisting of: a hydrogen group, a substituted or unsubstituted alkyl group having 1 to 10 carbon atoms, a substituted or unsubstituted aryl group having 5 to 15 carbon atoms, and a substituted or unsubstituted heteroaryl group having 5 to 15 carbon atoms.

9. The 9,10-dihydroacridine derivative as claimed in claim 8, wherein R⁴ is 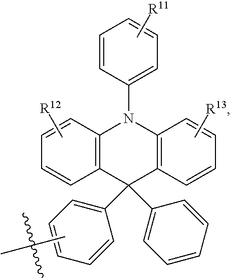
R⁵ and R⁶ are phenyl groups, R¹¹ is identical with R¹, R¹² is identical with R², and R¹³ is identical with R³.

10. The 9,10-dihydroacridine derivative as claimed in claim 9, wherein the 9,10-dihydroacridine derivative is:

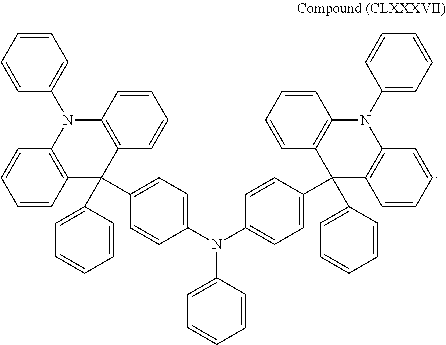 [SMILES: c1ccc(N(c2ccc(C3(c4ccccc4)c4ccccc4N(c4ccccc4)c4ccccc43)cc2)c2ccc(C3(c4ccccc4)c4ccccc4N(c4ccccc4)c4ccccc43)cc2)cc1]

11. An organic light emitting device comprising the 9,10-dihydroacridine derivative as claimed in claim 1.

12. The organic light emitting device as claimed in claim 11, wherein the organic light emitting device comprises:
a first electrode;
a hole injection layer formed on the first electrode;
a first hole transport layer formed on the hole injection layer, wherein the first hole transport layer is made of the 9,10-dihydroacridine derivative;
an emission layer formed on the first hole transport layer;
an electron transport layer formed on the emission layer;
an electron injection layer formed on the electron transport layer; and
a second electrode formed on the electron injection layer.

13. The organic light emitting device as claimed in claim 12, wherein the 9,10-dihydroacridine derivative is:

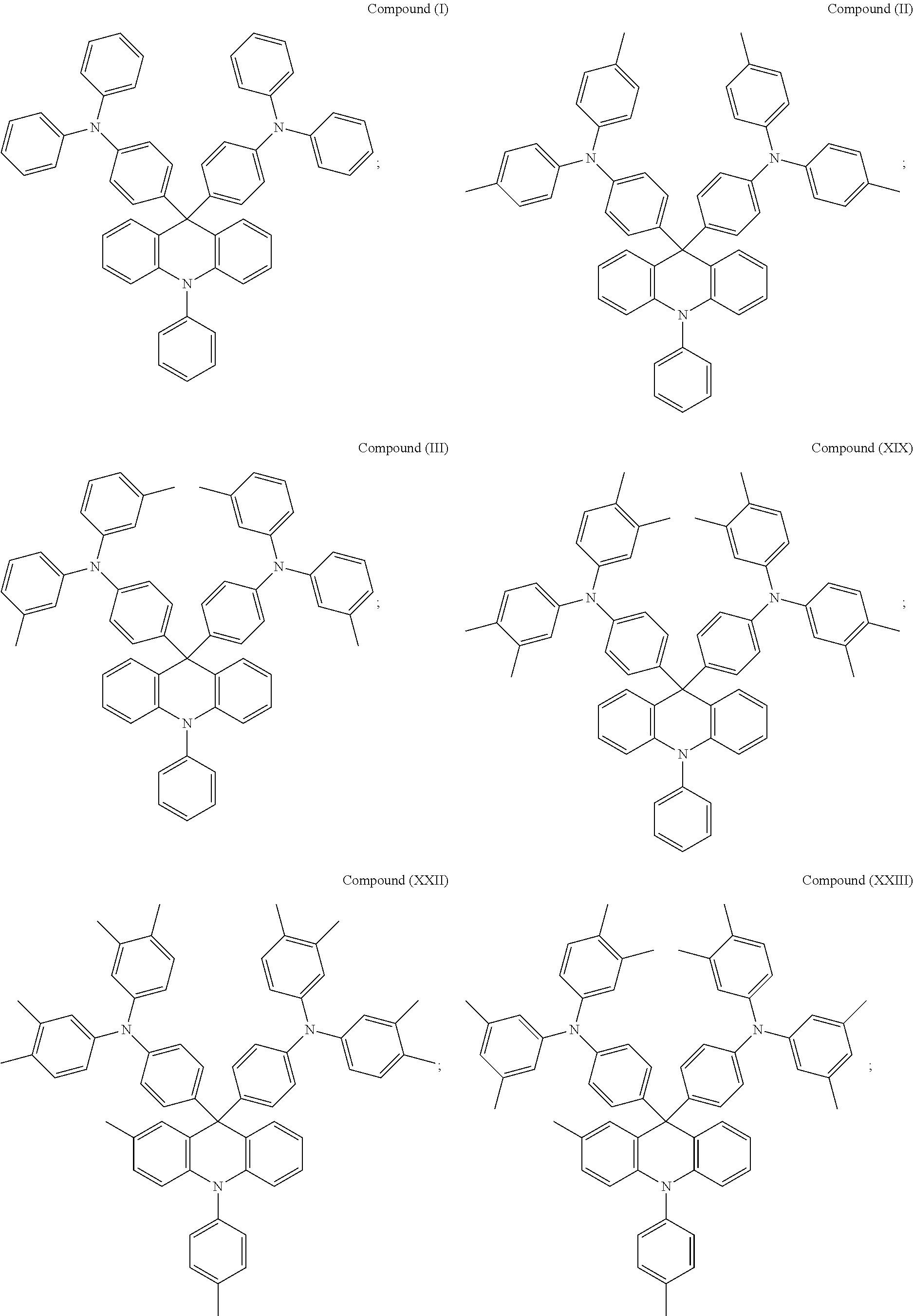

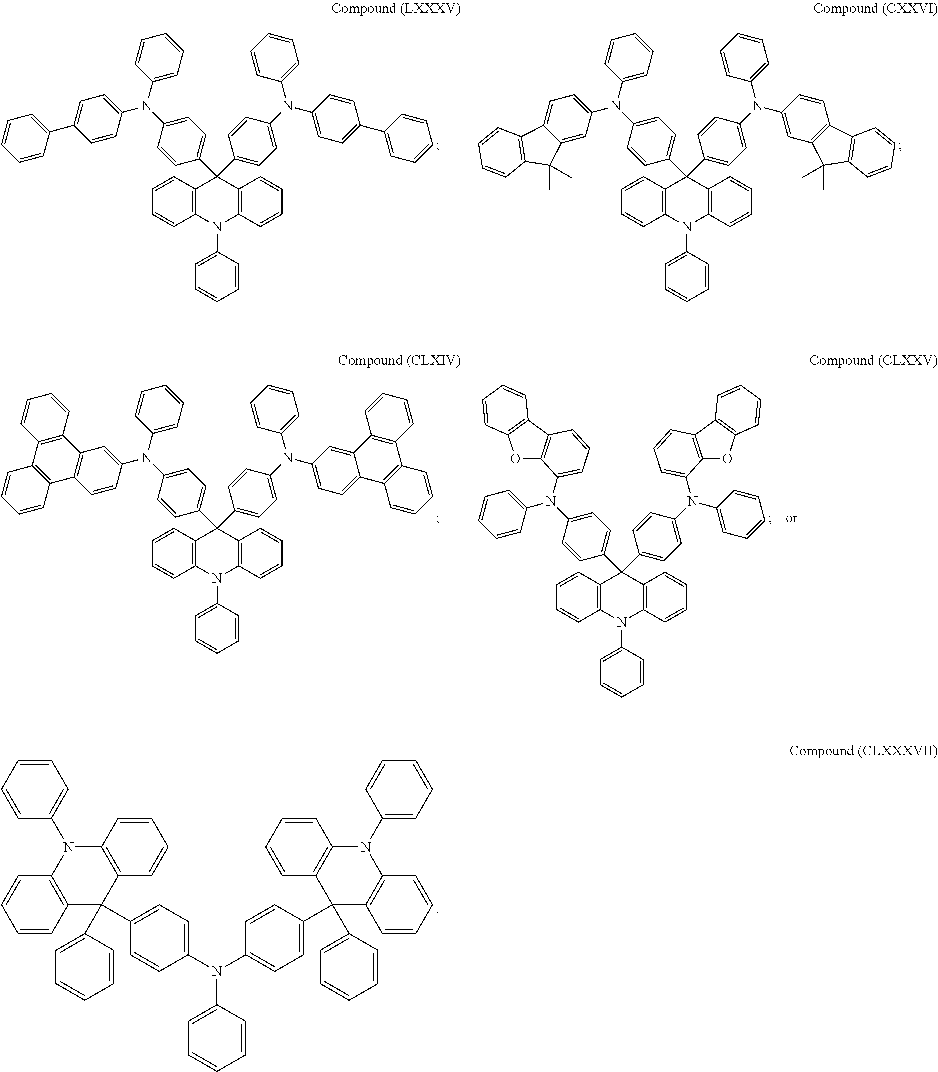

14. The organic light emitting device as claimed in claim 13, wherein the organic light emitting device comprises a second hole transport layer formed between the hole injection layer and the first hole transport layer.

15. The organic light emitting device as claimed in claim 13, wherein the organic light emitting device comprises a second hole transport layer formed between the first hole transport layer and the emission layer.
